(19) United States
(12) Patent Application Publication
(10) Pub. No.: US 2015/0138369 A1
(43) Pub. Date: May 21, 2015

(54) NEAR INFRARED ABSORPTIVE LIQUID COMPOSITION, NEAR INFRARED CUT FILTER USING THE SAME, METHOD OF MANUFACTURING THE SAME, AND CAMERA MODULE AND METHOD OF MANUFACTURING THE SAME

(71) Applicant: FUJIFILM Corporation, Tokyo (JP)

(72) Inventors: Hideki TAKAKUWA, Shizuoka (JP); Seongmu BAK, Shizuoka (JP); Kazuto SHIMADA, Shizuoka (JP)

(73) Assignee: FUJIFILM Corporation, Tokyo (JP)

(21) Appl. No.: 14/604,019

(22) Filed: Jan. 23, 2015

Related U.S. Application Data
(63) Continuation of application No. PCT/JP2013/070952, filed on Jul. 26, 2013.

(30) Foreign Application Priority Data
Jul. 27, 2012 (JP) 2012-167693
Oct. 26, 2012 (JP) 2012-236342

(51) Int. Cl. G02B 1/04; H04N 5/33; G02B 5/20

(52) U.S. Cl. CPC G02B 1/04; G02B 5/208; H04N 5/33
USPC 348/164; 252/587; 427/160; 428/447; 428/212; 428/704

(57) ABSTRACT

Provide a near-infrared absorbing composition excellent in the light resistance, and suppressed from producing non-uniformity.

A near-infrared absorbing composition comprising a copper complex having a maximum absorption wavelength in the near-infrared absorption region, and a surfactant.

### CROSS-REFERENCE TO RELATED APPLICATIONS

This application is a Continuation of PCT International Application No. PCT/JP2013/070952 filed on Jul. 26, 2013, which claims priority under 35 U.S.C §119(a) to Japanese Patent Application No. 2012-167693 filed on Jul. 27, 2012 and Japanese Patent Application No. 2012-236342 filed on Oct. 26, 2012. Each of the above application(s) is hereby expressly incorporated by reference, in its entirety, into the present application.

### TECHNICAL FIELD

The present invention relates to a near infrared absorptive liquid composition, a near infrared cut filter using the same and a method of manufacturing the same, and, a camera module and a method of manufacturing the same.

### BACKGROUND ART

Recent video camera, digital still camera, mobile phone with camera function and so forth employ CCD and CMOS image sensor, which are solid state image sensing devices capturing color image. These solid state image sensing devices need spectral sensitivity correction, since they use, for their light receiving units, a silicon photodiode which is sensitive in the near-infrared region, and often use a near-infrared cut filter (also referred to as IR cut filter, hereinafter).

Near-infrared absorbing compositions have been known as materials for composing this sort of near-infrared cut filter (Patent Literatures 1, 2). According to Patent Literature 1, the near-infrared absorbing composition is formed into a layer typically by vacuum evaporation, to thereby forma near-infrared cut layer. On the other hand, according to Patent Literature 2, the near-infrared absorbing composition is formed into a layer by coating, to thereby form the near-infrared cut layer.

### CITATION LIST

### Patent Literature

[Patent Literature 1] International Patent Publication WO99/26952, pamphlet

[Patent Literature 2] JP-A-H11-052127

### SUMMARY OF THE INVENTION

### Technical Problem

By the way, a camera module for mobile phone has no shutter, and is constantly exposed to light. The near-infrared cut filter is therefore required to have a higher level of light resistance. The near-infrared absorbing compositions described in Patent Literature 1 and Patent Literature 2 were, however, found to be insufficient in the light resistance. It was also found that the near-infrared absorbing compositions described in Patent Literature 1 and Patent Literature 2, when coated, were likely to produce defects on the surfaces thereof.

It is therefore an object of the present invention to address the problems in the prior art, and to provide a near-infrared absorbing composition excellent in the light resistance, and suppressed from producing the defects.

### Solution to Problem

In these circumstances, the present inventors found out from our thorough investigations that, by mixing a copper complex and a surfactant into the near-infrared absorbing composition, an infrared cut layer excellent in the light resistance with less defects may be formed, and the finding led us to complete the present invention. In particular, it was very surprising to find that mixing of the surfactant proved a large difference in the degree of expression of these effect.

The problems were solved by the configuration <1>, preferably by configurations <2> to <18> below.

<1> A near-infrared absorbing composition comprising a copper complex having a maximum absorption wavelength in a near-infrared absorption region, and a surfactant.
<2> The near-infrared absorbing composition of <1>

wherein the surfactant is at least either one of fluorine-containing surfactant and silicone-based surfactant.

<3> The near-infrared absorbing composition of <1> or <2>,

wherein the surfactant is a polymer having a fluoroaliphatic group.

<4> The near-infrared absorbing composition of any one of <1> to <3>, wherein amount of addition of the copper complex is 30 to 90% by mass of the whole solid content of the infrared absorbing composition.
<5> The near-infrared absorbing composition of any one of <1> to <4>,

wherein copper complex is a phosphate-copper complex compound.

<6> The near-infrared absorbing composition of <1>, wherein the phosphate-copper complex compound is formed by using a compound represented by the formula (1) below:

(HO)ₙ—P(═O)—(OR²)₃₋ₙ Formula (1)

(in the formula, R² represents a C₁₋₁₈ alkyl group, C₆₋₁₈ aryl group, C₁₋₁₈ aralkyl group, or C₁₋₁₈ alkenyl group, or —OR² represents a C₄₋₁₀₀ polyoxyalkyl group, C₄₋₁₀₀ (meth)acryloyloxyalkyl group, or, C₄₋₁₀₀ (meth)acryloyl polyoxyalkyl group, and n represents 1 or 2.)
<7> The near-infrared absorbing composition of any one of <1> to <6>, further comprising a curable compound.
<8> The near-infrared absorbing composition of any one of <1> to <7>, used in the form of coated film formed on an image sensor for solid state image sensing device.
<9> The near-infrared absorbing composition of any one of <1> to <8>, wherein amount of addition of the surfactant is 0.0001 to 2% by mass of the whole solid content.
<10> A stack comprising a near-infrared cut layer formed by curing the near-infrared absorbing composition described in any one of <1> to <9>, and a dielectric multi-layered film.
<11> The stack of <10>, wherein the near-infrared cut layer is provided on a transparent support.
<12> The stack of <10> or <11>,

wherein the dielectric multi-layered film is configured to have high refractive index material layers and low refractive index material layers alternately stacked therein.

<13> The stack of <12>,

wherein the high refractive index material layer is a layer composed of titania, and the low refractive index material layer is a layer composed of silica.

<14> A near-infrared cut filter having a near-infrared cut layer formed by curing the near-infrared absorbing composition described in any one of <1> to <9>, or having a stack described in any one of <10> to <13>.
<15> A camera module comprising a substrate for solid state image sensing device, and the near-infrared cut filter described in <14> disposed on the light receiving side of the substrate for solid state image sensing device.
<16> A method of manufacturing a camera module which has a substrate for solid state image sensing device, and a near-infrared cut filter disposed on the light receiving side of the substrate for solid state image sensing device, the method comprising:

applying the near-infrared absorbing composition described in any one of <1> to <9> to thereby form a film, on the light receiving side of the substrate for solid state image sensing device.

<17> The method of manufacturing a camera module of <16>, further comprising curing the film formed by applying the near-infrared absorbing composition, by irradiating the film with light.
<18> A near-infrared cut filter comprising a translucent support, a near-infrared cut layer formed by curing a near-infrared absorbing composition containing a copper complex having a maximum absorption wavelength in the near-infrared absorption region, and a dielectric multi-layered film, stacked in this order.

### Advantageous Effects of Invention

The present invention is the first to provide a near-infrared absorbing composition excellent in the light resistance, and suppressed from producing non-uniformity.

### BRIEF DESCRIPTION OF DRAWINGS

FIG. 1 is a schematic cross sectional view illustrating a configuration of a camera module having a solid state image sensing device according to an embodiment of the present invention; and

FIG. 2 is a schematic cross sectional view illustrating a substrate for solid state image sensing device according to an embodiment of the present invention.

### DESCRIPTION OF EMBODIMENTS

The present invention will be detailed below. Note in this specification that the wording “to” with preceding and succeeding numerals is used for indicating a numerical range with the lower and upper limits thereof respectively given by these numerals.

In this specification, “(meth)acrylate” means acrylate and methacrylate, “(meth)acryl” means acryl and methacryl, “(meth)acryloyl” means acryloyl and methacryloyl. The monomer in the present invention is discriminated from oligomer and polymer, and means any compound having a weight-average molecular weight of 2,000 or smaller. In this specification, the polymerizable compound means any compound having a polymerizable functional group, and may be a monomer or polymer. The polymerizable functional group means any group participating a polymerization reaction. Note that, in the nomenclature of group (atomic group) in this specification, any expression without indication of “substituted” or “unsubstituted” includes both cases having no substituent and having a substituent. For example, “alkyl group” includes not only an alkyl group having no substituent (unsubstituted alkyl group) but also an alkyl group having a substituent (substituted alkyl group).

Near-infrared radiation in the present invention means the radiation in the wavelength range from 700 to 2500 nm.

The near-infrared absorbing composition, the near-infrared cut filter, the camera module having such near-infrared cut filter and a substrate for solid state image sensing device, and the method of manufacturing the camera module of the present invention will be detailed. While the explanation will occasionally be based on representative embodiments of the present invention, the present invention is not limited to these embodiments.

The near-infrared absorbing composition of the present invention (occasionally referred to as “composition of the present invention”, hereinafter) characteristically contains a copper complex having a maximum absorption wavelength in the near-infrared absorption region, and a surfactant. The contents will be detailed.

### <Copper Complex>

The composition of the present invention contains the copper complex having a maximum absorption wavelength in the near-infrared absorption region. Amount of addition of the copper complex is preferably 30 to 90% by mass of the whole solid content of the composition, more preferably 35 to 80% by mass, furthermore preferably 40 to 80% by mass, and particularly 50 to 80% by mass. Since a large amount of copper complex may be mixed in the present invention, the infrared cut layer may advantageously be thinned (1 to 500 μm thick, for example).

Only one species of the copper complex, or two or more species thereof may be used. When two or more species are used in combination, the total amount falls in the ranges described above.

The copper complex used in the present invention is not specifically limited so long as it has a maximum absorption wavelength in the near-infrared region, and is preferably represented by the formula below (1):

[Chemical Formula 1]

Cu(L)ₙ.X Formula (1)

(in the formula (1), L represents a ligand coordinated on copper, and X is absent, or represents a halogen atom, H₂O, NO₃, ClO₄, SO₄, CN, SCN, BF₄, PF₆, BPh₄ (Ph represents a phenyl group), or alcohol. n represents an integer from 1 to 4.)

L represents a ligand coordinated on copper. The ligand is not specifically limited so long as it can coordinate on an copper ion, and preferably has a substituent containing C, N, O or S as an atom capable of coordinating on copper, and more preferably has a group containing lone pairs on N, O or S. Compounds capable of forming the ligand are exemplified by those having carboxylic acid, carbonyl (ester, ketone), phosphoric acid, sulfonic acid, amine, amide, sulfonamide, urethane, urea, alcohol or thiol, and preferably exemplified by those having carboxylic acid, carbonyl (ester, ketone), phosphoric acid, sulfonic acid or amine, and furthermore preferably exemplified by those having the carboxylic acid, carbonyl (ester, ketone), phosphoric acid or amine. The coordinatable group contained in a molecule is not only limited to a single species, but may be two or more species, and may be in a dissociated state or in a non-dissociated state. When dissociated, there is no X.

X is absent, or represents a halogen atom (fluorine atom, chlorine atom, bromine atom, and iodine atom), H₂O, NO₃, ClO₄, SO₄, CN, SCN, BF₄, PF₆, BPh₄ (Ph represents a phenyl group) or alcohol, and preferably represents NO₃, ClO₄, SO₄, SCN, BF₄, PF₆ or BPh₄.

n represents an integer from 1 to 4, and preferably from 1 to 2.

Among the compounds which configure the ligands used in the present invention, phosphoric acid ester compounds are preferable, and compounds represented by the formula below (1) are more preferable.

(HO)ₙ—P(═O)—(OR²)₃₋ₙ Formula (1)

(in the formula, each R² represents a C₁₋₁₈ alkyl group, C₆₋₁₈ aryl group. C₁₋₁₈ aralkyl group, or C₁₋₁₈ alkenyl group, or each —OR² represents a C₄₋₁₀₀ polyoxyalkyl group, C₄₋₁₀₀ (meth)acryloyloxyalkyl group, or C₄₋₁₀₀ (meth)acryloylpolyoxyalkyl group, and n represents 1 or 2.)

When n is 1, (R²)s may be same with, or different from each other.

In the formula, at least one —OR² preferably represents a C₄₋₁₀₀ (meth)acryloyloxyalkyl group, or C₄₋₁₀₀ (meth)acryloylpolyoxyalkyl group, and more preferably represents a C₄₋₁₀₀ (meth)acryloyloxyalkyl group.

The C₄₋₁₀₀ polyoxyalkyl group, C₄₋₁₀₀ (meth)acryloyloxyalkyl group, or C₄₋₁₀₀ (meth)acryloylpolyoxyalkyl group preferably has 4 to 20 carbon atoms, and more preferably has 4 to 10 carbon atoms.

In the formula (1), R² is preferably a C₁₋₁₈ alkyl group or C₆₋₁₈ aryl group, more preferably a C₁₋₁₀ alkyl group or C₆₋₁₀ aryl group, furthermore preferably a C₆₋₁₀ aryl group, and particularly a phenyl group.

In the present invention, when n is 1, one of R² exists preferably in the form of —OR² which preferably represents a C₄₋₁₀₀ (meth)acryloyloxyalkyl group, or C₄₋₁₀₀ (meth)acryloylpolyoxyalkyl group, and the other of R² preferably exists in the form of —OR² or represents alkyl group.

The copper phosphate compound used in the present invention preferably has a molecular weight of 300 to 1,500, and more preferably 320 to 900.

Specific examples of the compounds which configure the ligands include Exemplary Compounds (A-1) to (A-219) listed below:

TABLE 1

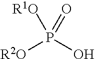

| | R¹ | R² |
|---|---|---|
| A-1 | H | 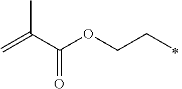 |
| A-2 | 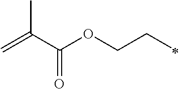 | 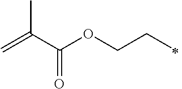 |
| A-3 | H | 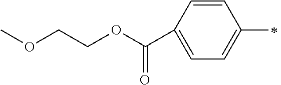 |
| A-4 | 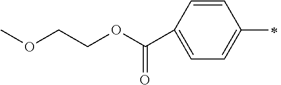 | 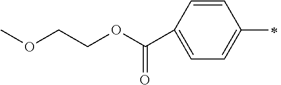 |
| A-5 | 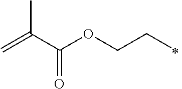 | 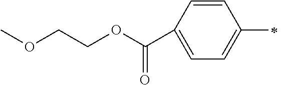 |
| A-6 | H | —CH₃ |
| A-7 | —CH₃ | —CH₃ |
| A-8 | H | —CH₂CH₃ |
| A-9 | —CH₂CH₃ | —CH₂CH₃ |
| A-10 | H | —CH(CH₃)₂ |
| A-11 | —CH(CH₃)₂ | —CH(CH₃)₂ |
| A-12 | H | —CH₂(CH₂)₂CH₃ |
| A-13 | —CH₂(CH₂)₂CH₃ | —CH₂(CH₂)₂CH₃ |
| A-14 | H | —CH₂CH₂OCH₂(CH₂)₂CH₃ |
| A-15 | —CH₂CH₂OCH₂(CH₂)₂CH₃ | —CH₂CH₂OCH₂(CH₂)₂CH₃ |
| A-16 | H | 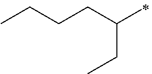 |
| A-17 | 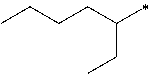 | 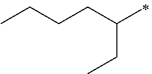 |
| A-18 | H | —CH₂(CH₂)₈CH₃ |
| A-19 | —CH₂(CH₂)₈CH₃ | —CH₂(CH₂)₈CH₃ |
| A-20 | H | —CH₂(CH₂)₆CH(CH₃)₂ |

In the table, “*” indicates a site of bonding with an oxygen atom.

TABLE 2

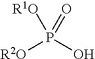

| | R¹ | R² |
|---|---|---|
| A-21 | —CH₂(CH₂)₆CH(CH₃)₂ | —CH₂(CH₂)₆CH(CH₃)₂ |
| A-22 | H | 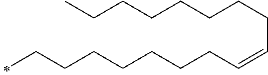 |
| A-23 | 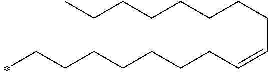 | 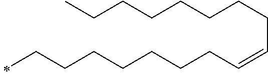 |
| A-24 | H | —CH₂(CH₂)₁₄CH(CH₃)₂ |
| A-25 | —CH₂(CH₂)₁₄CH(CH₃)₂ | —CH₂(CH₂)₁₄CH(CH₃)₂ |
| A-26 | H | —C₆H₅ |
| A-27 | —C₆H₅ | —C₆H₅ |
| A-28 | H | —CH₂CH₂OCH₃ |
| A-29 | —CH₂CH₂CH₃ | —CH₂CH₂OCH₃ |
| A-30 | H | —CH₂CH₂OCH₂CH₃ |
| A-31 | —CH₂CH₂OCH₂CH₃ | —CH₂CH₂OCH₂CH₃ |
| A-32 | H | —(C₂H₄O)₂C₂H₅ |
| A-33 | —(C₂H₄O)₂C₂H₅ | —(C₂H₄O)₂C₂H₅ |
| A-34 | H | —(C₂H₄O)₂C₄H₉ |
| A-35 | —(C₂H₄O)₂C₄H₉ | —(C₂H₄O)₂C₄H₉ |
| A-36 | H | —C₂H₄OCH₂CHCH₃)₂ |
| A-37 | —C₂H₄OCH₂CHCH₃)₂ | —C₂H₄OCH₂CHCH₃)₂ |
| A-38 | H | —(C₂H₄O)₂CH₂CHCH₃)₂ |
| A-39 | —(C₂H₄O)₂CH₂CHCH₃)₂ | —(C₂H₄O)₂CH₂CHCH₃)₂ |
| A-40 | H | —CH(CH₃)CH₂OCH₃ |

In the table, “*” indicates a site of bonding with an oxygen atom.

TABLE 3

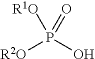

| | R¹ | R² |
|---|---|---|
| A-41 | H | —CH(CH₃)CH₂OCH₃ |
| A-42 | —CH(CH₃)CH₂CH₃ | —CH(CH₃)CH₂OCH₃ |
| A-43 | H | —(CH(CH₃)CH₂O)₂CH₃ |
| A-44 | —(CH(CH₃)CH₂O)₂CH₃ | —(CH(CH₂)CH₂O)₂CH₃ |
| A-45 | H | —(CH(CH₃)CH₂O)₃CH₃ |
| A-46 | —(CH(CH₃)CH₂O)₃CH₃ | —(CH(CH₃)CH₂O)₃CH₃ |
| A-47 | H | —CH₂CH(CH₃)OCH₃ |
| A-48 | —CH₂CH(CH₃)OCH₃ | —CH₂CH(CH₃)OCH₃ |
| A-49 | H | —(CH₂CH(CH₃)O)₂CH₃ |
| A-50 | —(CH₂CH(CH₃)O)₂CH₃ | —(CH₂CH(CH₃)O)₂CH₃ |
| A-51 | H | —(CH₂CH(CH₃)O)₃CH₃ |
| A-52 | —(CH₂CH(CH₃)O)₃CH₃ | —(CH₂CH(CH₃)O)₃CH₃ |
| A-53 | H | —CH(CH₃)CH₂OC(═O)CH₃ |
| A-54 | —CH(CH₃)CH₂OC(═O)CH₃ | —CH(CH₃)CH₂OC(═O)CH₃ |
| A-55 | H | —CH₂CH(CH₃)OC(═O)CH₃ |
| A-56 | —CH₂CH(CH₃)OC(═O)CH₃ | —CH₂CH(CH₃)OC(═O)CH₃ |
| A-57 | —CH₂CH(CH₃)OC(═O)CH₃ | —CH(CH₃)CH₂OC(═O)CH₃ |
| A-58 | H | —CH(CH₃)CH₂OC(═O)CH₂CH₃ |
| A-59 | —CH(CH₃)CH₂OC(═O)CH₂CH₃ | —CH(CH₃)CH₂OC(═O)CH₂CH₃ |
| A-60 | H | —CH₂CH(CH₃)OC(═O)CH₂CH₃ |

TABLE 4

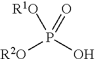

| | R¹ | R² |
|---|---|---|
| A-61 | —CH₂CH(CH₃)OC(═O)CH₂CH₃ | —CH₂CH(CH₃)OC(═O)CH₂CH₃ |
| A-62 | —CH₂CH(CH₃)OC(═O)CH₂CH₃ | —CH(CH₃)CH₂OC(═O)CH₂CH₃ |
| A-63 | H | —CH(CH₂CH₃)CH₂OC(═O)CH₃ |
| A-64 | —CH(CH₂CH₃)CH₂OC(═O)CH₃ | —CH(CH₂CH₃)OC(═O)CH₃ |
| A-65 | H | —CH₂CH(CH₂CH₃)OC(═O)CH₃ |
| A-66 | —CH₂CH(CH₂CH₃)OC(═O)CH₃ | —CH₂CH(CH₂CH₃)OC(═O)CH₃ |
| A-67 | —CH(CH₂CH₃)CH₂OC(═O)CH₃ | —CH₂CH(CH₂CH₃)OC(═O)CH₃ |
| A-68 | H | —CH(CH₂CH₃)CH₂OC(═O)CH₂CH₃ |
| A-69 | —CH(CH₂CH₃)CH₂OC(═O)CH₂CH₃ | —CH(CH₂CH₃)CH₂OC(═O)CH₂CH₃ |
| A-70 | H | —CH₂CH(CH₂CH₃)OC(═O)CH₂CH₃ |
| A-71 | —CH₂CH(CH₂CH₃)OC(═O)CH₂CH₃ | —CH₂CH(CH₂CH₃)OC(═O)CH₂CH₃ |
| A-72 | —CH(CH₂CH₃)CH₂OC(═O)CH₂CH₃ | —CH₂CH(CH₂CH₃)OC(═O)CH₂CH₃ |
| A-73 | H | —CH(CH₃)CH₂OC(=O)CH(CH₃)₂ |
| A-74 | —CH(CH₃)CH₂OC(═O)CH(CH₃)₂ | —CH(CH₃)CH₂OC(═O)(CH₃)₂ |
| A-75 | H | —CH₂CH(CH₃)OC(═O)CH(CH₃)₂ |
| A-76 | —CH₂CH(CH₃)OC(═O)CH(CH₃)₂ | —CH₂CH(CH₃)OC(═O)CH(CH₃)₂ |
| A-77 | —CH₂CH(CH₃)OC(═O)CH(CH₃)₂ | —CH(CH₃)CH₂OC(═O)CH(CH₃)₂ |
| A-78 | H | —CH(CH₂CH₃)CH₂OC(═O)CH(CH₃)₂ |
| A-79 | —CH(CH₂CH₃)CH₂OC(═O)CH(CH₃)₂ | —CH(CH₂CH₃)CH₂OC(═O)CH(CH₃)₂ |
| A-80 | H | —CH₂CH(CH₂CH₃)OC(═O)CH(CH₃)₂ |

TABLE 5

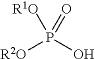

| | R¹ | R² |
|---|---|---|
| A-81 | —CH₂CH(CH₂CH₃)OC(═O)CH(CH₃)₂ | —CH₂CH(CH₂CH₃)OC(═O)CH(CH₃)₂ |
| A-82 | —CH₂CH(CH₂CH₃)OC(═O)CH(CH₃)₂ | —CH(CH₂CH₃)CH₂OC(═O)CH(CH₃)₂ |
| A-83 | —(CH(CH₂CH₃)CH₂O)₂C(═O)CH₃ | H |
| A-84 | —(CH(CH₂CH₃)CH₂O)₂C(═O)CH₃ | —(CH(CH₂CH₃)CH₂O)₂C(═O)CH₃ |
| A-85 | H | —CH(CH₃)CH₂C(═O)OCH₃ |
| A-86 | —CH(CH₃)CH₂C(═O)OCH₃ | —CH(CH₃)CH₂C(═O)OCH₃ |
| A-87 | H | —CH(CH₃)CH₂C(═O)OCH₂CH₃ |
| A-88 | —CH(CH₃)CH₂C(═O)OCH₂CH₃ | —CH(CH₃)CH₂C(═O)OCH₂CH₃ |
| A-89 | H | —CH₂CH(CH₃)C(═O)OCH₃ |
| A-90 | —CH₂CH(CH₃)C(═O)OCH₃ | —CH₂CH(CH₃)C(═O)OCH₃ |
| A-91 | H | —CH₂C(CH₃)₂C(═O)OCH₃ |
| A-92 | —CH₂C(CH₃)₂C(═O)OCH₃ | —CH₂C(CH₃)₂C(═O)OCH₃ |
| A-93 | —CH₂CH(C₂H₅)CH₂CH₂CH₂CH₃ | —CH₂CH(C₂H₅)CH₂CH₂CH₂CH₃ |
| A-94 | H | —CH(CH₃)CH₂OC₆H₅ |
| A-95 | H | —CH₂CH(CH₃)OC₆H₅ |
| A-96 | —CH₂CH(CH₃)OC₆H₅ | —CH₂CH(CH₃)OC₆H₅ |
| A-97 | —CH(CH₃)CH₂OC₆H₅ | —CH₂CH(CH₃)OC₆H₅ |
| A-98 | —CH(CH₃)CH₂OC₆H₅ | —CH(CH₃)CH₂OC₆H₅ |
| A-99 | H | —CH(CH₂OCH₃)CH₂OC₆H₅ |
| A-100 | —CH(CH₂OCH₃)CH₂OC₆H₅ | —CH(CH₂OCH₃)CH₂OC₆H₅ |

TABLE 6

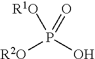

| | R¹ | R² |
|---|---|---|
| A-101 | H | —CH₂CH₂CH(CH₃)OCH₃ |
| A-102 | —CH₂CH₂CH(CH₃)OCH₃ | —CH₂CH₂CH(CH₃)OCH₃ |
| A-103 | H | 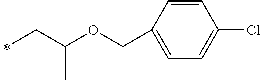 |
| A-103 | H | 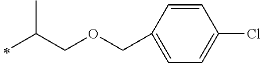 |
| A-104 | 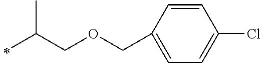 | 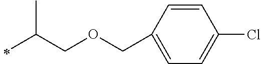 |
| A-105 | 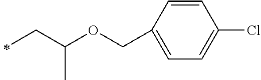 | 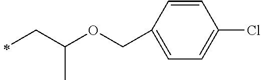 |
| A-106 | 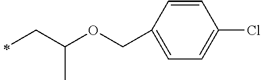 | 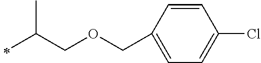 |

TABLE 7

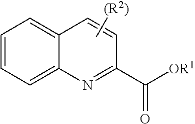

| | R¹ | R² |
|---|---|---|
| A-107 | H | H |
| A-108 | —CH₃ | H |
| A-109 | 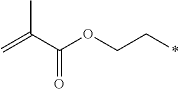 [SMILES: *CCOC(=O)C(=C)C] | H |
| A-110 | —CH₃ | —COCH₃ |
| A-111 | 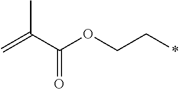 [SMILES: *CCOC(=O)C(=C)C] | 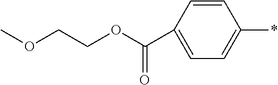 [SMILES: *c1ccc(C(=O)OCCOC)cc1] |
| A-112 | 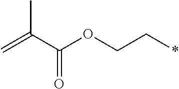 [SMILES: *CCOC(=O)C(=C)C] | —COCH₃ |

In the table, “*” indicates a site of bonding with the formula above.

TABLE 8

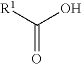

| | R¹ | R² |
|---|---|---|
| A-113 | —CH₃ | — |
| A-114 | —C₆H₅ | — |
| A-115 | 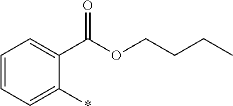 [SMILES: *c1ccccc1C(=O)OCCCC] | — |
| A-116 | 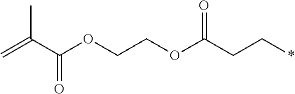 [SMILES: *CCC(=O)OCCOC(=O)C(=C)C] | — |
| A-117 | CH₂═CH (Me)— | — |
| A-118 | H | — |
| A-119 | —n-C₁₇H₃₅ | — |
| A-120 | 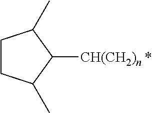 | — |
| A-121 | 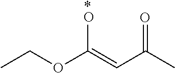 | — |
| A-122 | 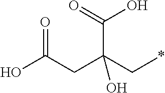 [SMILES: *CC(O)(CC(=O)O)C(=O)O] | — |

In the table, “*” indicates a site of bonding with a COOH group.

TABLE 9

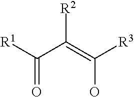

| | R¹ | R² | R³ |
|---|---|---|---|
| A-123 | CH₃ | H | C₆H₅ |
| A-124 | C₆H₅ | H | C₆H₅ |
| A-125 | CH₃ | CH₃ | C₆H₅ |
| A-126 | CH₂(CH₂)₂CH₃ | CH₃ | C₆H₅ |
| A-127 | CH₂(CH₂)₂CH₃ | CH₃ | 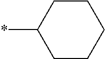 [SMILES: *C1CCCCC1] |

| | | |
|---|---|---|
| A-128 | H | 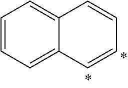 |

In the table, “*” indicates a site of bonding with the formula above.

TABLE 10

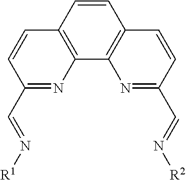

| | R¹ | R² |
|---|---|---|
| A-129 | 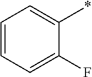 [SMILES: *c1ccccc1F] | 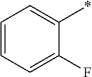 [SMILES: *c1ccccc1F] |
| A-130 | 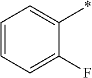 [SMILES: *c1ccccc1F] | 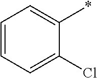 [SMILES: *c1ccccc1Cl] |
| A-131 | 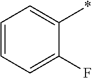 [SMILES: *c1ccccc1F] | 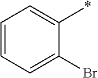 [SMILES: *c1ccccc1Br] |
| A-132 | 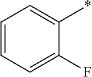 [SMILES: *c1ccccc1F] | 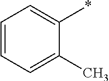 [SMILES: *c1ccccc1C] |
| A-133 | 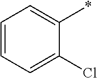 [SMILES: *c1ccccc1Cl] | 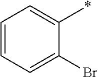 [SMILES: *c1ccccc1Br] |
| A-134 | 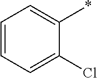 [SMILES: *c1ccccc1Cl] | 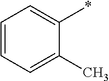 [SMILES: *c1ccccc1C] |
| A-135 | 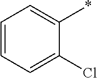 [SMILES: *c1ccccc1Cl] | 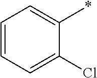 [SMILES: *c1ccccc1Cl] |
| A-136 | 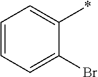 [SMILES: *c1ccccc1Br] | 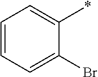 [SMILES: *c1ccccc1Br] |
| A-137 | 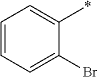 [SMILES: *c1ccccc1Br] | 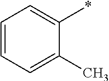 [SMILES: *c1ccccc1C] |
| A-138 | 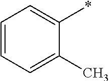 [SMILES: *c1ccccc1C] | 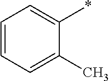 [SMILES: *c1ccccc1C] |

In the table,“*” indicates a site of bonding with a nitrogen atom.

TABLE 11

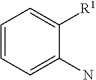

| | R¹ |
|---|---|
| A-139 | OH |
| A-140 | OCH₃ |
| A-141 | SCH₃ |

TABLE 12

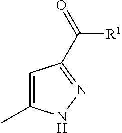

| | R¹ |
|---|---|
| A-142 | 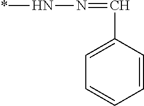 [SMILES: *NN=Cc1ccccc1] |

In the table, “*” indicates a site of bonding with the formula above.

TABLE 13

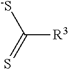

| | R³ |
|---|---|
| A-143 | 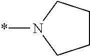 [SMILES: *N1CCCC1] |
| A-144 | 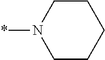 [SMILES: *N1CCCCC1] |
| A-145 | 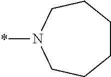 [SMILES: *N1CCCCCC1] |
| A-146 | 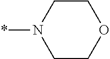 [SMILES: *N1CCOCC1] |
| A-147 | 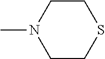 |
| A-148 | 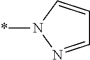 [SMILES: *n1cccn1] |
| A-149 | 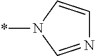 [SMILES: *n1ccnc1] |
| A-150 | 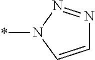 [SMILES: *n1ccnn1] |
| A-151 | 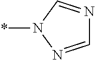 [SMILES: *n1cncn1] |

In the table, “*” indicates a site of bonding with the formula above.

TABLE 14

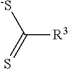

| | R³ |
|---|---|
| A-152 | 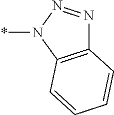 [SMILES: *n1nnc2ccccc21] |
| A-153 | 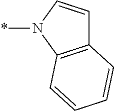 [SMILES: *n1ccc2ccccc21] |
| A-154 | 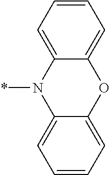 [SMILES: *N1c2ccccc2Oc2ccccc21] |
| A-155 | 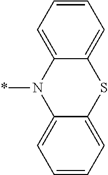 [SMILES: *N1c2ccccc2Sc2ccccc21] |
| A-156 | 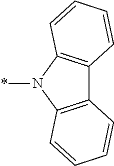 [SMILES: *n1c2ccccc2c2ccccc21] |
| A-157 | 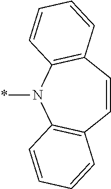 [SMILES: *N1c2ccccc2C=Cc2ccccc21] |

In the table, “*” indicates a site of bonding with the formula above.

TABLE 15

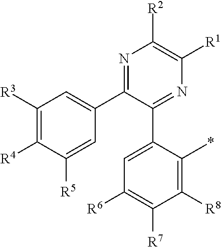

| | R¹ | R² | R³ | R⁴ | R⁵ | R⁶ | R⁷ | R⁸ |
|---|---|---|---|---|---|---|---|---|
| A-158 | H | H | H | F | H | H | F | H |
| A-159 | H | H | H | CF₃ | H | H | CF₃ | H |
| A-160 | H | H | H | CN | H | H | CN | H |
| A-161 | H | H | H | COOCH₃ | H | H | COOCH₃ | H |
| A-162 | CH₃ | CH₃ | H | F | H | H | F | H |
| A-163 | CH₃ | CH₃ | H | CF₃ | H | H | CF₃ | H |
| A-164 | CH₃ | CH₃ | H | CN | H | H | CN | H |
| A-165 | CH₃ | CH₃ | H | COOCH₃ | H | H | COOCH₃ | H |
| A-166 | H | CH₃ | H | F | H | H | F | H |
| A-167 | H | CH₃ | H | CF₃ | H | H | CF₃ | H |
| A-168 | H | CH₃ | H | CN | H | H | CN | H |
| A-169 | H | CH₃ | H | COOCH₃ | H | H | COOCH₃ | H |
| A-170 | H | H | F | H | F | F | H | F |
| A-171 | H | H | CF₃ | H | CF₃ | CF₃ | H | CF₃ |
| A-172 | H | H | CN | H | CN | CN | H | CN |
| A-173 | H | H | CN | COOCH₃ | CN | CN | COOCH₃ | CN |
| A-174 | CH₃ | CH₃ | F | H | F | F | H | F |
| A-175 | CH₃ | CH₃ | CF₃ | H | CF₃ | CF₃ | H | CF₃ |
| A-176 | CH₃ | CH₃ | CN | H | CN | CN | H | CN |
| A-177 | CH₃ | CH₃ | COOCH₃ | H | COOCH₃ | COOCH₃ | H | COOCH₃ |
| A-178 | H | CH₃ | F | H | F | F | H | F |
| A-179 | H | CH₃ | CF₃ | H | CF₃ | CF₃ | H | CF₃ |
| A-180 | H | CH₃ | CN | H | CN | CN | H | CN |
| A-181 | H | CH₃ | COOCH₃ | H | COOCH₃ | COOCH₃ | H | COOCH₃ |

In the table, “*” indicates a site of bonding with a metal atom.

TABLE 16

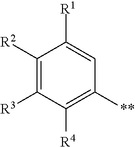

| | R¹ | R² | R³ | R⁴ |
|---|---|---|---|---|
| A-182 | H | H | H | 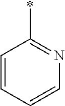 [SMILES: *c1ccccn1] |
| A-183 | H | H | H | 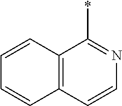 [SMILES: *c1nccc2ccccc12] |
| A-184 | H | H | H | 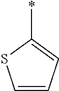 [SMILES: *c1cccs1] |
| A-185 | H | H | H | 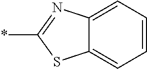 [SMILES: *c1nc2ccccc2s1] |
| A-186 | H | H | H | 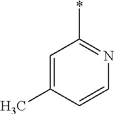 [SMILES: *c1cc(C)ccn1] |
| A-187 | H | H | H | 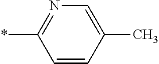 [SMILES: *c1ccc(C)cn1] |
| A-188 | H | H | H | 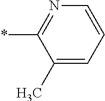 [SMILES: *c1ncccc1C] |
| A-189 | H | H | H | 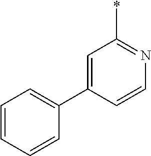 [SMILES: *c1cc(-c2ccccc2)ccn1] |

In the table, “*” indicates a site of bonding with the formula above.
In the table, “**” indicates a site of bonding with a metal atom.

TABLE 17

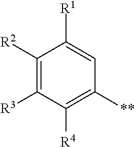

| | R¹ | R² | R³ | R⁴ |
|---|---|---|---|---|
| A-190 | H | H | H | 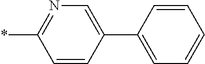 [SMILES: *c1ccc(-c2ccccc2)cn1] |
| A-191 | H | H | H | 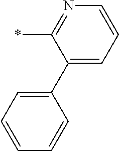 [SMILES: *c1ncccc1-c1ccccc1] |
| A-192 | H | CH₃ | H | 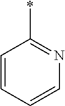 [SMILES: *c1ccccn1] |
| A-193 | CH₃ | H | H | 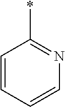 [SMILES: *c1ccccn1] |
| A-194 | H | H | CH₃ | 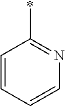 [SMILES: *c1ccccn1] |
| A-195 | H | C₆H₅ | H | 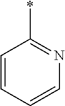 [SMILES: *c1ccccn1] |
| A-196 | C₆H₅ | H | H | 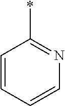 [SMILES: *c1ccccn1] |
| A-197 | H | H | C₆H₅ | 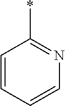 [SMILES: *c1ccccn1] |

In the table, “*” indicates a site of bonding with the formula above.
In the table, “**” indicates a site of bonding with a metal atom.

TABLE 18

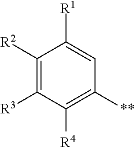

| | R¹ | R² | R³ | R⁴ |
|---|---|---|---|---|
| A-198 | F | H | H | 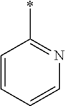 [SMILES: *c1ccccn1] |
| A-199 | CF₃ | H | H | 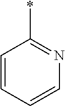 [SMILES: *c1ccccn1] |
| A-200 | F | H | H | 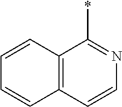 [SMILES: *c1nccc2ccccc12] |
| A-201 | CH₂CH₃ | H | H | 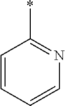 [SMILES: *c1ccccn1] |
| A-202 | n-C₃H₇ | H | H | 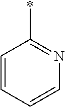 [SMILES: *c1ccccn1] |
| A-203 | n-C₄H₉ | H | H | 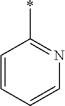 [SMILES: *c1ccccn1] |
| A-204 | n-C₃H₇ | H | H | 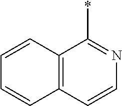 [SMILES: *c1nccc2ccccc12] |
| A-205 | n-C₄H₉ | H | H | 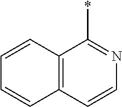 [SMILES: *c1nccc2ccccc12] |
| A-206 | n-C₆H₁₃ | H | H | 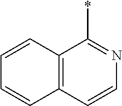 [SMILES: *c1nccc2ccccc12] |

In the table, “*” indicates a site of bonding with the formula above.
In the table, “**” indicates a site of bonding with a metal atom.

TABLE 19

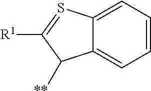

| | R¹ |
|---|---|
| A-207 | 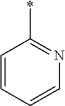 [SMILES: *c1ccccn1] |
| A-208 | 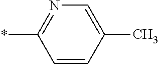 [SMILES: *c1ccc(C)cn1] |
| A-209 | 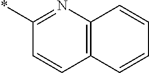 [SMILES: *c1ccc2ccccc2n1] |
| A-210 | 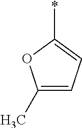 [SMILES: *c1ccc(C)o1] |
| A-211 | 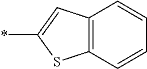 [SMILES: *c1cc2ccccc2s1] |
| A-212 | 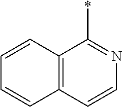 [SMILES: *c1nccc2ccccc12] |
| A-213 | C₆H₅ |

In the table, “*” indicates a site of bonding with the formula above.
In the table, “**” indicates a site of bonding with a metal atom.

TABLE 20

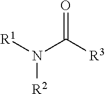

| | R¹ | R² | R³ |
|---|---|---|---|
| A-214 | CH₃ | CH₃ | H |

TABLE 21

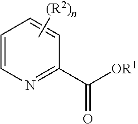

| | R¹ | R² |
|---|---|---|
| A-215 | H | H |
| A-216 | CH₃ | H |
| A-217 | 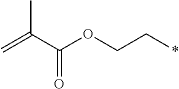 [SMILES: *CCOC(=O)C(=C)C] | H |
| A-218 | CH₃ | COCH₃ |
| A-219 | 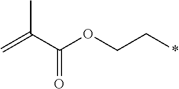 [SMILES: *CCOC(=O)C(=C)C] | COCH₃ |

In the table, “*” indicates a site of bonding with an oxygen atom.

The compounds which configure the ligands may be synthesized referring to publicly known methods. For example, the phosphoric acid ester shown below may be obtained by adding triethylamine to a tetrahydrofuran (THF) solution of 2,4-dimethylpentanol, stirring the mixture at 0° C. for 5 minutes, dropping thereinto phosphorus oxychloride, and stirring the mixture at room temperature for 6 hours to thereby complete the reaction. Upon completion of the reaction, the reaction liquid is poured into water so as not to elevate the temperature by 30° C. or more, separated in a chloroform/water system, and the solvent in the organic layer is distilled off to thereby obtain the phosphoric acid ester shown below:

### [Chemical Formula 2]

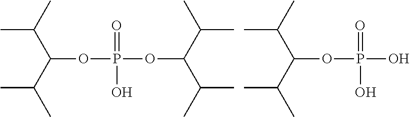

In the synthesis of the phosphate-copper complex compound, also commercially available phosphonic acids under the trade names of Phosmer M, Phosmer PE and Phosmer PP (from Uni-Chemical Co. Ltd.) may be used.

The copper salt used herein preferably contains divalent or trivalent copper, and more preferably divalent copper. Preferable examples of the copper salt include copper acetate, copper chloride, copper formate, copper stearate, copper benzoate, copper ethyl acetoacetate, copper pyrophosphate, copper naphthenate, copper citrate, copper nitrate, copper sulfate, copper carbonate, copper chlorate and copper (meth)acrylate, and more preferable examples include copper benzoate and copper (meth)acrylate.

Specific examples of the copper complex used in the present invention include Exemplary Compounds (Cu-1) to (Cu-219) shown below. The present invention is, of course, not limited to these compounds.

TABLE 22
Cu (L)ₙ · X Formula (1)

| | L | n | X |
|---|---|---|---|
| Cu-1 | A-1 | 2 | — |
| Cu-2 | A-2 | 2 | — |
| Cu-3 | A-3 | 2 | — |
| Cu-4 | A-4 | 2 | — |
| Cu-5 | A-5 | 2 | — |
| Cu-6 | A-6 | 2 | — |
| Cu-7 | A-7 | 2 | — |
| Cu-8 | A-8 | 2 | — |
| Cu-9 | A-9 | 2 | — |
| Cu-10 | A-10 | 2 | — |
| Cu-11 | A-11 | 2 | — |
| Cu-12 | A-12 | 2 | — |
| Cu-13 | A-13 | 2 | — |
| Cu-14 | A-14 | 2 | — |
| Cu-15 | A-15 | 2 | — |
| Cu-16 | A-16 | 2 | — |
| Cu-17 | A-17 | 2 | — |
| Cu-18 | A-18 | 2 | — |
| Cu-19 | A-19 | 2 | — |
| Cu-20 | A-20 | 2 | — |

TABLE 23
Cu (L)ₙ · X formula (1)

| | L | n | X |
|---|---|---|---|
| Cu-21 | A-21 | 2 | — |
| Cu-22 | A-22 | 2 | — |
| Cu-23 | A-23 | 2 | — |
| Cu-24 | A-24 | 2 | — |
| Cu-25 | A-25 | 2 | — |
| Cu-26 | A-26 | 2 | — |
| Cu-27 | A-27 | 2 | — |
| Cu-28 | A-28 | 2 | — |
| Cu-29 | A-29 | 2 | — |
| Cu-30 | A-30 | 2 | — |
| Cu-31 | A-31 | 2 | — |
| Cu-32 | A-32 | 2 | — |
| Cu-33 | A-33 | 2 | — |
| Cu-34 | A-34 | 2 | — |
| Cu-35 | A-35 | 2 | — |
| Cu-36 | A-36 | 2 | — |
| Cu-37 | A-37 | 2 | — |
| Cu-38 | A-38 | 2 | — |
| Cu-39 | A-39 | 2 | — |
| Cu-40 | A-40 | 2 | — |

TABLE 24
Cu (L)ₙ · X formula (1)

| | L | n | X |
|---|---|---|---|
| Cu-41 | A-41 | 2 | — |
| Cu-42 | A-42 | 2 | — |
| Cu-43 | A-43 | 2 | — |
| Cu-44 | A-44 | 2 | — |
| Cu-45 | A-45 | 2 | — |
| Cu-46 | A-46 | 2 | — |
| Cu-47 | A-47 | 2 | — |
| Cu-48 | A-48 | 2 | — |
| Cu-49 | A-49 | 2 | — |
| Cu-50 | A-50 | 2 | — |
| Cu-51 | A-51 | 2 | — |
| Cu-52 | A-52 | 2 | — |
| Cu-53 | A-53 | 2 | — |
| Cu-54 | A-54 | 2 | — |
| Cu-55 | A-55 | 2 | — |
| Cu-56 | A-56 | 2 | — |
| Cu-57 | A-57 | 2 | — |
| Cu-58 | A-58 | 2 | — |
| Cu-59 | A-59 | 2 | — |
| Cu-60 | A-60 | 2 | — |

TABLE 25
Cu (L)ₙ · X formula (1)

| | L | n | X |
|---|---|---|---|
| Cu-61 | A-61 | 2 | — |
| Cu-62 | A-62 | 2 | — |
| Cu-63 | A-63 | 2 | — |
| Cu-64 | A-64 | 2 | — |
| Cu-65 | A-65 | 2 | — |
| Cu-66 | A-66 | 2 | — |
| Cu-67 | A-67 | 2 | — |
| Cu-68 | A-68 | 2 | — |
| Cu-69 | A-69 | 2 | — |
| Cu-70 | A-70 | 2 | — |
| Cu-71 | A-71 | 2 | — |
| Cu-72 | A-72 | 2 | — |
| Cu-73 | A-73 | 2 | — |
| Cu-74 | A-74 | 2 | — |
| Cu-75 | A-75 | 2 | — |
| Cu-76 | A-76 | 2 | — |
| Cu-77 | A-77 | 2 | — |
| Cu-78 | A-78 | 2 | — |
| Cu-79 | A-79 | 2 | — |
| Cu-80 | A-80 | 2 | — |

TABLE 26
Cu (L)ₙ · X formula (1)

| | L | n | X |
|---|---|---|---|
| Cu-81 | A-81 | 2 | — |
| Cu-82 | A-82 | 2 | — |
| Cu-83 | A-83 | 2 | — |
| Cu-84 | A-84 | 2 | — |
| Cu-85 | A-85 | 2 | — |
| Cu-86 | A-86 | 2 | — |
| Cu-87 | A-87 | 2 | — |
| Cu-88 | A-88 | 2 | — |
| Cu-89 | A-89 | 2 | — |
| Cu-90 | A-90 | 2 | — |
| Cu-91 | A-91 | 2 | — |
| Cu-92 | A-92 | 2 | — |
| Cu-93 | A-93 | 2 | — |
| Cu-94 | A-94 | 2 | — |
| Cu-95 | A-95 | 2 | — |
| Cu-96 | A-96 | 2 | — |
| Cu-97 | A-97 | 2 | — |
| Cu-98 | A-98 | 2 | — |
| Cu-99 | A-99 | 2 | — |
| Cu-100 | A-100 | 2 | — |

TABLE 27
Cu (L)ₙ · X formula (1)

| | L | n | X |
|---|---|---|---|
| Cu-101 | A-101 | 2 | — |
| Cu-102 | A-102 | 2 | — |
| Cu-103 | A-103 | 2 | — |
| Cu-103 | A-103 | 2 | — |
| Cu-104 | A-104 | 2 | — |
| Cu-105 | A-105 | 2 | — |
| Cu-106 | A-106 | 2 | — |
| Cu-107 | A-107 | 2 | SO₄ |
| Cu-108 | A-108 | 2 | SO₄ |
| Cu-109 | A-109 | 2 | SO₄ |
| Cu-110 | A-110 | 2 | (NO₃)₂ |
| Cu-111 | A-111 | 2 | (NO₃)₂ |
| Cu-112 | A-112 | 2 | (ClO₄)₂ |
| Cu-113 | A-113 | 2 | — |
| Cu-114 | A-114 | 2 | — |
| Cu-115 | A-115 | 2 | — |
| Cu-116 | A-116 | 2 | — |
| Cu-117 | A-117 | 2 | — |
| Cu-118 | A-118 | 2 | — |
| Cu-119 | A-119 | 2 | — |
| Cu-120 | A-120 | 2 | — |

TABLE 28
Cu (L)ₙ · X formula (1)

| | L | n | X |
|---|---|---|---|
| Cu-121 | A-121 | 2 | — |
| Cu-122 | A-122 | 2 | — |
| Cu-123 | A-123 | 2 | — |
| Cu-124 | A-124 | 2 | — |
| Cu-125 | A-125 | 2 | — |
| Cu-126 | A-126 | 2 | — |
| Cu-127 | A-127 | 2 | — |
| Cu-128 | A-128 | 2 | — |
| Cu-129 | A-129 | 1 | (ClO₄)₂ |
| Cu-130 | A-130 | 1 | (ClO₄)₂ |
| Cu-131 | A-131 | 1 | (ClO₄)₂ |
| Cu-132 | A-132 | 1 | (ClO₄)₂ |
| Cu-133 | A-133 | 1 | (ClO₄)₂ |
| Cu-134 | A-134 | 1 | (ClO₄)₂ |
| Cu-135 | A-135 | 1 | (ClO₄)₂ |
| Cu-136 | A-136 | 1 | (ClO₄)₂ |
| Cu-137 | A-137 | 1 | (ClO₄)₂ |
| Cu-138 | A-138 | 1 | (ClO₄)₂ |
| Cu-139 | A-139 | 2 | — |
| Cu-140 | A-140 | 2 | — |

TABLE 29
Cu (L)ₙ · X formula (1)

| | L | n | X |
|---|---|---|---|
| Cu-141 | A-141 | 2 | — |
| Cu-142 | A-142 | 2 | Cl₂ |
| Cu-143 | A-143 | 2 | — |
| Cu-144 | A-144 | 2 | — |
| Cu-145 | A-145 | 2 | — |
| Cu-146 | A-146 | 2 | — |
| Cu-147 | A-147 | 2 | — |
| Cu-148 | A-148 | 2 | — |
| Cu-149 | A-149 | 2 | — |
| Cu-150 | A-150 | 2 | — |
| Cu-151 | A-151 | 2 | — |
| Cu-152 | A-152 | 2 | — |
| Cu-153 | A-153 | 2 | — |
| Cu-154 | A-154 | 2 | — |
| Cu-155 | A-155 | 2 | — |
| Cu-156 | A-156 | 2 | — |
| Cu-157 | A-157 | 2 | — |
| Cu-158 | A-158 | 2 | — |
| Cu-159 | A-159 | 2 | — |
| Cu-160 | A-160 | 2 | — |

TABLE 30
Cu (L)ₙ · X formula (1)

| | L | n | X |
|---|---|---|---|
| Cu-161 | A-161 | 2 | — |
| Cu-162 | A-162 | 2 | — |
| Cu-163 | A-163 | 2 | — |
| Cu-164 | A-164 | 2 | — |
| Cu-165 | A-165 | 2 | — |
| Cu-166 | A-166 | 2 | — |
| Cu-167 | A-167 | 2 | — |
| Cu-168 | A-168 | 2 | — |
| Cu-169 | A-169 | 2 | — |
| Cu-170 | A-170 | 2 | — |
| Cu-171 | A-171 | 2 | — |
| Cu-172 | A-172 | 2 | — |
| Cu-173 | A-173 | 2 | — |
| Cu-174 | A-174 | 2 | — |
| Cu-175 | A-175 | 2 | — |
| Cu-176 | A-176 | 2 | — |
| Cu-177 | A-177 | 2 | — |
| Cu-178 | A-178 | 2 | — |
| Cu-179 | A-179 | 2 | — |
| Cu-180 | A-180 | 2 | — |

TABLE 31
Cu (L)ₙ · X formula (1)

| | L | n | X |
|---|---|---|---|
| Cu-181 | A-181 | 2 | — |
| Cu-182 | A-182 | 2 | — |
| Cu-183 | A-183 | 2 | — |
| Cu-184 | A-184 | 2 | — |
| Cu-185 | A-185 | 2 | — |
| Cu-186 | A-186 | 2 | — |
| Cu-187 | A-187 | 2 | — |
| Cu-188 | A-188 | 2 | — |
| Cu-189 | A-189 | 2 | — |
| Cu-190 | A-190 | 2 | SO₄ |
| Cu-191 | A-191 | 2 | SO₄ |
| Cu-192 | A-192 | 2 | SO₄ |
| Cu-193 | A-193 | 2 | (NO₃)₂ |
| Cu-194 | A-194 | 2 | (NO₃)₂ |
| Cu-195 | A-195 | 2 | (ClO₄)₂ |
| Cu-196 | A-196 | 2 | Cl₂ |
| Cu-197 | A-197 | 2 | Cl₂ |
| Cu-198 | A-198 | 2 | (CN)₂ |
| Cu-199 | A-199 | 2 | (CN)₂ |
| Cu-200 | A-200 | 2 | SO₄ |

TABLE 32
Cu (L)ₙ · X formula (1)

| | L | n | X |
|---|---|---|---|
| Cu-201 | A-201 | 2 | (NO₃)₂ |
| Cu-202 | A-202 | 2 | (NO₃)₂ |
| Cu-203 | A-203 | 2 | (CN)₂ |
| Cu-204 | A-204 | 2 | (CN)₂ |
| Cu-205 | A-205 | 2 | (ClO₄)₂ |
| Cu-206 | A-206 | 2 | (ClO₄)₂ |
| Cu-207 | A-207 | 2 | SO₄ |
| Cu-208 | A-208 | 2 | SO₄ |
| Cu-209 | A-209 | 2 | (NO₃)₂ |
| Cu-210 | A-210 | 2 | (CN)₂ |
| Cu-211 | A-211 | 2 | (SCN)₂ |
| Cu-212 | A-212 | 2 | (SCN)₂ |
| Cu-213 | A-213 | 2 | Cl₂ |
| Cu-214 | A-214 | 2 | Cl₂ |
| Cu-215 | A-215 | 2 | SO₄ |
| Cu-216 | A-216 | 2 | SO₄ |
| Cu-217 | A-217 | 2 | (NO₃)₂ |
| Cu-218 | A-218 | 2 | (NO₃)₂ |
| Cu-219 | A-219 | 2 | (ClO₄)₂ |

### <Surfactant>

The composition of the present invention contains a surfactant. The surfactant may be a single species, or may be two or more species used in combination. Amount of addition of the surfactant is preferably 0.0001% by mass to 2% by mass of the whole solid content of the composition of the present invention, more preferably 0.005% by mass to 1.0% by mass, and furthermore preferably 0.01 to 0.1% by mass.

Various surfactants usable herein include fluorine-containing surfactant, nonionic surfactant, cationic surfactant, anionic surfactant, and silicone-based surfactant.

In particular, the composition of the present invention, containing at least either one of the fluorine-containing surfactant and silicone-based surfactant, is improved in the liquid characteristics (fluidity, in particular) when prepared in the form of coating liquid, and can further improve uniformity of thickness of coating and can reduce liquid consumption.

In other words, when the film is formed using the coating liquid applied by the composition containing at least either one of the fluorine-containing surfactant and silicone-based surfactant, surface tension between the surface to be coated and the coating liquid may be reduced, wettability on the surface to be coated may be improved, and coatability onto the surface to be coated may be improved. Accordingly, the composition is effective from the viewpoint that a film having a uniform thickness, only with a small irregularity in thickness, may be formed in a more successful manner, even if a small amount of liquid is used to form a thin film of several micrometers thick.

Fluorine content in the fluorine-containing surfactant is preferably 3% by mass to 40% by mass, more preferably 5% by mass to 30% by mass, and particularly 7% by mass to 25% by mass. The fluorine-containing surfactant, having the fluorine content adjusted in the ranges described above, is effective in terms of uniformity of thickness of the coated film and reduction of liquid consumption, and shows good solubility in a colored photosensitive composition.

The fluorine-containing surfactant is exemplified by Megafac F171, ditto F172, ditto F173, ditto F176, ditto F177, ditto F141, ditto F142, ditto F143, ditto F144, ditto R30, ditto F437, ditto F479, ditto F482, ditto F554, ditto F780, ditto R08 (all from DIC Corporation), Fluorad FC430, ditto FC431, ditto FC171 (all from Sumitomo 3M Ltd.), Surflon S-382, ditto S-141, ditto S-145, ditto SC-101, ditto SC-103, ditto SC-104, ditto SC-105, ditto SC1068, ditto SC-381, ditto SC-383, ditto S393, ditto KH-40 (all from Asahi Glass Co. Ltd.), Eftop EF301, ditto EF303, ditto EF351, ditto EF352 (all from JEMCO Inc.), and PF636, PF656, PF6320, PF6520, PF7002 (from OMNOVA Solutions Inc.).

Also polymer having a fluoroaliphatic group is preferable as the fluorine-containing surfactant. The polymer having a fluoroaliphatic group is exemplified by fluorine-containing surfactant having a fluoroaliphatic group obtained from a fluoroaliphatic compound, wherein the fluoroaliphatic group is manufactured by telomerization (also referred to as telomer process), or oligomerization (also referred to as oligomer process).

Now the “telomerization” means a method of allowing a low molecular weight compound to polymerize, to thereby synthesize a compound having in the molecule thereof one to two active groups. On the other hand, the “oligomerization” means a method of converting a monomer or a mixture of monomers into an oligomer.

The fluoroaliphatic group in the present invention is exemplified by —CF₃ group, —C₂F₅ group, —C₃F₇ group, —C₄F₉ group, —C₅F₁₁ group, —C₆F₁₃ group, —C₇F₁₅ group, —C₈F₁₇ group, —C₉F₁₉ group and —C₁₀F₂₁ group. From the viewpoints of compatibility and coatability, —C₂F₅ group, —C₃F₇ group, —C₄F₉ group, —C₅F₁₁ group, —C₆F₁₃ group, —C₇F₁₅ group and —C₈F₁₇ group are more preferable.

The fluoroaliphatic compound in the present invention may be synthesized according to a method described in JP-A-2002-90991.

The polymer having a fluoroaliphatic group in the present invention is preferably a copolymer of the monomer having a fluoroaliphatic group in the present invention and a (poly(oxyalkylene)) acrylate and/or (poly(oxyalkylene)) methacrylate. The copolymer may have a random distribution, or may be a block copolymer. The poly(oxyalkylene) group is exemplified by poly(oxyethylene) group, poly(oxypropylene) group and poly(oxybutylene) group, and may be a unit having alkylenes with different chain length in a single chain, such as poly(block-coupled product of oxyethylene and oxypropylene and oxyethylene) group and poly(block-coupled product of oxyethylene and oxypropylene) group. Moreover, the copolymer of the monomer with a fluoroaliphatic group and (poly(oxyalkylene)) acrylate (or methacrylate) is not limited to a bipolymer, but may be a terpolymer or higher multi-component copolymer obtained by concomitantly copolymerizing two or more different species of monomer with a fluoroaliphatic group and two or more different species of (poly(oxyalkylene)) acrylate (or methacrylate).

Commercially available surfactants, which contain the polymer with a fluoroaliphatic group in the present invention, include those typically described in paragraph [0352] of JP-A-2012-083727, the content of which is incorporated by reference into this specification. Usable examples include Magafac F-781 (from DIC Corporation), copolymer of acrylate (or methacrylate) having a C₆F₁₃ group and (poly(oxyethylene)) acrylate (or methacrylate) and (poly(oxypropylene)) acrylate (or methacrylate), copolymer of acrylate (or methacrylate) having a C₈F₁₇ group and (poly(oxyalkylene)) acrylate (or methacrylate), and copolymer of acrylate (or methacrylate) having a C₈F₁₇ group and (poly(oxyethylene)) acrylate (or methacrylate) and (poly(oxypropylene)) acrylate (or methacrylate).

The nonionic surfactant is specifically exemplified by those described in paragraph [0252] of JP-A-2012-201643, the content of which is incorporated by reference into this specification.

The cationic surfactant is specifically exemplified by those described in paragraph [0253] of JP-A-2012-201643, the content of which is incorporated by reference into this specification.

The anionic surfactant is specifically exemplified by W004, W005 and W017 (from Yusho Co. Ltd.).

The silicone-based surfactant is specifically exemplified by those described in paragraph [0210] of JP-A-2012-173327, the content of which is incorporated by reference into this specification. Other examples include “Toray Silicone SF8410”, “ditto SF8427”, “ditto SH8400”, “ST80PA”, “ST83PA” and “ST86PA” from Dow Corning Toray Co. Ltd., “TSF-400”, “TSF-401”, “TSF-410”, “TSF-4446” from Momentive Performance Materials Inc., and “KP321”, “KP323”, “KP324” and “KP340” from Shin-Etsu Chemical Co. Ltd.

### <Solvent>

The composition of the present invention preferably contains a solvent. Only one species of the solvent, or two or more species thereof may be used. When two or more species are used in combination, the total amount falls in the ranges described above. The content of the solvent is preferably 10 to 65% by mass of the composition, more preferably 20 to 60% by mass of the composition, and particularly 30 to 55% by mass.

The solvent used in the present invention is not specifically limited, and is arbitrarily selectable depending on purposes, so long as it allows the individual components of the composition of the present invention to uniformly dissolve of disperse therein. Preferable examples of the solvent include alcohols, ketones, esters, aromatic hydrocarbons, halogenated hydrocarbons, and dimethylformamide, dimethyl acetamide, dimethyl sulfoxide and sulfolane. Only one species of them, or two or more species thereof may be used in combination. In this case, particularly preferable is a mixed solvent composed of two or more species selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, ethylene glycol monobutyl ether acetate, propylene glycol monomethyl ether, and propylene glycol monomethyl ether acetate.

Specific examples of the alcohols, aromatic hydrocarbons, and halogenated hydrocarbons includes those described in paragraph [0136] of JP-A-2012-194534, the content of which is incorporated by reference into this specification. Specific examples of the esters, ketones and ethers are exemplified by those described in paragraph [0178] of JP-A-2012-201643, and are further exemplified by n-amyl acetate, ethyl propionate, dimethyl phthalate, ethyl benzoate, methyl sulfate, acetone, methyl isobutyl ketone, diethyl ether, and ethylene glycol monobutyl ether acetate.

### <Curable Compound>

The composition of the present invention generally contains a curable compound. It is, however, not always necessary if the copper complex per se is a curable compound, typically as a result of having a polymerizable group. The curable compound may be a polymerizable compound, or a non-polymerizable compound such as binder. The curable compound may also be a heat curable compound or a photo-curable compound, wherein the heat curable compound is more preferable by virtue of its higher reaction rate.

### <Compound Having Polymerizable Group>

The composition of the present invention preferably contains a compound having a polymerizable group (occasionally referred to as “polymerizable compound”, hereinafter). The compound of this sort has widely been known in the related industrial field, and is arbitrarily selectable without special limitation. The compound may have any chemical form selectable from monomer, oligomer, prepolymer and polymer.

The polymerizable compound may be either monofunctional or polyfunctional, where it is preferably polyfunctional. By containing the polyfunctional compound, the composition may further be improved in the near infrared shielding performance and heat resistance. The number of functional groups is preferably 2 to 8, although not specifically limited.

### <<A: Polymerizable Monomer and Polymerizable Oligomer>>

A first preferable embodiment of the composition of the present invention contains a monomer having a polymerizable group (polymerizable monomer) or an oligomer having a polymerizable group (polymerizable oligomer) (the polymerizable monomer and the polymerizable oligomer may collectively be referred to as “polymerizable monomer, etc.”, hereinafter), as the polymerizable compound.

Examples of the polymerizable monomer, etc. include unsaturated carboxylic acid (acrylic acid, methacrylic acid, itaconic acid, crotonic acid, isocrotonic acid, maleic acid, etc.) and esters and amides thereof, and preferably include ester formed between unsaturated carboxylic acid and aliphatic polyhydric alcohol compound, and amide formed between unsaturated carboxylic acid and aliphatic multi-valent amine compound. Also preferably used are adducts of unsaturated carboxylic acid esters or amides having a nucleophilic substituent such as hydroxy group, amino group, or mercapto group, with monofunctional or polyfunctional isocyanates or epoxy compounds; and dehydration condensation products with monofunctional or polyfunctional carboxylic acid. Also preferably used are adducts of unsaturated carboxylic acid esters or amides having an electronphilic substituent such as isocyanate group or epoxy group, with monofunctional or polyfunctional alcohols, amines, or thiols; and substitution products formed between unsaturated carboxylic acid esters or amides having an eliminatable substituent such as halogen group or tosyloxy group, with monofunctional or polyfunctional alcohols, amines, or thiols. Other examples usable herein include compounds obtained by replacing the above-described unsaturated carboxylic acid with unsaturated phosphonic acid, vinylbenzene derivative such as styrene, vinyl ether, allyl ether or the like.

Specific example of these compounds are described in paragraphs to [0108] of JP-A-2009-288705, all of which are also preferably used in the present invention.

The polymerizable monomer, etc. is also preferably a compound having at least one addition-polymerizable ethylene group, and having an ethylenic unsaturated group and showing a boiling point under normal pressure of 100° C. or above. The examples of which include polyfunctional acrylate and methacrylate, and mixture of them, exemplified by monofunctional acrylate and methacrylate such as polyethylene glycol mono(meth)acrylate, polypropylene glycol mono(meth)acrylate, and phenoxyethyl (meth)acrylate; compounds obtained by adding ethylene oxide or propylene oxide to polyfunctional alcohol, followed by conversion into (meth)acrylate, such as polyethylene glycol di(meth)acrylate, trimethylolethane tri(meth)acrylate, neopentylglycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol (meth)acrylate, trimethylolpropane tri(acryloyloxypropyl)ether, tri(acryloyloxyethyl)isocyanurate, glycerin and trimethylolethane; urethane (meth)acrylates such as those described in JP-B-548-41708, JP-B-550-6034 and JP-A-551-37193; polyester acrylates such as those described in JP-A-548-64183, JP-B-549-43191 and JP-B-552-30490; and epoxy acrylates obtained by reacting epoxy polymer with (meth)acrylic acid.

Other examples include polyfunctional (meth)acrylate obtained by reacting polyfunctional carboxylic acid with a compound having a cyclic ether group and an ethylenic unsaturated group, such as glycidyl (meth)acrylate.

Other examples of preferable polymerizable monomer usable herein include compounds having a fluorene ring and two or more ethylenic polymerizable groups, and cardo polymer, such as those described in JP-A-2010-160418, JP-A-2010-129825, Japanese Patent No. 4364216 and so forth.

As the compound having an ethylenic unsaturated group and showing a boiling point under normal pressure of 100° C. or above, also the compounds described in paragraphs [0254] to [0257] of JP-A-2008-292970 are preferable.

Also usable herein as the polymerizable monomer are the compounds obtained by adding ethylene oxide or propylene oxide to polyfunctional alcohol, followed by conversion into (meth)acrylate, such as those represented by the formulae (1) and (2) and specifically enumerated in JP-A-H10-62986.

The polymerizable monomer used in the present invention is more preferably polymerizable monomers represented by the formulae (MO-1) to (MO-6) below:

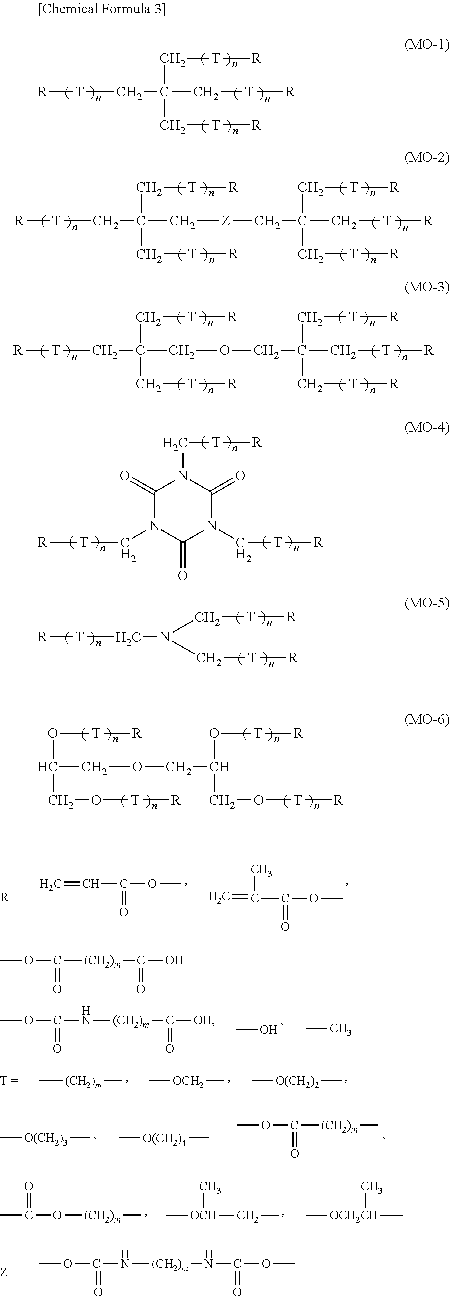

(In the formula, each n represents 0 to 14, and each m represents 1 to 8. A plurality of each of (R)s, (T)s and (Z)s in a single molecule may be same with, or different from each other. When T represents an oxyalkylene group, the carbon terminal thereof is bound to R. At least one of (R)s represents a polymerizable group.)

n is preferably 0 to 5, and more preferably 1 to 3.

m is preferably 1 to 5, and more preferably 1 to 3.

R preferably represents below:

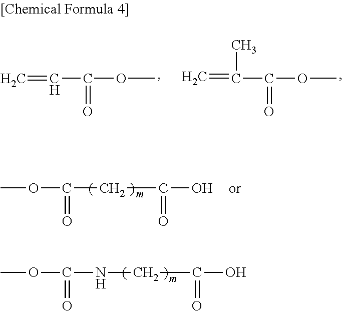

and preferably represents below:

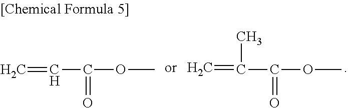

The radical polymerizable monomers represented by the formulae (MO-1) to (MO-6) are specifically exemplified by those described in paragraphs [0248] to [0251] of JP-A-2007-269779, which are also preferably used in the present invention.

In particular, the polymerizable monomer is exemplified by those described in paragraph [0151] of JP-A-2012-201643, the content of which is incorporated by reference into this specification. Diglycerin EO (ethylene oxide)-modified (meth)acrylate (commercially available as M-460, from Toagosei Co. Ltd.) is preferable. Also pentaerythritol tetraacrylate (A-TMMT, from Shin-Nakamura Chemical Co. Ltd.), and 1,6-hexanediol diacrylate (KAYARAD HDDA, from Nippon Kayaku Co. Ltd.) are preferable. Also oligomer type products of these compounds may be used.

The examples include RP-1040 (from Nippon Kayaku Co. Ltd.).

The polymerizable monomer, etc. may also be a multifunctional monomer, and may have an acid group such as carboxyl group, sulfonic acid group, phosphoric acid group or the like. Accordingly, any polymerizable monomer having an unreacted carboxyl group, such as for the case where the ethylenic compound is a mixture as described above, may be used in its intact form, or if necessary, the ethylenic compound may be introduced with an acid group by allowing a hydroxyl group thereof to react with a non-aromatic carboxylic anhydride. Specific examples of the non-aromatic carboxylic anhydride usable herein include tetrahydrophthalic anhydride, alkylated tetrahydrophthalic anhydride, hexahydrophthalic anhydride, alkylated hexahydrophthalic anhydride, succinic anhydride, and maleic anhydride.

In the present invention, the monomer having an acid group is an ester formed between an aliphatic polyhydroxy compound and an unsaturated carboxylic acid, and is preferably a multifunctional monomer introduced with an acid group by allowing an unreacted hydroxyl group of an aliphatic polyhydroxy compound to react with a non-aromatic carboxylic anhydride, and is particularly such ester obtained by using pentaerythritol and/or dipentaerythritol as the aliphatic polyhydroxy compound. Examples of commercially available polybasic acid-modified acrylic oligomer include Aronix Series M-305, M-510 and M-520 from Toagosei Co. Ltd.

The multifunctional monomer having an acid group preferably has an acid value of 0.1 to 40 mg KOH/g, and particularly 5 to 30 mg KOH/g. If the acid value of the multifunctional monomer is too small, the solubility in the process of development may degrade, whereas if it is too large, manufacturing and handling become difficult, photopolymerization performance may degrade, and curing performance characterized by surface smoothness of pixels may degrade. Accordingly, when two or more species of multifunctional monomer having different acid groups, or when a multifunctional monomer having no acid group is used in combination, it is necessary to adjust the acid value of the multifunctional monomer as a whole so as to fall within the ranges described above.

The composition also preferably contains, as the polymerizable monomer, etc., a polyfunctional monomer having a caprolactone-modified structure.

The polyfunctional monomer having a caprolactone-modified structure is not specifically limited so long as it has in the molecule thereof a caprolactone-modified structure. The examples of which include ε-caprolactone-modified polyfunctional (meth)acrylate which is obtainable by esterifying a polyhydric alcohol such as trimethylolethane, di-trimethylolethane, trimethylolpropane, di-trimethylolpropane, pentaerythritol, di-pentaerythritol, tri-pentaerythritol, glycerin, diglycerol or trimethylolmelamine, using (meth)acrylic acid and ε-caprolactone. Among them, the polyfunctional monomer having a caprolactone-modified structure represented by the formula (1) below is preferable.

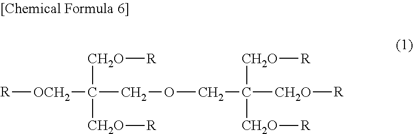

(In the formula, all of, or one to five of six (R)s represent a group represented by the formula (2) below, and the residual represents a group represented by the formula (3) below.)

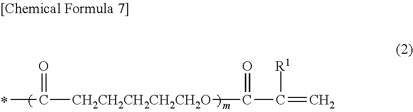

(In the formula, R¹ represents a hydrogen atom or methyl group, m represents an integer of 1 or 2, and “*” indicates an atomic bonding.)

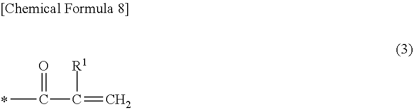

(In the formula, R¹ represents a hydrogen atom or methyl group, and “*” indicates an atomic bonding.)

Such polyfunctional monomer having a caprolactone structure is commercially available, for example, from Nippon Kayaku Co. Ltd. under the trade name of KAYARAD DPCA Series, which includes DPCA-20 (a compound represented by the formulae (1) to (3), where m=1, the number of groups represented by the formula (2) is 2, all (R¹)s represent a hydrogen atom), DPCA-30 (in the same formulae, m=1, the number of groups represented by the formula (2) is 3, all (R¹)s represent a hydrogen atom), DPCA-60 (in the same formulae, m=1, the number of groups represented by the formula (2) is 6, all (R¹)s represent a hydrogen atom), and DPCA-120 (in the same formulae, m=2, the number of groups represented by the formula (2) is 6, all (R¹)s represent a hydrogen atom).

In the present invention, a single species of the polyfunctional monomer having a caprolactone structure may be used alone, or two or more species may be used in a mixed manner.

The polymerizable monomer, etc. in the present invention is also preferably at least one species selected from the group consisting of compounds represented by the formula (i) or (ii) below.

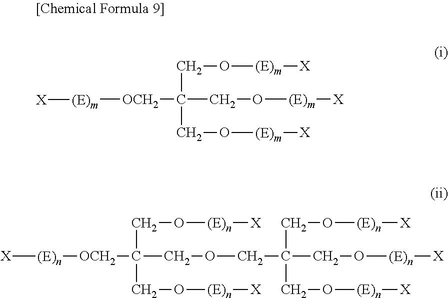

In the formulae (i) and (ii), each E independently represents —((CH₂)_{y}CH₂O)—, or —((CH₂)_{y}CH(CH₃)O)—, each y independently represents an integer of 0 to 10, and each X independently represents an acryloyl group, methacryloyl group, hydrogen atom, or carboxyl group.

In the formula (i), the total number of acryloyl group and methacryloyl group is 3 or 4, each m independently represents an integer of 0 to 10, and the individual (m)s add up to an integer of 0 to 40. When the individual (m)s add up to 0, any one of (X)s represents a carboxyl group.

In the formula (ii), the total number of acryloyl group and methacryloyl group is 5 or 6, each n independently represents an integer of 0 to 10, and the individual (n)s add up to an integer of 0 to 60. When the individual (n)s add up to 0, any one of (X)s represents a carboxyl group.

In the formula (i), m preferably represents an integer of 0 to 6, and more preferably of 0 to 4. The individual (m)s preferably add up to an integer of 2 to 40, more preferably to an integer of 2 to 16, and particularly to an integer of 4 to 8.

In the formula (ii), n preferably represents an integer of 0 to 6, and more preferably 0 to 4. The individual (n)s preferably add up to an integer of 3 to 60, more preferably to an integer of 3 to 24, and particularly to an integer of 6 to 12.

In the formula (i) or formula (ii), —((CH₂)_{y}CH₂O)— or —((CH₂)_{y}CH(CH₃)O)— is preferably bound to X, at the terminal thereof on the oxygen atom side.

A single species of the compound represented by the formula (i) or (ii) may be used alone, or two or more species thereof may be used in combination. In particular, a compound having acryloyl groups for all of six (X)s in the formula (ii) is preferable.

The compound represented by the formula (i) or (ii) may be synthesized by publicly known processes, such as a process of proceeding a ring-opening addition polymerization of pentaerytyritol or dipentaerytyritol with ethylene oxide or propylene oxide to thereby combine the ring-opened skeleton, and a process of allowing, for example, (meth)acryloyl chloride to react with the terminal hydroxyl group of the ring-opened skeleton, to thereby introduce a (meth)acryloyl group. The individual processes have been well-known, so that those skilled in the art will readily synthesize the compound represented by the formula (i) or (ii).

Among the compounds represented by the formula (i) or (ii), pentaerythritol derivative and/or dipentaerythritol derivative are more preferable.

More specifically, compounds represented by the formulae (a) to (f) below (also referred to as “Exemplary Compounds (a) to (f)”, hereinafter) are exemplified, and among them, Exemplary Compounds (a), (b), (e) and (f) are preferable.

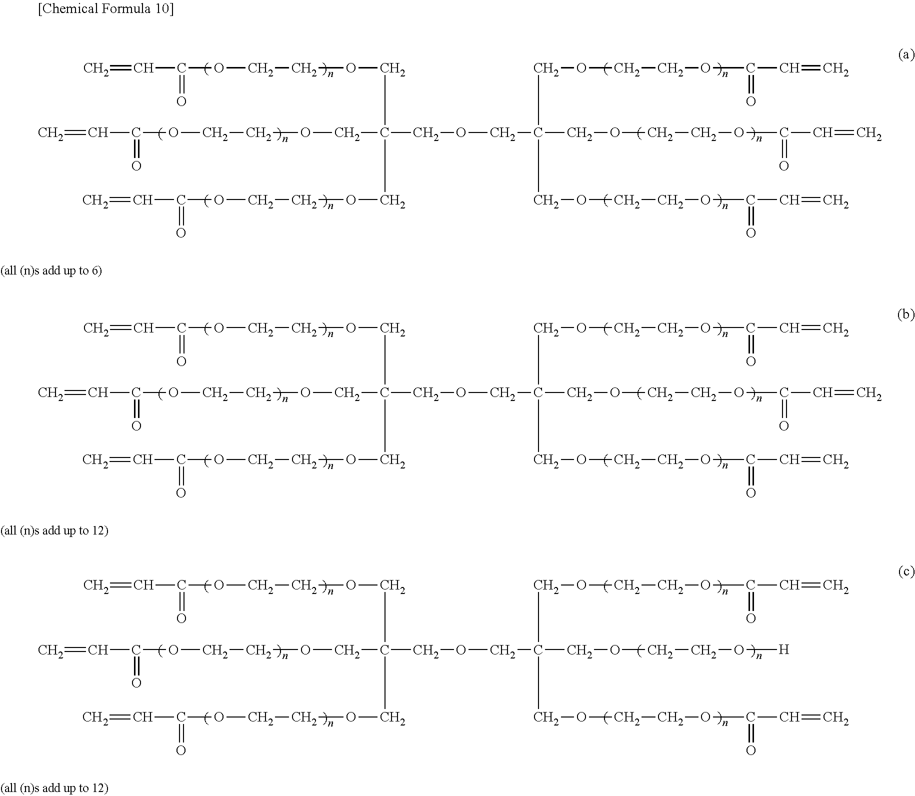

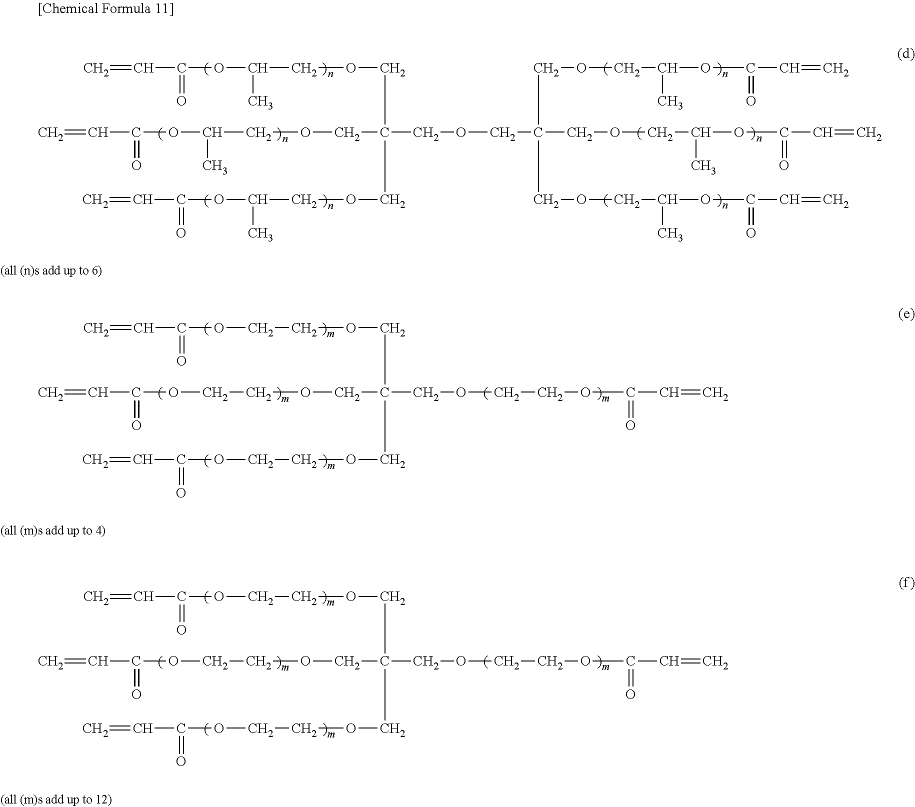

Examples of the polymerizable monomer, etc. represented by the formulae (i), (ii) which are commercially available include SR-494 from Sartomer, which is a tetrafunctional acrylate having four ethyleneoxy chains, DPCA-60 which is a hexafunctional acrylate having six pentylenoxy chains, and TPA-330 which is a trifunctional acrylate having three isobutylenoxy chains, the both from Nippon Kayaku Co. Ltd.

Other preferable examples of the polymerizable monomer, etc. include urethane acrylates described in JP-B-S48-41708, JP-A-S51-37193, JP-B-H2-32293 and JP-B-H2-16765, and urethane compounds having an ethylene oxide-based skeleton described in JP-B-S58-49860, JP-B-S56-17654, JP-B-S62-39417 and JP-B-S62-39418. Moreover, by using, as the polymerizable monomer, etc., an addition polymerizable monomer having in the molecule thereof an amino structure or sulfide structure, described in JP-A-S63-277653, JP-A-S63-260909 and JP-A-H01-105238, it is now possible to obtain a curable composition with a very high speed.

Examples of the polymerizable monomer, etc. which are commercially available include urethane oligomer UAS-10, UAB-140 (from Sanyo-Kokusaku Pulp Co. Ltd.), UA-7200 (from Shin-Nakamura Chemical Co. Ltd.), DPHA-40H (from Nippon Kayaku Co. Ltd.), and UA-306H, UA-306T, UA-3061, AH-600, T-600 and AI-600 (from Kyoeisha Chemical Co. Ltd.).

Also polyfunctional thiol compound having in the molecule thereof two or more mercapto (SH) groups is preferable as the polymerizable monomer, etc. In particular, a compound represented by the formula (I) below is preferable.

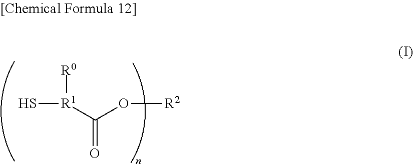

(In the formula, R¹ represents an alkyl group, R² represents an aliphatic group with a valency of n, which may contain atom(s) other than carbon atom, R⁰ represents an alkyl group but not H, and n represents 2 to 4.)

The polyfunctional thiol compound represented by the formula (I) is exemplified, together with structural formula, by 1,4-bis(3-mercaptobutyryloxy)butane [formula (II)], 1,3,5-tris(3-mercaptobutyloxyethyl)-1,3,5-triazine-2,4,6 (1H,3H,5H)-trione [formula (III)], and pentaerythritol tetrakis(3-mercaptobutyrate) [formula (IV)]. Only a single species of these polyfunctional thiols may be used alone, or two or more species thereof may be used in combination.

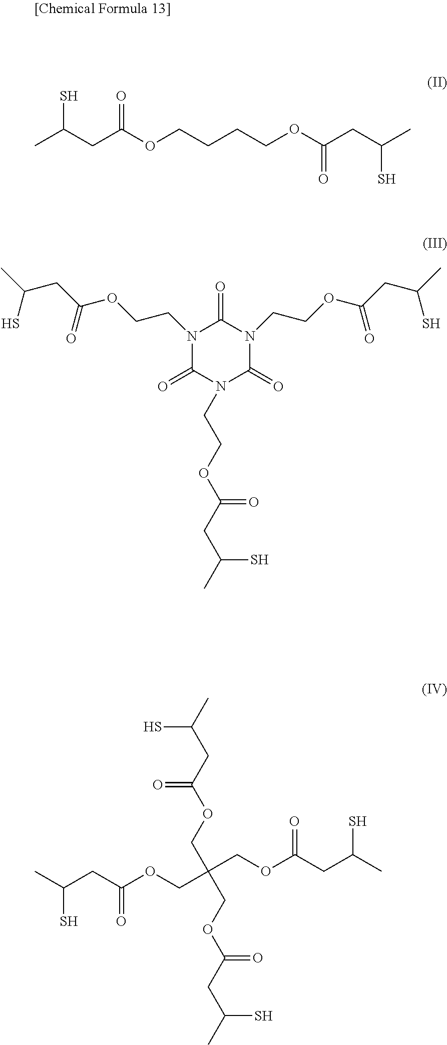

For the composition of the present invention, it is also preferable to use, as the polymerizable monomer, etc., a polymerizable monomer or oligomer having in the molecule thereof two or more epoxy groups or oxetanyl groups. Specific examples of these compounds will be described in the section of “Polymer Having Polymerizable Group in Side Chain” in the next.

### <<B: Polymer Having Polymerizable Group in Side Chains>>

A second preferable embodiment of the composition of the present invention contains, as the polymerizable compound, a polymer having polymerizable groups in the side chains thereof.

The polymerizable group is exemplified by ethylenic unsaturated double bond group, epoxy group and oxetanyl group.

The latter will collectively be described in the section for compounds having an epoxy group or oxetanyl group.

The polymer having an ethylenic unsaturated bond in the side chain thereof is preferably a polymer having, as the unsaturated double bond moiety thereof, at least one functional group selected from those represented by the formulae (1) to (3) below.

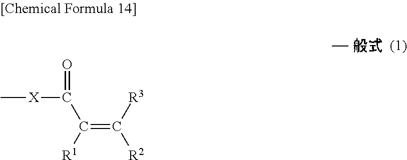

In the formula (1), each of R² to R³ independently represents a hydrogen atom or monovalent organic group. R² is preferably exemplified by hydrogen atom or alkyl group which may have a substituent, and in particular, hydrogen atom and methyl group are preferable by virtue of their high radical reactivity. Each of R² and R³ is independently exemplified by hydrogen atom, halogen atom, amino group, carboxyl group, alkoxycarbonyl group, sulfo group, nitro group, cyano group, alkyl group which may have a substituent, aryl group which may have a substituent, alkoxy group which may have a substituent, aryloxy group which may have a substituent, alkylamino group which may have a substituent, arylamino group which may have a substituent, alkylsulfonyl group which may have a substituent, and arylsulfonyl group which may have a substituent. Among them, hydrogen atom, carboxyl group, alkoxycarbonyl group, alkyl group which may have a substituent, and aryl group which may have a substituent are preferable by virtue of their high radical reactivity.

X represents an oxygen atom, sulfur atom, or —N(R¹²)—, and R²² represents a hydrogen atom or monovalent organic group. R¹² is exemplified by an alkyl group which may have a substituent, among which a hydrogen atom, methyl group, ethyl group, and isopropyl group are preferable by virtue of their high radical reactivity.

Examples of the substituent which may be introduced herein include alkyl group, alkenyl group, alkynyl group, aryl group, alkoxy group, aryloxy group, halogen atom, amino group, alkylamino group, arylamino group, carboxyl group, alkoxycarbonyl group, sulfo group, nitro group, cyano group, amide group, alkylsulfonyl group, and arylsulfonyl group.

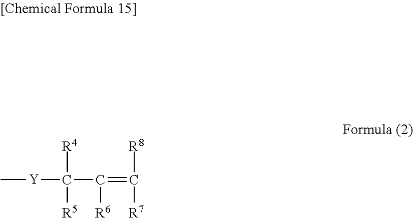

In the formula (2), each of R⁴ to R⁸ independently represents a hydrogen atom or monovalent organic group. Each of R⁴ to R⁸ is preferably a hydrogen atom, halogen atom, amino group, dialkylamino group, carboxy group, alkoxycarbonyl group, sulfo group, nitro group, cyano group, alkyl group which may have a substituent, aryl group which may have a substituent, alkoxy group which may have a substituent, aryloxy group which may have a substituent, alkylamino group which may have a substituent, arylamino group which may have a substituent, alkylsulfonyl group which may have a substituent, and arylsulfonyl group which may have a substituent. Among them, hydrogen atom, carboxy group, alkoxycarbonyl group, alkyl group which may have a substituent, and aryl group which may have a substituent are preferable.

Examples of the substituent which may be introduced herein are similar to those represented by the formula (1). Y represents an oxygen atom, sulfur atom, or —N(R¹²)—. R¹² is synonymous to R¹² in the formula (1), the same will also apply to the preferable examples thereof.

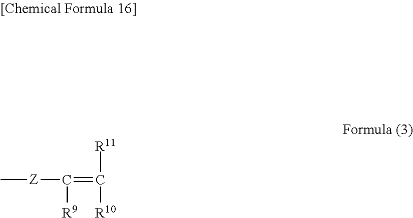

In the formula (3), R⁹ is preferably exemplified by hydrogen atom or alkyl group which may have a substituent. Among them, hydrogen atom and methyl group are preferable by virtue of their high radical reactivity. Each of R¹⁰ and R¹¹ independently represents a hydrogen atom, halogen atom, amino group, dialkylamino group, carboxy group, alkoxycarbonyl group, sulfo group, nitro group, cyano group, alkyl group which may have a substituent, aryl group which may have a substituent, alkoxy group which may have a substituent, aryloxy group which may have a substituent, alkylamino group which may have a substituent, arylamino group which may have a substituent, alkylsulfonyl group which may have a substituent, and arylsulfonyl group which may have a substituent. Among them, hydrogen atom, carboxy group, alkoxycarbonyl group, alkyl group which may have a substituent, and aryl group which may have a substituent are preferable by virtue of their high radical reactivity.

Examples of the substituent which may be introduced herein are similar to those represented by the formula (1). Z represents an oxygen atom, sulfur atom, —N(R¹³)—, or phenylene group which may have a substituent. R¹³ is exemplified by an alkyl group which may have a substituent. Among them, methyl group, ethyl group and isopropyl group are preferable by virtue of their high radical reactivity.

The polymer having an ethylenic unsaturated bond in the side chain thereof, in the present invention, is preferably a compound which contains, in one molecule thereof, 20 mol % or more and less than 95 mol % of a structural unit having the functional group represented by the formulae (1) to (3). The range is more preferably 25 to 90 mol %, and furthermore preferably 30 mol % or more and less than 85 mol %.

The polymer compound which contains the structural unit having the group represented by the formulae (1) to (3) may be synthesized based on the methods described in paragraphs [0027] to [0057] of JP-A-2003-262958. Among the methods, Method of Synthesis 1) described in the patent literature is preferably used, which will be described in below.

The polymer having an ethylenic unsaturated bond is preferably a polymer additionally having an acid group.

The acid group in the context of the present invention is a dissociative group with a pKa of 14 or smaller, wherein preferable examples include —COOH, —SO₃H, —PO₃H₂, —OSO₃H, —OPO₂H₂, —PhOH, —SO₂H, —SO₂NH₂, —SO₂NHCO—, and —SO₂NHSO₂—. Among them, —COOH, —SO₃H and —PO₃H₂ are preferable, and —COOH is more preferable.

The polymer containing in the side chain thereof an acid group and an ethylenic unsaturated bond may be obtained, for example, by adding an ethylenic unsaturated group-containing epoxy compound to a carboxy group of a carboxyl group-containing, alkali-soluble polymer.

The carboxyl group-containing polymer includes 1) polymer obtained by radical polymerization or ion polymerization of a carboxyl group-containing monomer, 2) polymer obtained by radical or ion polymerization of an acid anhydride-containing monomer, and succeeding hydrolysis or half-esterification of the acid anhydride unit, and 3) epoxy acrylate obtained by modifying an epoxy polymer with a unsaturated monocarboxylic acid and an acid anhydride.

Specific examples of the carboxy group-containing, vinyl-based polymer include homopolymer obtained by polymerization of unsaturated carboxylic acid, used as the carboxyl group-containing monomer, such as (meth)acrylic acid, 2-succinoloyloxyethyl methacrylate, 2-malenoloyloxyethyl methacrylate, 2-phthaloyloxyethyl methacrylate, 2-hexahydrophthaloyloxyethyl methacrylate, maleic acid, fumaric acid, itaconic acid, and crotonic acid; and copolymer obtained by polymerization of these unsaturated carboxylic acids with a vinyl monomer having no carboxyl group, such as styrene, α-methyl styrene, methyl (meth)acrylate, ethyl (meth)acrylate, propyl (meth)acrylate, isopropyl (meth)acrylate, butyl (meth)acrylate, vinyl acetate, acrylonitrile, (meth)acrylamide, glycidyl (meth)acrylate, allyl glycidyl ether, glycidyl ethylacrylate, crotonic acid glycidyl ether, (meth)acrylic acid chloride, benzyl (meth)acrylate, hydroxyethyl (meth)acrylate, N-methylolacrylamide, N,N-dimethyl acrylamide, N-methacryloyl morpholine, N,N-dimethylaminoethyl (meth)acrylate, and N,N-dimethylaminoethyl acrylamide.

Other examples include polymer obtained by co-polymerizing maleic anhydride with styrene, α-methyl styrene or the like, and then half-esterifying or hydrolysing the maleic anhydride unit moiety with a monohydric alcohol such as methanol, ethanol, propanol, butanol, or hydroxyethyl (meth)acrylate.

Among them, the carboxyl group-containing polymer, and in particular, (meth)acrylic acid-containing (meth)acrylic acid (co)polymer is preferable. Specific examples of these copolymers include methyl methacrylate/methacrylic acid copolymer described in JP-A-560-208748, methyl methacrylate/methyl acrylate/methacrylic acid copolymer described in JP-A-560-214354, benzyl methacrylate/methyl methacrylate/methacrylic acid/2-ethylhexyl acrylate copolymer described in JP-A-H5-36581, methyl methacrylate/n-butyl methacrylate/2-ethylhexyl acrylate/methacrylic acid copolymer described in JP-A-H5-333542, styrene/methyl methacrylate/methyl acrylate/methacrylic acid copolymer described in JP-A-H7-261407, methyl methacrylate/n-butyl acrylate/2-ethylhexyl acrylate/methacrylic acid copolymer described in JP-A-H10-110008, and methyl methacrylate/n-butyl acrylate/2-ethylhexyl acrylate/styrene/methacrylic acid copolymer described in JP-A-H10-198031.

The polymer having in the side chain thereof an acid group and a polymerizable group, in the present invention, is preferably a polymer having, as the unsaturated double bond moiety thereof, at least one structural unit represented by the formulae (1-1) to (3-1) below.

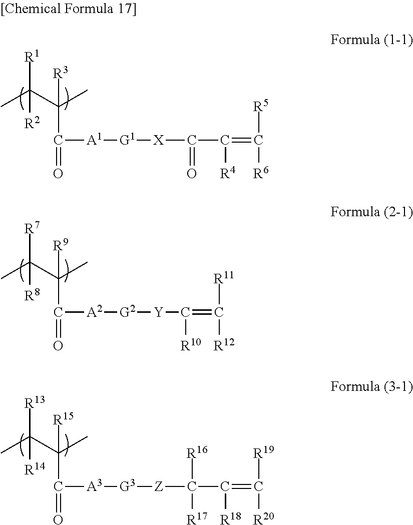

In the formulae (1-1) to (3-1), each of A¹, A² and A³ independently represents an oxygen atom, sulfur atom, or —N(R²¹)—, where R²¹ represents an alkyl group which may have a substituent. Each of G¹, G² and G³ independently represents a divalent organic group. Each of X and Z independently represents an oxygen atom, sulfur atom, or —N(R²²)—, where R²² represents an alkyl group which may have a substituent. Y represents an oxygen atom, sulfur atom, phenylene group which may have a substituent, or —N(R²³)—, where R²³ represents an alkyl group which may have a substituent. Each of R¹ to R²⁰ independently represents a monovalent substituent.

In the formula (1-1), each of R¹ to R³ independently represents a monovalent substituent, which is exemplified by hydrogen atom, and alkyl group additionally having a substituent. Among them, each of R¹ and R² preferably represents a hydrogen atom, and R³ is preferably represents a hydrogen atom or methyl group.

Each of R⁴ to R⁶ independently represents a monovalent substituent. R⁴ is exemplified by hydrogen atom or alkyl group which may additionally have a substituent. Among them, hydrogen atom, methyl group, and ethyl group are preferable. Each of R⁵ and R⁶ independently represents a hydrogen atom, halogen atom, alkoxycarbonyl group, sulfo group, nitro group, cyano group, alkyl group which may additionally have a substituent, aryl group which may additionally have a substituent, alkoxy group which may additionally have a substituent, aryloxy group which may additionally have a substituent, alkylsulfonyl group which may additionally have a substituent, and arylsulfonyl group which may additionally have a substituent. Among them, hydrogen atom, alkoxycarbonyl group, alkyl group which may additionally have a substituent, and aryl group which may additionally have a substituent are preferable.

Examples of the substituent which may be introduced herein include methoxycarbonyl group, ethoxycarbonyl group, isopropyloxycarbonyl group, methyl group, ethyl group, and phenyl group.

A¹ represents an oxygen atom, sulfur atom, or —N(R²¹)—, and X represents an oxygen atom, sulfur atom or —N(R²²)—. Each of R²¹ and R²² is exemplified by alkyl group which may have a substituent.

G¹ represents a divalent organic group, wherein an alkylene group which may have a substituent is preferable. More preferably, G¹ is exemplified by C₁₋₂₀ alkylene group which may have a substituent, C₃₋₂₀ cycloalkylene group which may have a substituent, and C₆₋₂₀ aromatic group which may have a substituent. Among them, C₁₋₁₀ straight-chain or branched alkylene group which may have a substituent, C₃₋₁₀ cycloalkylene group which may have a substituent, and C₆₋₁₂ aromatic group which may have a substituent are preferable by virtue of their performances related to strength, developability and so forth.

The substituent on G¹ is preferably a hydroxyl group.

In the formula (2-1), each of R⁷ to R⁹ independently represents a monovalent substituent, preferably exemplified by hydrogen atom, and alkyl group which may additionally have a substituent, wherein each of R⁷ and R⁸ preferably represents a hydrogen atom, and R⁹ preferably represents a hydrogen atom or methyl group.

Each of R¹³ to R¹² independently represents a monovalent substituent. Specific examples of the substituent include hydrogen atom, halogen atom, dialkylamino group, alkoxycarbonyl group, sulfo group, nitro group, cyano group, alkyl group which may additionally have a substituent, aryl group which may additionally have a substituent, alkoxy group which may additionally have a substituent, aryloxy group which may additionally have a substituent, alkylsulfonyl group which may additionally have a substituent, and arylsulfonyl group which may additionally have a substituent. Among them, hydrogen atom, alkoxycarbonyl group, alkyl group which may additionally have a substituent, and aryl group which may additionally have a substituent are preferable.

Examples of the substituent which may be introduced herein are similar to those represented by the formula (1-1).

A² represents an oxygen atom, sulfur atom, or —N(R²¹)—, where R²¹ is exemplified by hydrogen atom and alkyl group which may have a substituent.

G² represents a divalent organic group, which is preferably an alkylene group which may have a substituent. More preferably, G² is exemplified by C₁₋₂₀ alkylene group which may have a substituent, C₃₋₂₀ cycloalkylene group which may have a substituent, and C₆₋₂₀ aromatic group which may have a substituent. Among them, C₁₋₁₀ straight-chain or branched alkylene group which may have a substituent, C₃₋₁₀ cycloalkylene group which may have a substituent, and C₆₋₁₂ aromatic group which may have a substituent are preferable by virtue of their performances related to strength, developability and so forth.

The substituent on G² is preferably a hydroxyl group.

Y represents an oxygen atom, sulfur atom, —N(R²³)—, or phenylene group which may have a substituent. R²³ is exemplified by hydrogen atom, and alkyl group which may have a substituent.

In the formula (3-1), each of R¹³ to R¹⁵ independently represents a monovalent substituent, which is exemplified by hydrogen atom, and alkyl group which may have a substituent. Among them, each of R¹³ and R¹⁴ preferably represents a hydrogen atom, and R¹⁵ preferably represents a hydrogen atom or methyl group.

Each of R¹⁶ to R²⁰ independently represents a monovalent substituent, wherein each of R¹⁶ to R²⁰ is exemplified by hydrogen atom, halogen atom, dialkylamino group, alkoxycarbonyl group, sulfo group, nitro group, cyano group, alkyl group which may additionally have a substituent, aryl group which may additionally have a substituent, alkoxy group which may additionally have a substituent, aryloxy group which may additionally have a substituent, alkylsulfonyl group which may additionally have a substituent, and arylsulfonyl group which may additionally have a substituent. Among them, hydrogen atom, alkoxycarbonyl group, alkyl group which may additionally have a substituent, and aryl group which may additionally have a substituent are preferable. Examples of the substituent which may be introduced herein are similar to those represented by the formula (1).

A³ represents an oxygen atom, sulfur atom, or —N(R²¹)—, and Z represents an oxygen atom, sulfur atom, or —N(R²²)—. Examples of R²¹ and R²² are similar to those represented by the formula (1).

G³ represents a divalent organic group, which is preferably an alkylene group which may have a substituent. G³ is preferably exemplified by C₁₋₂₀ alkylene group which may have a substituent, C₃₋₂₀ cycloalkylene group which may have a substituent, and C₆₋₂₀ aromatic group which may have a substituent. Among them, C₁₋₁₀ straight-chain or branched alkylene group which may have a substituent, C₃₋₁₀ cycloalkylene group which may have a substituent, C₆₋₁₂ aromatic group which may have a substituent are preferable by virtue of their performances related to strength, developability and so forth.

The substituent on G³ is preferably a hydroxyl group.

Preferable examples of the constituent having an ethylenic unsaturated bond and an acid group may be referred to, and selectable from those described in paragraphs [0060] to [0063] of JP-A-2009-265518, the content of which is incorporated by reference into this specification.

The polymer having acid groups and ethylenic unsaturated bonds in the side chains thereof preferably has an acid value of 20 to 300 mg KOH/g, more preferably 40 to 200 mg KOH/g, and furthermore preferably 60 to 150 mg KOH/g.

The polymer having in the side chain thereof a polymerizable group is also preferably a polymer having, in the side chain thereof, an ethylenic unsaturated bond and an urethane group (occasionally referred to as “urethane polymer”, hereinafter).

The urethane polymer is a polyurethane polymer having, as the basic skeleton thereof, a structural unit represented by a reaction product formed between at least one species of diisocyanate compound represented by the formula (4) below, and at least one species of diol compound represented by the formula (5) below (properly referred to as “specific polyurethane polymer”, hereinafter).

OCN—X⁰—NCO Formula (4)

HO—Y⁰—OH Formula (5)

In the formulae (4) and (5), each of X⁰ and Y⁰ independently represents a divalent organic residue.

If at least either one of the diisocyanate compound represented by the formula (4) and the diol compound represented by the formula (5) has at least one of the group represented by the formulae (1) to (3) corresponded to the unsaturated double bond moieties, then the specific polyurethane polymer, having the group(s) represented by the formulae (1) to (3) introduced into the side chain thereof, is produced as a reaction product of the diisocyanate compound and the diol compound. According to this method, the specific polyurethane polymer in the present invention may readily be manufactured, more easily than by a method of replacing or introducing a desired side chain after reaction and production of the polyurethane polymer.

### 1) Diisocyanate Compound

The diisocyanate compound represented by the formula (4) above is exemplified by a product obtained, for example, by an addition reaction of a triisocyanate compound, with one equivalent of a monofunctional alcohol or monofunctional amine compound having an unsaturated group.

The triisocyanate compound may be referred to compounds described in paragraphs [0099] to [0105] of JP-A-2009-265518, the content of which is incorporated by reference into this specification.

A preferable method of introducing the unsaturated group into the side chains of the polyurethane polymer is such as using, as a source material for manufacturing the polyurethane polymer, a diisocyanate compound having an unsaturated group in the side chain thereof. The diisocyanate compound, which is obtainable by an addition reaction of the triisocyanate compound with one equivalent of the monofunctional alcohol or monofunctional amine compound having an unsaturated group, and therefore having the unsaturated group in the side chain thereof, may be referred to and selectable from compounds described typically in paragraphs [0107] to [0114] of JP-A-2009-265518, the content of which is incorporated by reference into this specification.

The specified polyurethane polymer used in the present invention may be copolymerized with a diisocyanate compound other than the above-described diisocyanate compound having an unsaturated group, from the viewpoint of improving the compatibility with the other components in the polymerizable composition, and of improving the shelf stability.

The diisocyanate compound to be co-polymerized is exemplified by those listed below. A diisocyanate compound represented by the formula (6) below is preferable.

OCN-L¹-NCO Formula (6)

In formula (6), L¹ represents a divalent aliphatic or aromatic hydrocarbon group which may have a substituent. As necessary, L¹ may have other functional group non-reactive with an isocyanate group, such as ester, urethane, amide and ureido group.

The diisocyanate compound represented by the formula (6) specifically includes those listed below.

The examples include aromatic diisocyanate compound such as 2,4-tolylene diisocyanate, dimer of 2,4-tolylene diisocyanate, 2,6-tolylenedilene diisocyanate, p-xylylene diisocyanate, m-xylylene diisocyanate, 4,4′-diphenylmetane diisocyanate, 1,5-naphthylene diisocyanate, and 3,3′-dimethylbiphenyl-4,4′-diisocyanate; aliphatic diisocyanate compound such as hexamethylene diisocyanate, trimethyl hexamethylene diisocyanate, lysine diisocyanate, and dimer acid diisocyanate; alicyclic diisocyanate compound such as isophorone diisocyanate, 4,4′-methylenebis(cyclohexylisocyanate), methyl cyclohexane-2,4- (or -2,6-)diisocyanate, and 1,3-(isocyanatemethyl)cyclohexane; and diisocyanate compound obtained as a reaction product of a diol and a diisocyante, such as an adduct of 1 mol of 1,3-butylene glycol and 2 mol of tolylene diisocyanate.

### 2) Diol Compound

The diol compound represented by the formula (5) is broadly exemplified by polyether diol compound, polyester diol compound, and polycarbonate diol compound.

Another preferable method of introducing the unsaturated group into the side chains of the polyurethane polymer, other than the method described above, is such as using a diol compound having an unsaturated group in the side chain thereof, as a source material of the polyurethane polymer. This sort of diol compound may be any of commercially available ones such as trimethylolpropane monoallyl ether, or may be compounds readily manufacturable by allowing a halogenated diol compound, triol compound or aminodiol compound to react with a carboxylic acid having an unsaturated group, acid chloride, isocyanate, alcohol, amine, thiol or halogenated alkyl compound. Specific examples of these compounds may be referred to, and selectable from those typically described in paragraphs [0122] to [0125] of JP-A-2009-265518, the content of which is incorporated by reference into this specification.

More preferable polymer used in the present invention is exemplified by a polyurethane resin obtained by using, in the process of synthesis thereof, a diol compound represented by the formula (G) below, as at least one diol compound having an ethylenic unsaturated linking group.

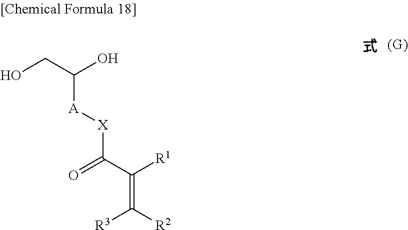

In the formula (G), each of R¹ to R³ independently represents a hydrogen atom or monovalent organic group, A represents a divalent organic residue, X represents an oxygen atom, sulfur atom, or —N(R¹²)—, where R¹² represents a hydrogen atom or monovalent organic group.

Note that R¹ to R³ and X in the formula (G) are synonymous to R¹ to R³ and X in the formula (1), the same will also apply to the preferable examples thereof.

By using the polyurethane polymer derived from such diol compound, it is supposed that an excessive molecular motion of the polymer principal chain is suppressed by the contribution of a secondary alcohol with a large steric hindrance, and thereby the film strength is improved.

Specific examples of the diol compound represented by the formula (G), which may preferably be used for the synthesis of the specific polyurethane polymer, will be listed below.

Specific examples of the diol represented by the formula (G), preferably used for synthesis of the specified polyurethane polymer, may be referred to, and selectable from compounds described in paragraphs [0129] to [0131] of JP-A-2009-265518, the content of which is incorporated by reference into this specification.

The specific polyurethane polymer used in the present invention may, for example, be co-polymerized with a diol compound other than the above-described diol compound having an unsaturated group, from the viewpoint of improving the compatibility with the other components in the polymerizable composition, and of improving the shelf stability.

Such diol compound is exemplified by the above-described polyether diol compound, polyester diol compound, and polycarbonate diol compound.

The polyether diol compound is exemplified by compounds represented by the formulae (7), (8), (9), (10) and (11) below, and, a random copolymer composed of ethylene oxide having a terminal hydroxy group and propylene oxide.

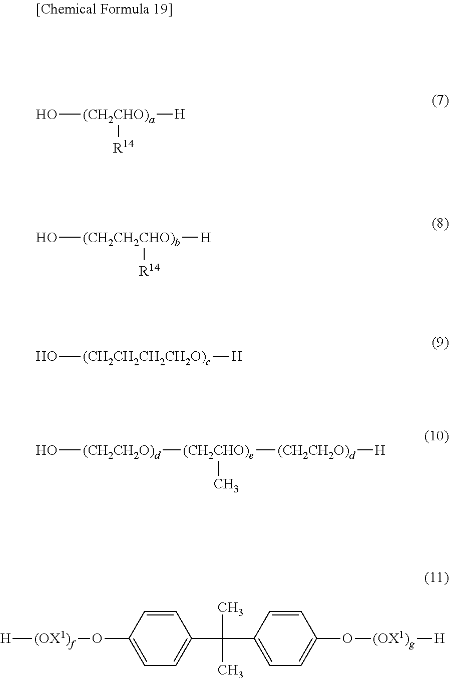

In the formulae (7) to (11), R¹⁴ represents a hydrogen atom or methyl group, and X¹ represents the groups below. Each of a, b, c, d, e, f and g represents an integer of 2 or larger, and preferably an integer of 2 to 100.

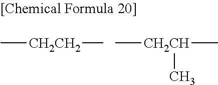

The polyether diol compounds represented by the formulae (7) to (11) above are specifically referred to, and selectable from compounds described in paragraphs [0137] to [0140] of JP-A-2009-265518, the content of which is incorporated by reference into this specification.

The random copolymer formed between ethylene oxide and propylene oxide, respectively having terminal hydroxy groups, is specifically exemplified by the products under the trade names of Newpol 50HB-100, Newpol 50HB-260, Newpol 50HB-400, Newpol 50HB-660, Newpol 50HB-2000 and Newpol 50HB-5100 from Sanyo Chemical Industries, Ltd.

The polyester diol compound is exemplified by the compounds represented by the formulae (12), (13).

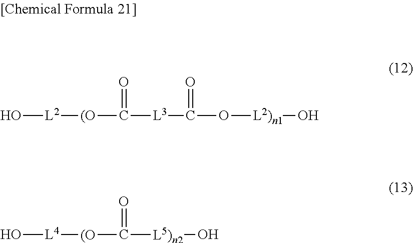

In the formulae (12) and (13), L², L³ and L⁴ may be same with, or different from each other, each of which represents a divalent aliphatic or aromatic hydrocarbon group, and L⁵ represents a divalent aliphatic hydrocarbon group. It is preferable that each of L² to L⁴ independently represents an alkylene group, alkenylene group, alkynylene group, or arylene group, and L⁵ represents an alkylene group. Each of L² to L⁵ may contain other functional group non-reactive with isocyanate group, such as ether, carbonyl, ester, cyano, olefin, urethane, amide, ureido group or halogen atom. Each of n1 and n2 independently represents an integer of 2 or larger, and preferably an integer of 2 to 100.

The polycarbonate diol compound is exemplified by compound represented by the formula (14).

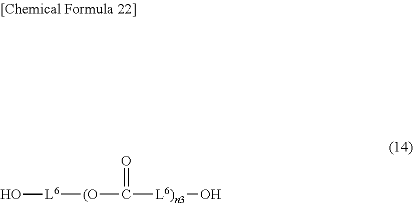

In the formula (14), (L⁶)s are same with, or different from each other, and each of which represents a divalent aliphatic or aromatic hydrocarbon group. L⁶ preferably represents an alkylene group, alkenylene group, alkynylene group, and arylene group. L⁶ may contain other functional group non-reactive with isocyanate group, such as ether, carbonyl, ester, cyano, olefin, urethane, amide, ureido group or halogen atom. n3 represents an integer of 2 or larger, and preferably an integer of 2 to 100.

Specific diol compounds represented by the formulae (12), (13) and (14) may be referred to, and selectable from compounds typically described in paragraphs [0148] to [0150] of JP-A-2009-265518, the content of which is incorporated by reference into this specification.

In synthesis of the specific polyurethane polymer, a diol compound having a substituent non-reactive with isocyanate group may be used in addition to the above-described diol compound. Examples of such diol compound include those listed below.

HO-L⁷-O—CO-L⁸-CO—O-L⁷-OH (15)

HO-L⁸-CO—O-L⁷-OH (16)

In the formulae (15) and (16), L⁷ and L⁸ may be same with, or different from each other, and each of which represents a divalent aliphatic hydrocarbon group, aromatic hydrocarbon group or heterocyclic group, which may have a substituent (for example, alkyl group, aralkyl group, aryl group, alkoxy group, aryloxy group, and halogen atom such as —F, —Cl, —Br, —I). As necessary, each of L⁷ and L⁸ may have therein other functional group non-reactive with isocyanate group, such as carbonyl group, ester group, urethane group, amide group, or ureido group. L⁷ and L⁸ may form a ring.

In synthesis of the specific polyurethane polymer, a diol compound having a carboxyl group may be used in addition to the above-described diol compound.

Examples of such diol compound include those represented by the formulae (17) to (19).

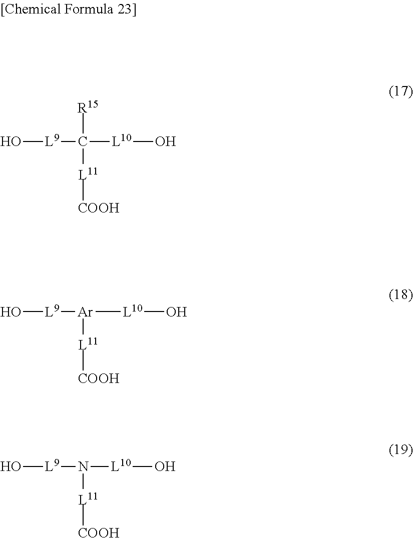

In the formulae (17) to (19), R¹⁵ represents a hydrogen atom, alkyl group, aralkyl group, aryl group, alkoxy group, or aryloxy group, which may have a substituent (exemplified by the individual groups of cyano, nitro, halogen atom such as —F, —Cl, —Br, —I, —CONH₂, —COOR¹⁶, —OR¹⁶, —NHCONHR¹⁶, —NHCOOR¹⁶, —NHCOR¹⁶, and —OCONNHR¹⁶ (R¹⁶ represents a C₁₋₁₀ alkyl group, or C₇₋₁₅ aralkyl group.)), and preferably represents a hydrogen atom, C₁₋₈ alkyl group, or C₆₋₁₅ aryl group. L⁹, L¹⁰ and L¹¹ may be same with, or different from each other, and each of which represents a single bond, or a divalent aliphatic or aromatic hydrocarbon group which may have a substituent (for example, alkyl, aralkyl, aryl, alkoxy and halogeno groups are preferable), preferably represents a C₁₋₂₀ alkylene group, or C₆₋₁₅ arylene group, and furthermore preferably a C₁₋₈ alkylene group. As necessary, L⁹ to L¹¹ may have therein other functional group non-reactive with isocyanate group, such as carbonyl, ester, urethane, amide, ureido, or ether group. Any two or three of R¹⁵, L⁷, L⁸ and L⁹ may form a ring.

Ar represents a trivalent aromatic hydrocarbon group, and preferably a C₆₋₁₅ aromatic group.

The diol compound having a carboxyl group represented by the formulae (17) to (19) is exemplified by those listed below.

The examples include 3,5-dihydroxy benzoic acid, 2,2-bis(hydroxymethyl) propionic acid, 2,2-bis(2-hydroxyethyl) propioic acid, 2,2-bis(3-hydroxypropyl) propionic acid, bis(hydroxymethyl) acetic acid, bis(4-hydroxyphenyl) acetic acid, 2,2-bis(hydroxymethyl) butyric acid, 4,4-bis(4-hydroxyphenyl) pentanoic acid, tartaric acid, N,N-dihydroxyethylglycine, and N,N-bis(2-hydroxyethyl)-3-carboxy-propionamide.

By the presence of a carboxyl group, the polyurethane polymer is preferably given a capability of forming hydrogen bond and alkali-solubility. More specifically, the polyurethane polymer having in the side chain thereof an ethylenic unsaturated binding group is a polymer further having a carboxyl group in the side chain thereof. More specifically, a polyurethane polymer having 0.3 meq/g or more of ethylenic unsaturated binding group in the side chain thereof, and 0.4 meq/g or more of carboxyl group in the side chain thereof, is particularly preferable for use as the binder polymer in the present invention.

For synthesis of the specific polyurethane polymer, compounds derived from tetracarboxylic dianhydride ring-opened by a diol compound, represented by the formulae (20) to (22) below, may be used in addition to the above-described diol. Examples of such diol compound include those listed below.

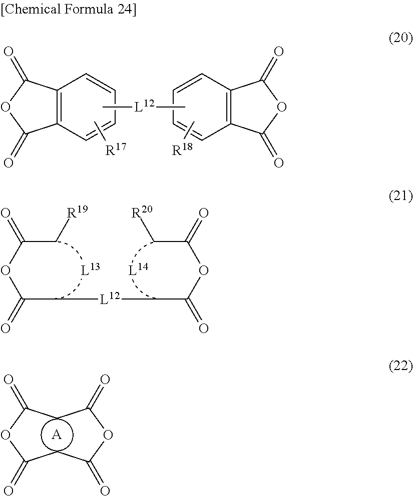

In the formulae (20) to (22), L¹² represents a single bond, divalent aliphatic or aromatic hydrocarbon group which may have a substituent (for example, alkyl, aralkyl, aryl, alkoxy, halogeno, ester and amide groups are preferable), —CO—, —SO—, —SO₂—, —O— or —S—, and preferably represents a single bond, C₁₋₁₅ divalent aliphatic hydrocarbon group, —CO—, —SO₂—, —O— or —S—. R¹⁷ and R¹⁸ may be same or different, each of which represents a hydrogen atom, alkyl group, aralkyl group, aryl group, alkoxy group, or halogeno group, and preferably represents a hydrogen atom, C₁₋₈ alkyl group, C₆₋₁₅ aryl group, C₁₋₈ alkoxy group or halogeno group. Any two of L¹², R¹⁷ and R¹⁸ may combine to form a ring.

R¹⁹ and R²⁰ may be same or different, each of which represents a hydrogen atom, alkyl group, aralkyl group, aryl group or halogeno group, and preferably represents a hydrogen atom, C₁₋₈ alkyl, or C₆₋₁₅ aryl group. Any of two L¹², R¹⁹ and R²⁰ may combine to form a ring. L¹³ and L¹⁴ may be same or different, each of which represents a single bond, double bond, or divalent aliphatic hydrocarbon group, and preferably represents a single bond, double bond, or methylene group. A represents a mononuclear or polynuclear aromatic ring, and preferably represents a C₆₋₁₈ aromatic ring.

The compounds represented by the formulae (20), (21) and (22) above are specifically referred to, and selectable from compounds described in paragraphs [0163] to [0164] of JP-A-2009-265518, the content of which is incorporated by reference into this specification.

Exemplary methods of introducing a compound, obtained by ring-opening reaction of these tetracarboxylic acid dianhydrides using a diol compound, into the polyurethane polymer include the followings.

a) a method of allowing an alcohol-terminated compound, obtained by ring-opening reaction of the tetracarboxylic acid dianhydride using a diol compound, to react with a diisocyanate compound; and

b) a method of allowing an alcohol-terminated urethane compound, obtained by reacting a diisocyanate compound with an excessive diol compound, to react with the tetracarboxylic acid dianhydride.

The diol compound used in the ring-opening reaction is specifically referred to, and selectable from compounds typically described in paragraph [0166] of JP-A-2009-265518, the content of which is incorporated by reference into this specification.

The specified polyurethane polymer usable in the present invention may be synthesized by heating the diisocyanate compound and the diol compound in an aprotic solvent, while being added with a publicly known catalyst with an activity depending on reactivity of the individual components. Molar ratio of the diisocyanate and the diol compound (Mₐ:M_{b}) used for the synthesis is preferably 1:1 to 1.2:1. By treatment using alcohols or amines, a product having a desired physical properties, such as molecular weight and viscosity, may be obtained in a final form containing no isocyanate group remained therein.

With respect to the amount of introduction of the ethylenic unsaturated bond contained in the specified polyurethane polymer in the present invention, the amount of the ethylenic unsaturated linking group, in terms of equivalent, in the side chains is preferably 0.3 meq/g or more, and more preferably 0.35 to 1.50 meq/g.

Molecular weight of the specified polyurethane polymer in the present invention is preferably 10,000 or larger in terms of weight-average molecular weight, and more preferably in the range from 40,000 to 200,000.

In the present invention, also styrene-based polymer having ethylenic unsaturated bonds in the side chains thereof (occasionally referred to as “styrene-based polymer”, hereinafter) is preferable, and polymer having at least either one of a styrenic double bond (styrene and α-methylstyrene-based double bond) represented by the formula (23) below, and a vinylpyridinium group represented by the formula (24) below, is more preferable.

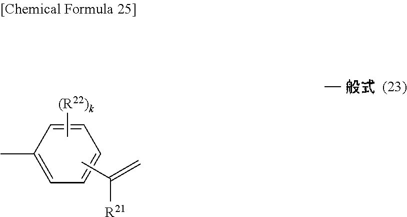

In the formula (23), R²¹ represents a hydrogen atom or methyl group. R²² represents a substitutable arbitrary atom or atomic group. k represents an integer of 0 to 4.

The styrenic double bond contained in the formula (23) is bound to the principal chain of the polymer, via a single bond, or an arbitrary atom or atomic group. Mode of bonding is not specifically limited.

Preferable examples of repeating unit of the polymer compound having the functional group represented by the formula (23) is referred to, and selectable from compounds typically described in paragraphs to [0181] of JP-A-2009-265518, the content of which is incorporated by reference into this specification.

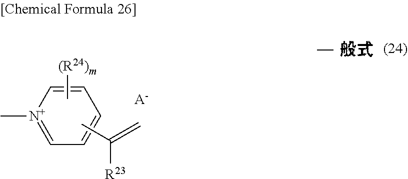

In the formula (24), R²³ represents a hydrogen atom or methyl group. R²⁴ represents a substitutable arbitrary atom or atomic group. m represents an integer of 0 to 4. A represents an anion. The pyridinium ring may be condensed with a benzene ring as a substituent, to be given in the form of benzopyridinium which includes quinolinium group and isoquinolinium group.

The vinylpyridinium group represented by the formula (24) is bound to the principal chain of the polymer, via a single bond, or an arbitrary atom or atomic group. Mode of bonding is not specifically limited.

Preferable examples of the repeating unit of the polymer compound having a functional group, represented by the formula (24), is referred to, and selectable from those typically described in paragraph [0184] of JP-A-2009-265518, the content of which is incorporated by reference into this specification.

One method of synthesizing the styrene-based polymer is exemplified by a method of allowing monomers, having a functional groups represented by the formulae (23) or (24), and also having functional groups copolymerizable with other copolymerizable components, to copolymerize with each other, by a publicly-known method of copolymerization. The styrene-based polymer may be a homopolymer having only either one of the functional groups represented by the formulae (23) and (24), or may be a copolymer having two or more species of either one of, or both of the functional groups.

Moreover, the styrene-based polymer may be a copolymer with other copolymerizable monomer having none of these functional groups. Carboxy group-containing monomer is preferably selectable as the other copolymerizable monomer, typically for the purpose of providing the polymer with solubility in alkaline aqueous solution, and is exemplified by acrylic acid, methacrylic acid, 2-carboxyethyl acrylate, 2-carboxyethyl methacrylate, crotonic acid, maleic acid, fumaric acid, monoalkyl maleate, monoalkyl fumarate, and 4-carboxystyrene.

It is also preferable to use the styrene-based polymer after being synthesized as a (multi-component) copolymer, by introducing other monomer other than the carboxy group-containing monomer. The monomer which may be introduced into the copolymer in this case is referred to, and selectable from compounds described in paragraph [0187] of JP-A-2009-265518, the content of which is incorporated by reference into this specification.

When the above-described copolymer is used as the styrene-based polymer, ratio of the repeating unit having the functional groups represented by the formula (23) and/or formula (24), relative to the whole copolymer composition is preferably 20% by mass or more, and more preferably 40% by mass or more. In these ranges, the effect of the present invention is distinctive, and thereby a highly sensitive crosslinked system may be provided.

Molecular weight of the styrene-based polymer preferably falls in the range from 10,000 to 300,000 in terms of weight-average molecular weight, more preferably in the range from 15,000 to 200,000, and most preferably in the range from 20,000 to 150,000.

Other polymer having ethylenic unsaturated bonds in the side chains thereof includes novolac polymer having ethylenic unsaturated groups in the side chains thereof, and is exemplified by a polymer obtained by introducing, into the side chain of the polymer described in JP-A-H09-269596, an ethylenic unsaturated bond according to a method described in JP-A-2002-62648.

The acetal polymer, having ethylenic unsaturated bonds bound to the side chains thereof, is typically exemplified by polymers described in JP-A-2002-162741.

The polyamide-based polymer, having the ethylenic unsaturated bonds bound to the side chains thereof, is typically exemplified by polymers described in Japanese Patent Application No. 2003-321022, or polymers obtained by introducing the ethylenic unsaturated bonds into the polyamide polymer cited therein, by a method described in JP-A-2002-62648.

The polyimide polymer, having the ethylenic unsaturated bonds bound to the side chains thereof, is exemplified by polymers described in Japanese Patent Application No. 2003-339785, or polymers obtained by introducing the ethylenic unsaturated bonds into the polyimide polymer cited therein, by a method described in JP-A-2002-62648.

### <<C: Compound Having Epoxy Group or Oxetanyl Group>>

A third preferable embodiment of the present invention relates to an embodiment which contains a compound having an epoxy group or oxetanyl group, as the polymerizable compound. The compound having an epoxy group or oxetanyl group specifically includes polymer having epoxy groups in the side chains thereof, and polymerizable monomer or oligomer having two or more epoxy groups in the molecule thereof, and is exemplified by bisphenol A-type epoxy resin, bisphenol F-type epoxy resin, phenol novolac-type epoxy resin, cresol novolac-type epoxy resin, and aliphatic epoxy resin.

These compounds are commercially available, or may be obtained by introducing epoxy groups into the side chains of the polymer.

The commercially available products are referred to, and selectable from compounds typically described in paragraph [0191] of JP-A-2012-155288, the content of which is incorporated by reference into this specification.

The commercially available products are exemplified by Denacol EX-212L, EX-214L, EX-216L, EX-321L and EX-850L (all from Nagase ChemteX Corporation). Other examples include ADEKA RESIN EP-40005, ibid. EP-40035, ibid. EP-40105, ibid. and EP-40115 (all from ADEKA Corporation), NC-2000, NC-3000, NC-7300, XD-1000, EPPN-501 and EPPN-502 (all from ADEKA Corporation), and JER1031S (Japan Epoxy Resin Co. Ltd.).

Specific examples of the polymer, having oxetanyl groups in the side chains thereof, and polymerizable monomer or oligomer having two or more oxetanyl group in the molecule thereof, include Aron Oxetane OXT-121, OXT-221, OX-SQ, and PNOX (all from Toagosei Co. Ltd.).

In the synthesis based on introduction into the side chains of the polymer, a reaction for introduction may be proceeded typically by using a tertiary amine such as triethylamine or benzylmethylamine; quaternary ammonium salt such as dodecyl trimethyl ammonium chloride, tetramethyl ammonium chloride or tetraethyl ammonium chloride; pyridine or triphenylphosphine as a catalyst, in an organic solvent, at a reaction temperature of 50 to 1500° C., for several to several tens hours. Amount of introduction of alicyclic epoxy unsaturated compound is preferably controlled so as to adjust the acid value of the resultant polymer to 5 to 200 KOH·mg/g. Molecular weight is in the range from 500 to 5,000,000 on the weight average basis, and preferably in the range from 1,000 to 500,000.

The epoxy unsaturated compound usable herein includes those having a glycidyl group as an epoxy group, such as glycidyl (meth)acrylate and allyl glycidyl ether, wherein unsaturated compounds having alicyclic epoxy groups are preferable. These sorts of compounds may be referred to, and selectable from those typically described in paragraph [0045] of JP-A-2009-265518, the content of which is incorporated by reference into this specification.

Details of these polymerizable compounds, regarding the structures thereof, independent/combined mode of use, amount of addition and so forth, are arbitrarily determined so as to be matched to final performance designs of the near-infrared absorbing composition. For example, a structure having a large content of unsaturated group is preferable from the viewpoint of sensitivity, and is bi-functional or of higher functionality in most cases. On the other hand, from the viewpoint of improving strength of the near-infrared cut filter, the structure is preferably tri-functional or of higher functionality. Also a method of controlling both of sensitivity and strength, by combining the compounds having different numbers of functionality and different polymerizable groups (for example, acrylic ester, methacrylic ester, styrene-based compound, vinyl ether-based compound), is effective. Selection and usage of the polymerizable compound are critical factors also with respect to compatibility and dispersibility of other components (for example, metal oxide, dye, or polymerization initiator) contained in the near-infrared absorbing composition. For example, the compatibility may be improved by using low-purity compound, or by using two or more species in combination. Alternatively, a specified structure is selectable from the viewpoint of improving adhesiveness to a hard surface such as supporting member.

Amount of addition of the polymerizable compound to the composition of the present invention is preferably 1 to 80% by mass of the whole solid content excluding the solvent, more preferably 15 to 70% by mass, and particularly 20 to 60% by mass.

Only one species of the polymerizable compound, or two or more species thereof may be used. When two or more species are used in combination, the total amount falls in the ranges described above.

### <Binder Polymer>

The near infrared absorptive liquid composition of the present invention may further contain a binder polymer, in addition to the polymerizable compound, as necessary, for example for the purpose of improving film characteristics. An alkali-soluble resin is preferably used as the binder polymer. Use of the alkali-soluble resin is effective in improving the heat resistance, and in finely controlling the coatability.

The alkali-soluble resin is properly selectable from linear organic high polymers, having in the molecule thereof (preferably, in the molecule having an acrylic copolymer or styrene-based copolymer in the principal chain) at least one group capable of enhancing alkali solubility. Polyhydroxy styrene-based resin, polysiloxane-based resin, acrylic resin, acrylamide-based resin, and acryl/acrylamide copolymer resin are preferable from the viewpoint of heat resistance, whereas, acrylic resin, acrylamide-based resin, and acryl/acrylamide copolymer resin are preferable from the viewpoint of controlling the developability.

The group capable of enhancing alkali solubility (also referred to as “acid group”, hereinafter) is exemplified by carboxyl group, phosphoric acid group, sulfonic acid group, and phenolic hydroxyl group. Those making the resin soluble into organic solvent and developable with a weak-alkaline aqueous solution are preferable. (Meth)acrylic acid is particularly preferable. The acid group may be of a single species, or of two or more species.

Examples of monomer capable of adding an acid group after polymerization include a monomer having a hydroxy group such as 2-hydroxyethyl (meth)acrylate, a monomer having an epoxy group such as glycidyl (meth)acrylate, and a monomer having an isocyanate group such as 2-isocyanate ethyl (meth)acrylate. The group for introducing an acid group may be of a single species or of two or more species. The acid group may be introduced into the alkali-soluble binder, for example, by polymerizing the monomer having the acid group and/or the monomer capable of adding an acid group after polymerization (occasionally referred to as “acid group introducing monomer”, hereinafter) as a monomer component. For the case where the acid group is introduced by using, as the monomer component, the monomer capable of introducing an acid group after polymerization, a treatment for adding the acid group described later will be necessary after the polymerization.

The alkali-soluble resin may be manufactured, for example, by a publicly known radical polymerization process. Conditions for polymerization regarding temperature, pressure, species and amount of radical initiator, and species of solvent are readily adjustable by those skilled in the art, and may also be determined by experiments.

The linear organic high polymer used as the alkali-soluble resin is preferably a polymer having a carboxylic acid in the side chains thereof, and this sort of polymer may be referred to, and selectable from compounds typically described in paragraph [0253] of JP-A-2012-162684, the content of which is incorporated by reference into this specification.

The alkali-soluble resin also preferably contains represented by the formula (ED) below:

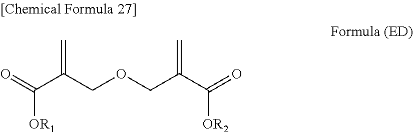

(in the formula (ED), each of R¹ and R² independently represents a hydrogen atom or a C₁₋₂₅ hydrocarbon group which may have a substituent). In this way, the composition of the present invention may forma cured coated film especially excellent in the heat resistance and translucency. In the formula (1) representing the ether dimer, the C₁₋₂₅ hydrocarbon group which may have a substituent represented by R¹ and R² is exemplified by, but not specially limited to, straight-chain or branched alkyl group such as methyl, ethyl, n-propyl, isopropyl, n-butyl, isobutyl, t-butyl, t-amyl, stearyl, lauryl, and 2-ethylhexyl groups; aryl group such as phenyl group; alicyclic group such as cyclohexyl, t-butylcyclohexyl, dicyclopentadienyl, tricyclodecanyl, isobornyl, adamantyl, and 2-methyl-2-adamantyl groups; alkoxy-substituted alkyl group such as 1-methoxyethyl, and 1-ethoxyethyl groups; and aryl group-substituted alkyl group such as benzyl group. Among them, substituents having a primary or secondary carbon less eliminatable by acid or heat, such as methyl, ethyl, cyclohexyl and benzyl, are preferable from the viewpoint of heat resistance.

Specific examples of the ether dimer may be referred to, and selectable from those typically described in paragraph [0257] of JP-A-2012-162684, the content of which is incorporated by reference into this specification.

In the present invention, content of a structural unit derived from the ether dimer is 1 to 50 mol % of the whole polymer, and more preferably 1 to 20 mol %.

Any other monomer may be copolymerized, in addition to the ether dimer.

The other monomer copolymerizable together with the ether dimer is exemplified by a monomer for introducing an acid group, monomer for introducing a radical polymerizable double bond, monomer for introducing an epoxy group, and other copolymerizable monomers besides those described above. Only one species of the monomer, or two or more species thereof may be used.

The monomer for introducing an acid group is exemplified by monomers having a carboxyl group such as (meth)acrylic acid and itaconic acid, monomers having a phenolic hydroxy group such as N-hydroxyphenyl maleimide, and monomers having a carboxylic anhydride group such as maleic anhydride and itaconic anhydride. Among them, (meth)acrylic acid is particularly preferable.

The monomer for introducing an acid group may also be a monomer capable of providing the acid group after polymerization, and is exemplified by monomers having a hydroxy group such as 2-hydroxyethyl (meth)acrylate, monomers having an epoxy group such as glycidyl (meth)acrylate, and monomers having an isocyanate group such as 2-isocyanate ethyl (meth)acrylate. When the monomer for introducing a radical polymerizable double bond, or the monomer capable of providing an acid group after polymerization is used, it is necessary to conduct a treatment for providing an acid group after polymerization. The treatment for providing an acid group after polymerization will vary depending on species of the monomer, and may be exemplified by the followings. When the monomer having a hydroxy group is used, the treatment will be such as adding an acid anhydride such as succinic anhydride, tetrahydrophthalic anhydride, and maleic anhydride. When the monomer having an epoxy group is used, the treatment will be such as adding an acid anhydride such as succinic anhydride, tetrahydrophthalic anhydride or maleic anhydride, to a hydroxy group produced after adding a compound having an amino group and an acid group, such as N-methylaminobenzoic acid or N-methylaminophenol, or produced after adding an acid such as (meth)acrylic acid. When the monomer having an isocyanate group is used, the treatment will be such as adding a compound having a hydroxy group and an acid group, such as 2-hydroxybutyric acid.

When the polymer, obtained by polymerizing the monomer component which contains a compound represented by the formula (ED), contains the monomer for introducing an acid group, the content of which, although not specifically limited, is preferably 5 to 70% by mass of the total monomers, and more preferably 10 to 60% by mass.

The monomer for introducing a radical polymerizable double bond is exemplified by carboxyl group-containing monomer such as (meth)acrylic acid and itaconic acid; monomers having a carboxylic acid anhydride group such as maleic anhydride and itaconic anhydride; and monomers having an epoxy group such as glycidyl (meth)acrylate, 3,4-epoxy cyclohexyl methyl (meth)acrylate, and o- (or m-, or p-)vinyl benzylglycidyl ether. When the monomer for introducing a radical polymerizable double bond is used, it is necessary to conduct a treatment for providing a radical polymerizable double bond after polymerization. The treatment for providing a radical polymerizable double bond after polymerization will vary depending on species of the monomer to be used capable of providing a radical polymerizable double bond, and may be exemplified by the followings. When the monomer having a carboxy group such as (meth)acrylic acid or itaconic acid is used, the treatment will be such as adding a compound having both of an epoxy group and a radical polymerizable double bond, such as glycidyl (meth)acrylate, 3,4-epoxy cyclohexyl methyl (meth)acrylate, o- (or m-, or p-)vinyl benzylglycidyl ether. When the monomer having a carboxylic acid anhydride group such as maleic anhydride or itaconic anhydride is used, the treatment will be such as adding a compound having both of a hydroxy group and a radical polymerizable double bond, such as 2-hydroxyethyl (meth)acrylate. When the monomer having an epoxy group, such as glycidyl (meth)acrylate, 3,4-epoxy cyclohexyl methyl (meth)acrylate, or o- (or m-, or p-)vinyl benzylglycidyl ether, is used, the treatment will be such as adding a compound having both of an acid group and a radical polymerizable double bond, such as (meth)acrylic acid.

When the polymer obtained by polymerizing the compound represented by the formula (ED) contains the monomer for introducing a radical polymerizable double bond, the content of which, although not specifically limited, is preferably 5 to 70% by mass of the total monomers, and more preferably 10 to 60% by mass.

The monomer for introducing an epoxy group is exemplified by glycidyl (meth)acrylate, 3,4-epoxy cyclohexyl methyl (meth)acrylate, and o- (or m-, or p-)vinyl benzylglycidyl ether.

When the polymer obtained by polymerizing the monomer component, which contains a compound represented by the formula (ED), contains the monomer for introducing an epoxy group, the content of which, although not specifically limited, is preferably 5 to 70% by mass of the total monomers, and more preferably 10 to 60% by mass.

Other copolymerizable monomers may be referred to, and selectable from compounds typically described in paragraph [0328] of JP-A-2012-046629, the content of which is incorporated by reference into this specification.

When the polymer obtained by polymerizing the monomer component, which contains a compound represented by the formula (ED), contains the other copolymerizable monomer, the content of which, although not specifically limited, is preferably 95% by mass or less, and more preferably 85% by mass or less.

Weight-average molecular weight of the polymer obtained by polymerizing the monomer component which contains a compound represented by the formula (ED) is preferably, but not specifically limited to 2,000 to 200,000, more preferably 5,000 to 100,000, and furthermore preferably 5,000 to 20,000 from the viewpoint of viscosity of a colored radiation-sensitive composition, and heat resistance of a coated film formed by the composition.

When the polymer obtained by polymerizing the monomer component which contains a compound represented by the formula (ED) has an acid group, the acid value is preferably 30 to 500 mg KOH/g, and more preferably 50 to 400 mg KOH/g.

The polymer obtained by polymerizing the monomer component which contains a compound represented by the formula (ED) may readily be obtained, by polymerizing at least the monomer which essentially contains an ether dimer. In this process, the polymerization and cyclization of the ether dimer concurrently proceed to form a tetrahydropyran structure.

A method used for synthesizing the polymer, obtainable by polymerizing the monomer component which contains a compound represented by the formula (ED), is arbitrarily selectable from a variety of publicly-known methods of polymerization without special limitation, wherein solution polymerization process is particularly preferable. In more details, the polymer, obtainable by polymerizing the monomer component which contains a compound represented by the formula (ED), may be synthesized according to a method of synthesizing polymer (a) described in JP-A-2004-300204.

Exemplary polymers, obtainable by polymerizing the monomer component which contains a compound represented by the formula (ED), will now be listed below, without limiting the present invention to these compounds. Note that compositional ratios shown in the exemplary compound below is given by mol %.

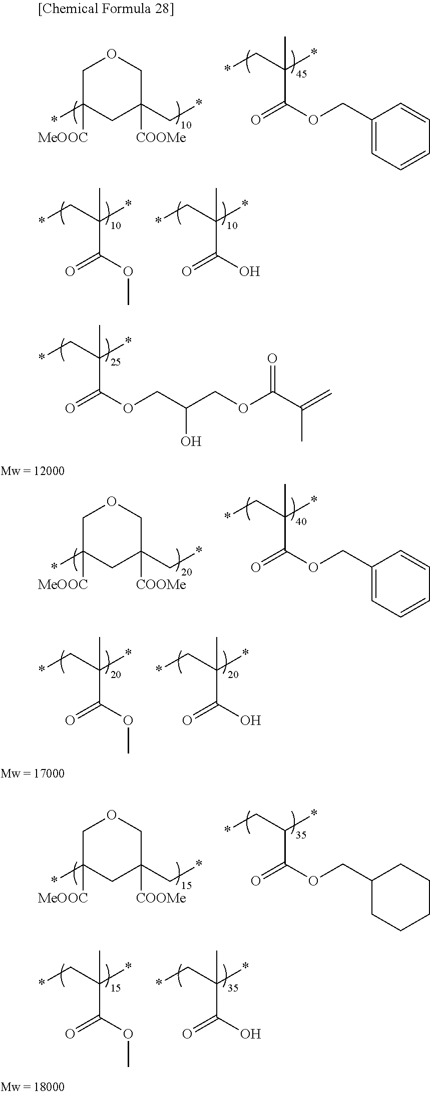

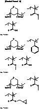

In particular in the present invention, preferable are polymers obtained by copolymerizing all of dimethyl-2,2′-[oxybis(methylene)]bis-2-propenoate (referred to as “DM”, hereinafter), benzyl methacrylate (referred to as “BzMA”, hereinafter), methyl methacrylate (referred to as “MMA”, hereinafter), methacrylic acid (referred to as “MAA”, hereinafter), and glycidyl methacrylate (referred to as “GMA”, hereinafter). In particular, molar ratio of DM:BzMA:MMA:MAA:GMA is preferably (5 to 15):(40 to 50):(5 to 15):(5 to 15):(20 to 30). These components preferably account for 95% by mass or more of the components composing the copolymer used in the present invention. Weight-average molecular weight of the polymer is preferably 9,000 to 20,000.

In the present invention, also an alkali-soluble phenol resin is preferably used. The alkali-soluble phenol resin is exemplified by novolac resin, vinyl polymer and so forth.

The novolac resin is typically exemplified by those obtainable by condensing phenols and aldehydes, under the presence of an acid catalyst. The phenols are exemplified by phenol, cresol, ethylphenol, butyl phenol, xylenol, phenylphenol, catechol, resorcinol, pyrogallol, naphthol, and bisphenol-A.

The aldehydes are exemplified by formaldehyde, paraformaldehyde, acetaldehyde, propionaldehyde, and benzaldehyde.

Only one species each of the phenols and aldehydes may be used, or two or more each species of them may be used in combination.

The novolac resin may be controlled in the molecular weight distribution thereof, typically by fractionation. The novolac resin may also be mixed with a low molecular weight component having a phenolic hydroxy group such as bisphenol-C and bisphenol-A.

As the alkali-soluble resin, particularly preferable are multi-component copolymer such as composed of benzyl (meth)acrylate/(meth)acrylic acid copolymer, and benzyl (meth)acrylate/(meth)acrylic acid/other monomer. Other examples include copolymer having 2-hydroxyethyl methacrylate co-polymerized therein, and those described in JP-A-H7-140654 including 2-hydroxypropyl (meth)acrylate/polystyrene macromonomer/benzyl methacrylate/methacrylic acid copolymer, 2-hydroxy-3-phenoxypropyl acrylate/polymethyl methacrylate macromonomer/benzyl methacrylate/methacrylic acid copolymer, 2-hydroxyethyl methacrylate/polystyrene macromonomer/methyl methacrylate/methacrylic acid copolymer, and 2-hydroxyethyl methacrylate/polystyrene macromonomer/benzyl methacrylate/methacrylic acid copolymer.

Acid value of the alkali-soluble resin is preferably 30 mg KOH/g to 200 mg KOH/g, more preferably 50 mg KOH/g to 150 mg KOH/g, and most preferably 70 to 120 mg KOH/g.

Weight average molecular weight (Mw) of the alkali-soluble resin is preferably 2,000 to 50,000, more preferably 5,000 to 30,000, and most preferably 7,000 to 20,000.

Content of the binder polymer in the present invention is preferably 1% by mass to 80% by mass of the whole solid content of the composition, more preferably 10% by mass to 70% by mass, and furthermore preferably 20 to 60% by mass.

### <Polymerization Initiator>

The composition of the present invention may also contain a polymerization initiator. The polymerization initiator may be of a single species, or of two or more species. When two or more species are used, the total content is adjusted to the range described below. The content is preferably 0.01% by mass to 30% by mass, more preferably 0.1% by mass to 20% by mass, and particularly 0.1% by mass to 15% by mass.

The polymerization initiator is properly selectable depending on purposes, without special limitation so long as it can initiate polymerization of the polymerizable compound with the aid of light and/or heat, and is preferably a photopolymerizable compound. When the polymerization is triggered by light, the polymerization initiator preferably shows photosensitivity over the region from ultraviolet radiation to visible light.

On the other hand, when the polymerization is triggered by heating, the polymerization initiator is preferably decomposable at 150° C. to 250° C.

The polymerization initiator preferably has at least an aromatic group, and is exemplified by acylphosphine compound, acetophenone-based compound, α-aminoketone compound, benzophenone-based compound, benzoin ether-based compound, ketal derivative compound, thioxanthone compound, oxime compound, hexaaryl biimidazole compound, trihalomethyl compound, azo compound, organic peroxide, diazonium compound, iodonium compound, sulfonium compound, azinium compound, benzoin ether-based compound, ketal derivative compound, onium salt compound, metallocene compound, organic borate compound, and disulfone compound.

From the viewpoint of sensitivity, preferable are the oxime compound, acetophenone-based compound, α-aminoketone compound, trihalomethyl compound, hexaaryl biimidazole compound and thiol compound.

Examples of the polymerization initiator preferably used in the present invention will be listed below, but not intended to limit the present invention.

The acetophenone-based compound, the trihalomethyl compound, the hexaaryl biimidazole compound, and the oxime compound may be referred to, and selectable from compounds specifically described in paragraphs [0020] to [0023] of JP-A-2012-122045, the content of which is incorporated by reference into this specification.

More preferably, cyclic oxime compound described in JP-A-2007-231000 and JP-A-2007-322744 are used in a successful manner.

Still other examples include oxime compounds having specified substituents described in JP-A-2007-269779, and oxime compounds having a thioaryl group described in JP-A-2009-191061.

More specifically, also oxime compounds represented by the formula (1) below are preferable. The oxime may be an E-isomer, or Z-isomer, or mixture of E-isomer and Z-isomer, with respect to the N—O bond.

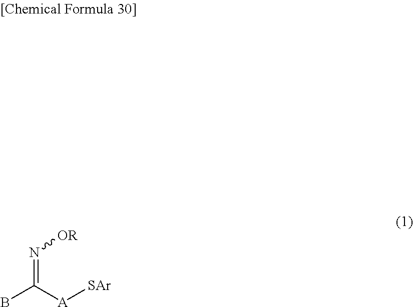

(In the formula (1), each of R and B independently represents a monovalent substituent, A represents a divalent organic group, and Ar represents an aryl group.)

The monovalent substituent represented by R is preferably a monovalent non-metallic atomic group. The monovalent non-metallic atomic group is exemplified by alkyl group, aryl group, acyl group, alkoxycarbonyl group, aryloxycarbonyl group, heterocyclic group, alkylthiocarbonyl group, and arylthiocarbonyl group. Each of these groups may have one or more substituents. The substituent may further be substituted by other substituent.

Examples of the substituent include halogen atom, aryloxy group, alkoxycarbonyl group or aryloxycarbonyl group, acyloxy group, acyl group, alkyl group, and aryl group.

The alkyl group which may have a substituent is preferably a C₁₋₃₀ alkyl group. More specifically, the alkyl group may be referred to, and selectable from compounds typically described in paragraph [0026] of JP-A-2012-032556, the content of which is incorporated by reference into this specification.

The aryl group which may have a substituent is preferably a C₆₋₃₀ aryl group. More specifically, the aryl group may be referred to, and selectable from compounds typically described in paragraph [0027] of JP-A-2012-032556, the content of which is incorporated by reference into this specification.

The acyl group which may have a substituent is preferably a C₂₋₂₀ acyl group. More specifically, the acyl group may be referred to, and selectable from compounds typically described in paragraph [0028] of JP-A-2012-032556, the content of which is incorporated by reference into this specification.

The alkoxycarbonyl group which may have a substituent is preferably a C₂₋₂₀ alkoxycarbonyl group. More specifically, the alkoxycarbonyl group may be referred to, and selectable from compounds typically described in paragraph [0029] of JP-A-2012-032556, the content of which is incorporated by reference into this specification.

The aryloxycarbonyl group which may have a substituent may be referred to, and selectable from compounds typically described in paragraph [0030] of JP-A-2012-032556, the content of which is incorporated by reference into this specification.

The heterocyclic group which may have a substituent is preferably an aromatic or aliphatic heterocycle containing a nitrogen atom, oxygen atom, sulfur atom or phosphorus atom.

More specifically, the heterocyclic group may be referred to, and selectable from compounds typically described in paragraph [0031] of JP-A-2012-032556, the content of which is incorporated by reference into this specification.

The alkylthiocarbonyl group which may have a substituent may be referred to, and selectable from compounds typically described in paragraph [0032] of JP-A-2012-032556, the content of which is incorporated by reference into this specification.

The arylthiocarbonyl group which may have a substituent may be referred to, and selectable from compounds typically described in paragraph [0033] of JP-A-2012-032556, the content of which is incorporated by reference into this specification.

The monovalent substituent represented by B is exemplified by aryl group, heterocyclic group, arylcarbonyl group, or heterocyclic carbonyl group. These groups may have one or more substituents. The substituent may be exemplified by those described previously. The above-described substituents may further be substituted by other substituents.

Among them, particularly preferable structures are listed below.

In the structures below, Y, X and n are synonymous to Y, X and n in the formula (2) described later, the same will also apply to the preferable ranges.

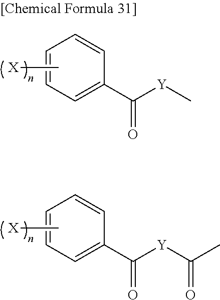

The divalent organic group represented by A is exemplified by C₁₋₁₂ alkylene group, cyclohexylene group, and alkynylene group. Each of these groups may have one or more substituents. The substituent is exemplified by the substituents described previously. The above-described substituents may further be substituted by other substituents.

In particular, from the viewpoint of enhancing the sensitivity and suppressing coloration over time under heating, A preferably represents an unsubstituted alkylene group; an alkylene group substituted by an alkyl group (for example, methyl group, ethyl group, tert-butyl group or dodecyl group); an alkylene group substituted by an alkenyl group (for example, vinyl group or allyl group); or an alkylene group substituted by an aryl group (for example, phenyl group, p-tolyl group, xylyl group, cumenyl group, naphthyl group, anthryl group, phenanthryl group or styryl group).

The aryl group represented by Ar is preferably a C₆₋₃₀ aryl group, and may have a substituent. The substituent is exemplified by those same as the substituents introduced into the substituted aryl group exemplified previously as the specific examples of the aryl group which may have a substituent.

Among others, substituted or unsubstituted phenyl group is preferable in view of enhancing the sensitivity, and suppressing coloration with time under heating.

In the formula (1), “SAr” structure formed by Ar and the adjacent S is preferably a structure typically described in paragraph [0040] of JP-A-2012-032556, the content of which is incorporated by reference into this specification.

The oxime compound is also preferably a compound represented by the formula (2) below:

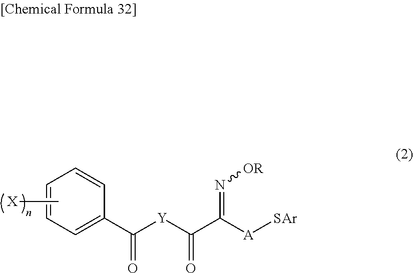

(in the formula (2), each of R and X independently represents a monovalent substituent, each of A and Y independently represents a divalent organic group, Ar represents an aryl group, and n represents an integer of 0 to 5).

R, A and Ar in the formula (2) are synonymous to R, A and Ar in the formula (1), the same will also apply to the preferable ranges.

The monovalent substituent represented by X is exemplified by alkyl group, aryl group, alkoxy group, aryloxy group, acyl oxy group, acyl group, alkoxycarbonyl group, amino group, heterocyclic group and halogen atom. Each of these group may have one or more substituents. The substituents may be exemplified by those described previously. The substituent may further be substituted by other substituent.

Among them, X preferably represents an alkyl group, from the viewpoint of improving the solubility into solvents and absorption efficiency in the longer wavelength region.

n in the formula (2) represents an integer of 0 to 5, and preferably an integer of 0 to 2.

The divalent organic group represented by Y is exemplified by those having structures below. Note that, in the groups shown below, * represents a site of bonding with the carbon atom adjacent to Y in the formula (2).

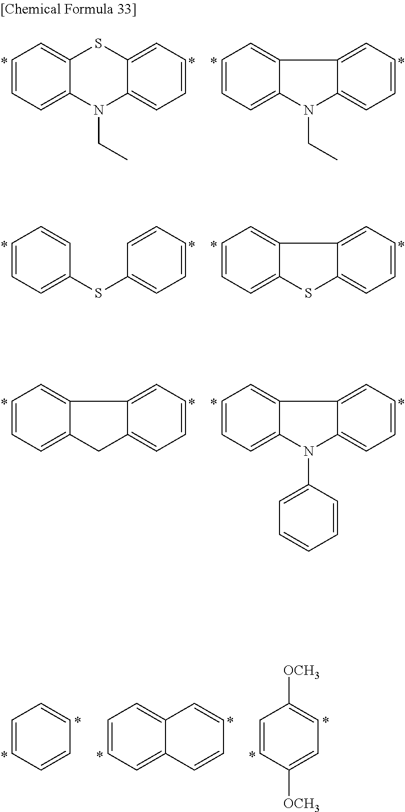

In particular, the structures shown below are preferable from the viewpoint of increasing the sensitivity.

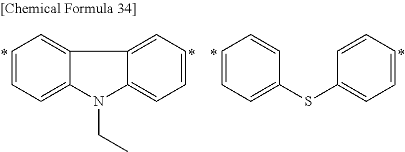

The oxime compound is also preferably a compound represented by the formula (3) below.

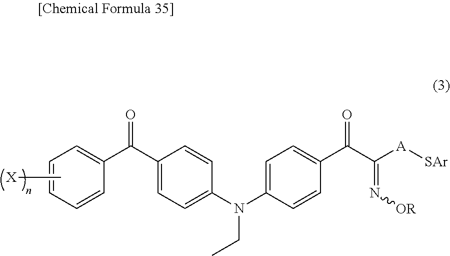

R, X, A, Ar and n in the formula (3) are synonymous to R, X, A, Ar and n in the formula (2), the same will also apply to the preferable ranges.

Specific examples of the oxime compound which are preferably used may be referred to, and selectable from compounds typically described in paragraph [0033] of JP-A-2012-032556, and paragraph [0033] of JP-A-2012-122045, the content of which is incorporated by reference into this specification. (PIox-1) to (PIox-13) will be shown below, without limiting the present invention.

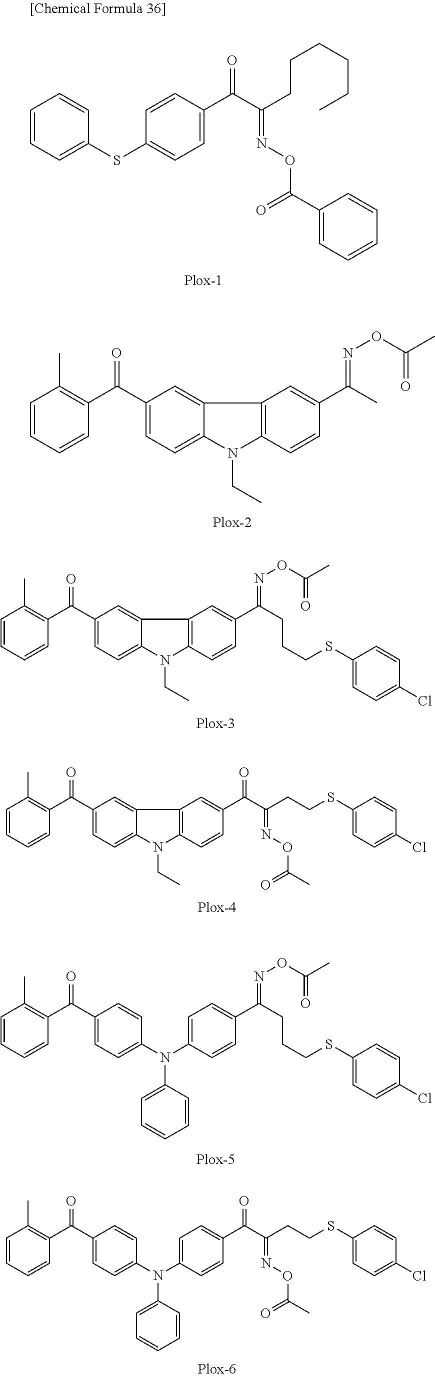 [SMILES: CCCCCC/C(=N\OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCCSc1ccc(Cl)cc1)c1ccc(N(c2ccccc2)c2ccc(C(=O)c3ccccc3C)cc2)cc1 ; CC(=O)O/N=C(\CCSc1ccc(Cl)cc1)C(=O)c1ccc(N(c2ccccc2)c2ccc(C(=O)c3ccccc3C)cc2)cc1]

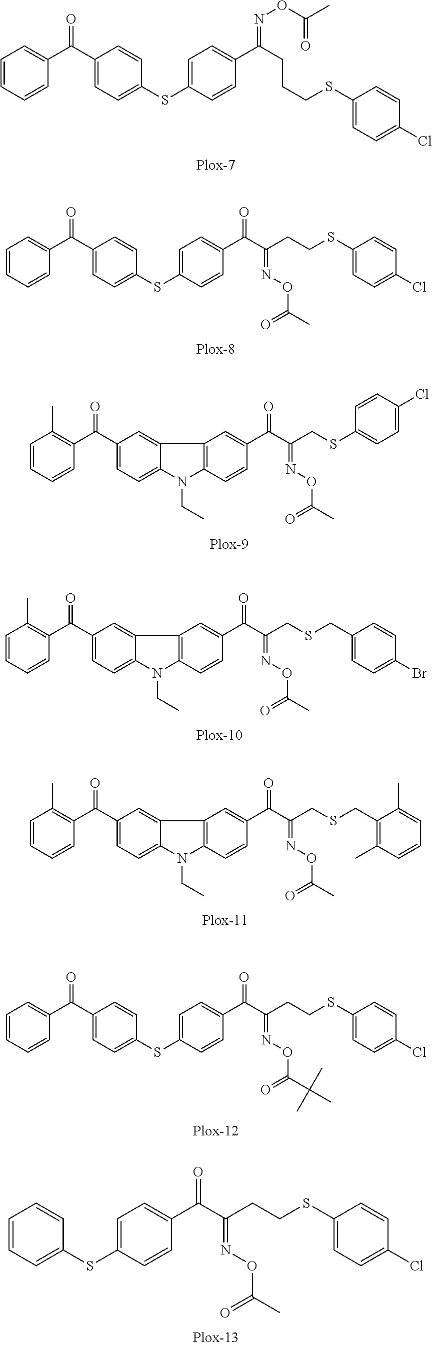

The oxime compound preferably has a maximum absorption wavelength in the wavelength range from 350 nm to 500 nm, more preferably from 360 nm to 480 nm, and particularly shows large absorbance at 365 nm and 455 nm.

From the viewpoint of sensitivity, the oxime compound preferably has a molar extinction coefficient at 365 nm or 405 nm of 3,000 to 300,000, more preferably 5,000 to 300,000, and particularly 10,000 to 200,000.

The molar extinction coefficient of the compound is measurable by any of publicly known methods, and is specifically measured typically by using a UV-visible spectrophotometer (Cary-5 spectrophotometer, from Varian, Inc.), using ethyl acetate as a solvent, at a concentration d of 0.01 g/L.

The photo-polymerization initiator is more preferably selectable from the group consisting of oxime compound, acetophenone-based compound and acyl phosphine compound. More specifically, also amino acetophenone-based initiator described in JP-A-H10-291969, acylphosphine oxide-based initiator described in Japanese Patent No. 4225898, and the oxime-based initiator described above may be used. Also compounds described in JP-A-2001-233842 may be used as the oxime-based initiator.

The acetophenone-based initiator is commercially available under the trade names of IRGACURE-907, IRGACURE-369 and IRGACURE-379 (all from BASF Japan Ltd.). The acylphosphine-based initiator is commercially available under the trade names of IRGACURE-819 and DAROCUR-TPO (both from BASF Japan Ltd.).

### <Other Components>

For the near-infrared absorbing composition of the present invention, in addition to the essential components and the preferable additives, any other component(s) may arbitrarily be selected and used depending on purposes, provided that the effects of the present invention are not adversely affected.

Other components are exemplified by binder polymer, dispersant, sensitizer, crosslinking agent, hardening accelerator, filler, heat hardening accelerator, heat polymerization inhibitor and plasticizer. It is also allowable to combine and use adhesion enhancer to the surface of substrate and other auxiliaries (for example, electro-conductive particle, filler, defoaming agent, flame retarder, leveling agent, stripping accelerator, antioxidant, perfume, surface tension modifier, and chain transfer agent).

By appropriately mixing these components, target properties of the near-infrared absorbing filter, such as stability and film properties, become adjustable.

These components are referred to, and selectable from components typically described in paragraphs [0183] to [0260] of JP-A-2012-003225, paragraphs [0101] to [0102] of JP-A-2008-250074, paragraphs [0103] to [0104] of JP-A-2008-250074, and paragraphs [0107] to [0109] of JP-A-2008-250074, the content of which is incorporated by reference into this specification.

Since the near-infrared absorbing composition of the present invention may be given in the form of liquid, so that near-infrared cut filter may readily be manufactured only by a simple process of spin coating, so that poor manufacturability of the conventional near-infrared cut filter described above may be improved.

While applications of the near-infrared absorbing composition of the present invention are not specifically limited, they are exemplified by a near-infrared cut filter on the light receiving side of the substrate for solid state image sensing device (for example, a near-infrared cut filter used for wafer level lenses), and a near-infrared cut filter on the back side of the substrate for solid state image sensing device (on the side opposite to the light receiving side). The composition is more preferably used for a light blocking film on the light receiving side of the substrate for solid state image sensing device. In particular, in the present invention, the composition is preferably used in the form of coated film formed on an image sensor for the solid state image sensing device.

Viscosity of the near-infrared absorbing composition of the present invention, when used for forming the infrared cut layer by coating, preferably falls in the range from 1 mPa·s or larger and 3,000 mPa·s or smaller, more preferably 10 mPa·s or larger and 2,000 mPa·s or smaller, and furthermore preferably from 100 mPa·s or larger and 1,500 mPa·s or smaller.

When the near-infrared absorbing composition of the present invention is used for the near-infrared cut filter disposed on the light receiving side of the substrate for solid state image sensing device, and is used for forming the infrared cut layer by coating, the viscosity is preferably 10 mPa·s or larger and 3,000 mPa·s or smaller, from the viewpoint of ensuring thick film formability and uniformity in coating, more preferably 500 mPa·s or larger and 1,500 mPa·s or smaller, and most preferably 700 mPa·s or lager and 1,400 mPa·s or smaller.

The present invention also relates to a stack which includes the near-infrared cut layer formed by curing the near-infrared absorbing composition, and a dielectric multi-layered film. A preferable embodiment of the stack of the present invention relates to an embodiment having the near-infrared cut layer provided on the transparent support, or, an embodiment having the transparent support, the near-infrared cut layer and a dielectric multi-layered film provided in this order, and more preferably, an embodiment having the transparent support, the near-infrared cut layer and the dielectric multi-layered film provided in this order in a consecutive manner.

The dielectric multi-layered film used in the present invention is a film capable of reflecting and/or absorbing near-infrared radiation.

Ceramics is typically used as a material for composing the dielectric multi-layered film. In order to form the near-infrared cut filter making use of an effect of interference of light, it is preferable to use two or more species of ceramics with different refractive indices.

Alternatively, it is also preferable to use a noble metal film showing absorbance in the near-infrared region, while considering the thickness and the number of layers so as not to adversely affect the transmissivity of visible light through the near-infrared cut filter.

A specific configuration preferably used as the dielectric multi-layered film is such as having high refractive index material layers and low refractive index material layers alternately stacked therein.

The high refractive index material layer may be configured by a material having a refractive index of 1.7 or larger, wherein the material is generally selectable from those having a refractive index of 1.7 to 2.5.

The material is exemplified by titanium oxide (titania), zirconium oxide, tantalum pentoxide, niobium pentoxide, lanthanum oxide, yttrium oxide, zinc oxide, zinc sulfide, indium oxide, and materials mainly composed of these oxides and doped with a small amount of titanium oxide, tin oxide and/or cerium oxide. Among them, titanium oxide (titania) is preferable.

The low refractive index material layer may be configured by a material having a refractive index of 1.6 or smaller, wherein the material is generally selectable from those having a refractive index of 1.2 to 1.6.

The material is exemplified by silica, alumina, lanthanum fluoride, magnesium fluoride and aluminum sodium hexafluoride. Among them, silica is preferable.

Thickness of each of the high refractive index material layer and the low refractive index material layer is generally in the range from 0.1λ to 0.5λ, where λ (nm) is wavelength of infrared to be blocked. If the thickness falls outside the above-described range, product (n×d) of refractive index (n) and thickness (d) may largely depart from optical thickness given by λ/4, and which destructs the optical relationship between reflection and refraction, and tends to degrade controllability of blocking/transmission at specific wavelength.

The number of stacking of layers in the dielectric multi-layered film is preferably 5 to 50, and more preferably 10 to 45.

Method of forming the dielectric multi-layered film is not specifically limited, and is exemplified by a method of forming a dielectric multi-layered film by alternately stacking the high refractive index material layers and the low refractive index material layers typically by CVD, sputtering, vacuum evaporation or the like, and then bonding it to the film using an adhesive, and a method of forming the dielectric multi-layered film by alternately stacking the high refractive index material layers and the low refractive index material layers, directly on the film typically by CVD, sputtering, vacuum evaporation or the like.

If the substrate tends to warp when the dielectric multi-layered film is formed by vacuum evaporation, the warping may be canceled by depositing the dielectric multi-layered film on both surfaces of the substrate, or by irradiating radiation such as UV radiation onto the surface of the substrate having the dielectric multi-layered film formed thereon. The radiation may be irradiated concurrently with vacuum evaporation of the dielectric multi-layered film, or may separately be irradiated after completion of the vacuum evaporation.

The present invention also relates to a near-infrared cut filter having the near-infrared cut filter obtained by using the above-described near-infrared absorbing composition of the present invention, and the stack. Since this sort of near-infrared cut filter is composed of the near-infrared absorbing composition of the present invention, so that the near-infrared cut filter has a large blocking performance in the near-infrared region (near-infrared blocking performance), a large translucency in the visible light region (visible light translucency), and excellent weatherability such as light resistance and moisture resistance. In particular, the near-infrared cut filter of the present invention is beneficial in the wavelength range from 700 to 2,500 nm.

The present invention also relates to a near-infrared cut filter configured by a transparent support, a near-infrared cut layer formed by curing a near-infrared absorbing composition containing a copper complex having a maximum absorption wavelength in the near-infrared absorption region, and a dielectric multi-layered film, stacked in this order. The copper complex having a maximum absorption wavelength in the near-infrared absorption region is synonymous to the copper complex used for the near-infrared absorbing composition of the present invention, the same will also apply to the preferable ranges.

The present invention also relates to a method of manufacturing a near-infrared cut filter, the method includes applying (preferably by coating or printing, and more preferably by spin coating or screen printing) the near-infrared absorbing composition to thereby form a film, on the light receiving side of the substrate for solid state image sensing device.

In the process of manufacturing the near-infrared cut filter, first, a film is formed using the near-infrared absorbing composition of the present invention. The film is not specifically limited so long as it is formed while containing the near-infrared absorbing composition. Thickness and structure of stacking may arbitrarily be selectable depending on purposes.

An exemplary method of forming the film is such as directly applying (preferably by coating), onto the support, the near-infrared absorbing composition of the present invention (coating liquid having the solid components in the composition dissolved, emulsified or dispersed in the solvent), and then by drying it to form the film.

The support may be a transparent substrate composed of glass or the like, or may be a substrate for solid state image sensing device, or may be another substrate separately provided on the light receiving side of the substrate for solid state image sensing device (for example, a glass substrate 30 described later), or may be a layer such as planarizing layer provided on the light receiving side of the substrate for solid state image sensing device.

The near-infrared absorbing composition (coating liquid) may be applied, for example, by a method of using a spin coater, slit-and-spin coater or the like.

Conditions for drying of the coated film may vary depending on species of the solvent and ratio of use. The drying is generally proceeded at 60° C. to 150° C., for 30 seconds to 15 minutes or around.

Thickness of the film is arbitrarily selectable depending on purposes without special limitation, and is preferably 1 μm to 500 μm for example, more preferably 1 μm to 300 μm, and particularly 1.0 μm to 200 μm.

The method of forming the near-infrared cut filter using the near-infrared absorbing composition of the present invention may further include any other process.

The other process may arbitrarily selectable depending on purposes without special limitation, and is exemplified by surface treatment, pre-baking, hardening, and post-baking of the base.

### <Preheating Process, Postheating Process>

Heating temperature in the preheating process and the postheating process is generally 80° C. to 200° C., and preferably 90° C. to 150° C.

Heating time in the preheating process and the postheating process is generally 30 seconds to 240 seconds, and preferably 60 seconds to 180 seconds.

### <Curing Process>

The curing process is provided, as necessary, for curing the formed film. By the process, the mechanical strength of the near infrared cut filter may be improved.

The curing process is properly selectable depending on purposes, without special limitation. Preferable examples include whole exposure and whole heating. Note that the word “exposure” in the context of the present invention is used not only for exposure by light of various wavelength, but also for exposure by electron beam, and irradiation of radioactive ray such as X-ray.

The exposure is preferably effected by irradiation of radioactive ray. Particularly preferable examples of the radioactive ray usable for the exposure include electron beam, and ultraviolet radiation and visible light such as KrF, ArF, g-line, h-line and i-line. Particularly, KrF, g-line, h-line and i-line are preferable.

Method of exposure include exposure using a stepper, and exposure using a high-pressure mercury lamp.

Exposure energy is preferably 5 mJ/cm² to 3,000 mJ/cm², more preferably 10 mJ/cm² to 2,000 mJ/cm², and most preferably 50 mJ/cm² to 1,000 mJ/cm².

Method of the whole exposure is exemplified by method of exposing the entire surface of the formed film. When the near infrared absorptive liquid composition contains a polymerizable compound, curing of a polymerizable component generated from the composition in the film is promoted, so that the film is further cured, and is improved in the mechanical strength and durability.

Apparatus for implementing the whole exposure is selectable depending on purposes, without special limitation. Preferable examples include a UV exposure apparatus typically using ultra-high pressure mercury lamp.

Methods of whole heating process is exemplified by method of heating of the entire surface of the formed film. By the whole heating, strength of the patterned film may be enhanced.

Heating temperature in the whole heating is preferably 120° C. to 250° C., and more preferably 120° C. to 250° C. If the heating temperature is 120° C. or above, the strength of the film may be enhanced by the heating, whereas if 250° C. or below, the film may be prevented from being embrittled due to decomposition of the components in the film.

Heating time in the whole heating is preferably 3 minutes to 180 minutes, and more preferably 5 minutes to 120 minutes.

Apparatus for implementing the whole heating is properly selectable from publicly-known apparatuses depending on purposes, without special limitation, and is exemplified by drying oven, hot plate, and IR heater.

The present invention also relates to a camera module which includes a substrate of solid state image sensing device, and a near infrared cut filter disposed on the light receiving side of the substrate of solid state image sensing device, wherein the above-described near infrared cut filter is the near infrared cut filter of the present invention.

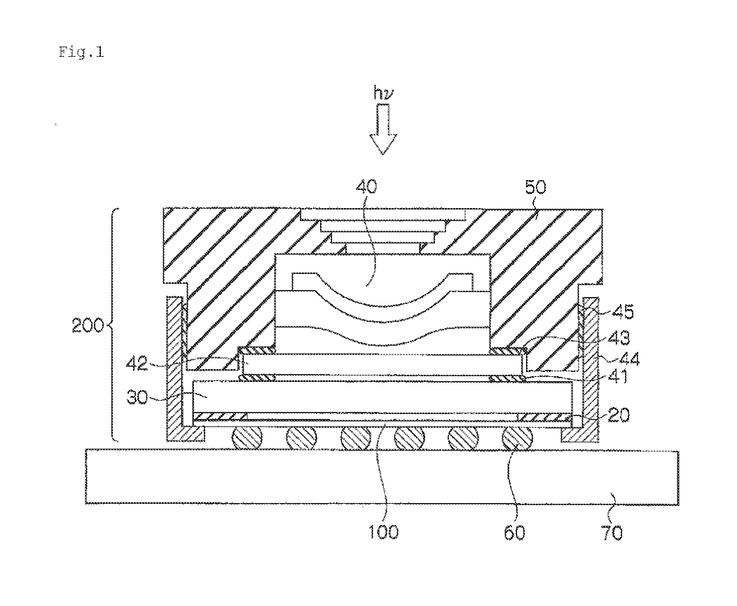

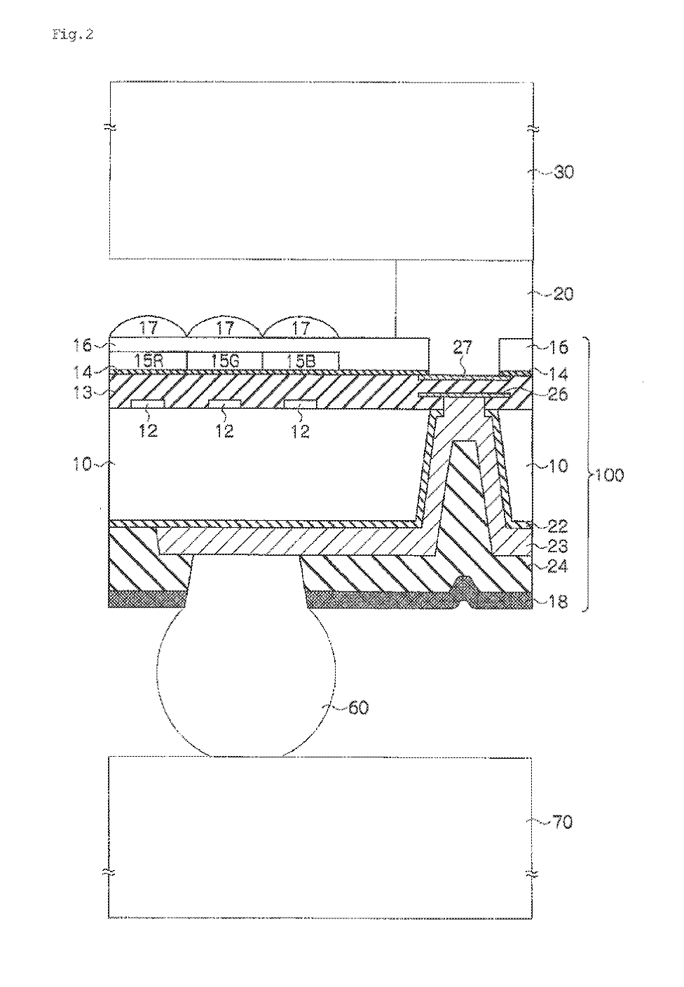

The camera module according to the embodiment of the present invention will be explained below, referring to FIG. 1 and FIG. 2, but not intended to limit the present invention to the specific examples below.

Note that all constituents commonly appear in FIG. 1 and FIG. 2 will given the same reference numerals or marks.

In the description, the words “on”, “above” and “upper side” are used in relation to the further side as viewed from the silicon substrate 10, whereas “under”, “below” and “lower side” are used in relation to the side closer to the silicon substrate 10.

FIG. 1 is a schematic cross sectional view illustrating a configuration of a camera module having a solid state image sensing device.

A camera module 200 illustrated in FIG. 1 is connected through solder balls 60 which are connecting members, to a circuit substrate 70 which is a mounting substrate.

In further detail, the camera module 200 is configured to have a substrate for solid state image sensing device 100 which has an image sensing unit provided on a first principal surface of a silicon substrate; a planarizing layer (not illustrated in FIG. 1) provided on a first principal surface (on the light receiving side) of the substrate for solid state image sensing device 100; a glass substrate 30 (translucent substrate) provided on the planarizing layer; a near-infrared cut filter 42 disposed above the glass substrate 30 (translucent substrate); a lens holder 50 disposed above the near-infrared cut filter 42 and housing in the inner space thereof an image sensing lens 40; and a light blocking and electromagnetic shield 44 disposed so as to surround the substrate for solid state image sensing device 100 and the glass substrate 30. The individual components are bonded by adhesives 20, 45.

The present invention also relates to a method of manufacturing a camera module which has a substrate for solid state image sensing device, and a near-infrared cut filter disposed on the light receiving side of the substrate for solid state image sensing device, the method includes applying the near-infrared absorbing composition described above to thereby form a film, on the light receiving side of the substrate for solid state image sensing device.

Accordingly, in the camera module of this embodiment, the near-infrared cut filter 42 is formed typically by applying the near-infrared absorbing composition of the present invention over the planarizing layer. The method of forming the film by application, to thereby manufacture the near-infrared cut filter, is same as described above.

The camera module 200 is configured to allow incident light by from the external to transmit sequentially through the image sensing lens 40, the near-infrared cut filter 42, the glass substrate 30, and the planarizing layer, and to reach the image sensing unit on the substrate for solid state image sensing device 100.

The camera module 200 is connected through the solder balls 60 (connecting material) to the circuit substrate 70, on the second principal surface side of the substrate for solid state image sensing device 100.

The camera module 200 may alternatively be configured to have the near-infrared cut filter directly provided on the planarizing layer, while omitting the glass substrate 30, or may still alternatively be configured to have the near-infrared cut filter provided over the glass substrate 30, while omitting the planarizing layer.

FIG. 2 is an enlarged cross sectional view illustrating the substrate of solid state image sensing device 100 in FIG. 1.

The substrate of solid state image sensing device 100 is configured to have a silicon substrate 10 as a base, image sensing devices 12, an insulating interlayer 13, a base layer 14, a red color filter 15R, a green color filter 15G, a blue color filter 15B, an overcoat 16, microlenses 17, a light-shielding film. 18, an insulating film 22, a metal electrode 23, a solder resist layer 24, an internal electrode 26, and a device surface electrode 27.

Note that the solder resist layer 24 is omissible.

First, the configuration of the substrate of solid state image sensing device 100 will be explained mainly on the first principal plane side thereof.

As illustrated in FIG. 2, on the first principal plane side of the silicon substrate 10, which is a base of the substrate of solid state image sensing device 100, provided is the image sensing device section having a plurality of image sensing devices 12 such as CCDs or CMOSs arranged therein in a two dimensional manner.

In the image sensing device section, the insulating interlayer 13 is formed over the image sensing devices 12, and the base layer 14 is formed over the insulating interlayer 13. Over the base layer 14, there are provided the red color filter 15R, the green color filter 15G and the blue color filter 15B (in some cases, collectively referred to as “color filter 15”, hereinafter) so as to be respectively corresponded to the image sensing devices 12.

An unillustrated light-shielding film may be provided to the boundaries of the red color filter 15R, the green color filter 15G, and the blue color filter 15B, and to the periphery of the image sensing device section. The light-shielding film may be manufactured, for example, by using a publicly known black color resist.

The overcoat 16 is formed over the color filter 15, and the microlenses 17 are formed over the overcoat 16 so as to be respectively corresponded to the image sensing devices 12 (color filter 15).

On the microlenses 17, provided is the planarizing layer.

On the periphery of the image sensing device section on the first principal plane side, there are provided a peripheral circuit (not illustrated) and the internal electrode 26, wherein the internal electrode 26 is electrically connected through the peripheral circuit to the image sensing devices 12.

Further over the internal electrode 26, the device surface electrode 27 is formed while placing in between the insulating interlayer 13. In the insulating interlayer 13 laid between the internal electrode 26 and the device surface electrode 27, there is formed a contact plug (not illustrated) for electrically connecting these electrodes. The device surface electrode 27 is used for applying voltage and reading signals through the contact plug and the internal electrode 26.

Over the device surface electrode 27, the base layer 14 is formed. Over the base layer 14, the overcoat 16 is formed. The base layer 14 and the overcoat 16 are opened above the device surface electrode 27 to form a pad opening, in which a part of the device surface electrode 27 exposes.

A configuration on the first principal surface side of the substrate for solid state image sensing device 100 has been described. Another possible embodiment is such as having the near-infrared cut filter provided between the base layer 14 and the color filter 15, or, between the color filter 15 and the overcoat 16, in place of providing the near-infrared cut filter 42 over the planarizing layer.

On the first principal surface side of the substrate for solid state image sensing device 100, the adhesive 20 is provided around the image sensing unit, and the substrate for solid state image sensing device 100 and the glass substrate 30 are bonded while placing the adhesive 20 in between.

The silicon substrate 10 has through-holes which extend therethrough, and each through-hole has provided therein a through-electrode as a part of the metal electrode 23. By the through-electrodes, the image sensing unit and the circuit substrate 70 are electrically connected.

Next, the configuration of the substrate of solid state image sensing device 100 will be explained mainly on the second principal plane side thereof.

On the second principal plane side, the insulating film 22 is formed so as to extend over the second principal plane and the inner wall of the through-hole.

On the insulating film 22, there is provided the metal electrode 23 patterned so as to extend from a region on the second principal plane of the silicon substrate 10 to the inside of the through-hole. The metal electrode 23 is an electrode for connecting the image sensing device section in the substrate of solid state image sensing device 100 and the circuit substrate 70.

The through-hole electrode is a portion of the metal electrode 23 formed in the through-hole. The through-hole electrode extends through a part of the silicon substrate 10 and the insulating interlayer to reach the lower side of the internal electrode 26, and is electrically connected to the internal electrode 26.

Further on the second principal plane side, there is provided a solder resist layer 24 (protective insulating film) formed so as to cover the second principal plane having the metal electrode 23 formed thereon, and has an opening which allows a part of the metal electrode 23 to expose therein.

Further on the second principal plane side, there is provided a light-shielding film 18 formed so as to cover the second principal plane having the solder resist layer 24 formed thereon, and has an opening which allows a part of the metal electrode 23 to expose therein.

While the light-shielding film 18 illustrated in FIG. 2 is patterned so as to cover a part of the metal electrode 23, and to allow the residual part to expose, it may alternatively be patterned so as to allow the entire portion of the metal electrode 23 to expose (the same will also apply to the patterning of the solder resist layer 24).

Alternatively, the solder resist layer 24 is omissible, and the light-shielding film 18 may be provided directly on the second principal plane having the metal electrode 23 formed thereon.

On the exposed portion of the metal electrode 23, there is provided a solder ball 60 as a connection component, and through the solder ball 60, the metal electrode 23 of the substrate of solid state image sensing device 100 and an unillustrated connection electrode of the circuit substrate 70 are electrically connected.

The configuration of the substrate for solid state image sensing device 100 has been explained, which may be formed any of publicly known methods such as described in paragraphs [0033] to [0068] of JP-A-2009-158863, and paragraphs [0036] to [0065] of JP-A-2009-99591.

The insulating interlayer 13 is configured by a SiO₂ film or a SiN film, typically formed by sputtering, CVD (Chemical Vapor Deposition) or the like.

The color filter is formed typically by using publicly known color resist, by photolithography.

The overcoat 16 and the base layer 14 are formed typically by using publicly known resist for forming organic insulating interlayer, by photolithography.

The microlens 17 is formed typically by using a styrene-based polymer, by photolithography.

The solder resist layer 24 is preferably formed by using, for example, a publicly known solder resist containing a phenolic polymer, polyimide-based polymer, or amine-based polymer, by photolithography.

The solder balls 60 are formed typically by using Sn—Pb (eutectic), 95Pb—Sn (high-lead, high-melting-point solder), or Pb-free solder such as Sn—Ag, Sn—Cu, Sn—Ag—Cu or the like. The solder balls 60 are formed, for example, into a spherical form with a diameter of 100 μm to 1,000 μm (preferably 150 μm to 700 μm).

The internal electrode 26 and the device-top electrode 27 are configured as a metal electrode composed of Cu or the like, typically formed by CMP (Chemical Mechanical Polishing), or photolithography combined with etching.

The metal electrode 23 is configured as a metal electrode composed of Cu, Au, Al, Ni, W, Pt, Mo, Cu compound, W compound, Mo compound or the like, typically formed by sputtering, photolithography, etching or electroplating. The metal electrode 23 may have a single-layered structure or a stacked structure composed of two or more layers. Thickness of the metal electrode 23 is typically 0.1 μm to 20 μm (preferably 0.1 μm to 10 μm). The silicon substrate 10 is not specifically limited, and may also be a substrate thinned by grinding the back surface. While thickness of the substrate is not specifically limited, a silicon wafer having of 20 μm to 200 μm thick (preferably 30 to 150 μm thick) is typically used.

The through-holes in the silicon substrate 10 are formed typically by photolithography combined with RIE (Reactive Ion Etching).

While one embodiment of the camera module has been explained referring to FIG. 1 and FIG. 2, the embodiment is not limited to that illustrated in FIG. 1 and FIG. 2.

### Example

The present invention will further be detailed below referring to Examples. Materials, amount of use, ratio, details of processes, procedures of process and so forth described in Examples below may be modified arbitrarily, without departing from the spirit of the present invention. Accordingly, the scope of the present invention should not be construed to be limited by Examples below. In Examples, wording of “part(s)” used for describing the amount of use means “part(s) by weight”, unless otherwise specifically stated.

Abbreviations below were used in Examples.

### <Curable Compounds (Polymerizable Compounds)>

Curable compound A: KARAYADDPHA (from Nippon Kayaku Co. Ltd., mixture of dipentaerythritol pentaacrylate and dipentaerythritol hexaacrylate)
Curable compound B: A-TMMT (from Shin-Nakamura Chemical Co. Ltd., pentaerythritol tetraacrylate)
curable compound C: JER157S65 (from Mitsubishi Chemical Corporation, novolac-type epoxy compound)
Curable compound D: EHPE3150 (from Daicel Corporation, polyfunctional epoxy compound)
Curable compound E: Denacol EX-211 (from Nagase ChemteX Corporation, neopentyl glycol diglycidyl ether)
Curable compound F: Aronix M-305 (from Toagosei Co. Ltd., pentaerythritol triacrylate)
Curable compound G: KAYARAD HDDA (from Nippon Kayaku Co. Ltd., 1,6-hexanediol diacrylate)
P-1: resin composed of benzylmethacrylate and methacrylic acid, with a molar ratio of 80:20 (Mw=30000); binder)

### <Surfactants>

ADD-1: Megafac F176 (from DIC Corporation) (fluorine-containing surfactant)
ADD-2: Megafac R08 (from DIC Corporation) (fluorine-containing and silicone-based surfactant)
ADD-3: polysiloxane polymer KP-341 (from Shin-Etsu Chemical Co. Ltd.) (silicone-based surfactant)
ADD-4: Megafac F-475 (from DIC Corporation) (surfactant containing a polymer having a fluoroaliphatic group)
ADD-5: copolymer of an acrylate having a C₆F₁₃ group, (poly(oxypropylene)) acrylate and (poly(oxypropylene))methacrylate (surfactant containing a polymer having a fluoroaliphatic group)
ADD-6: copolymer of an acrylate having a C₆F₁₃ group, and (poly(ethyleneoxy, propyleneoxy and ethyleneoxy blocks)) acrylate (surfactant containing a polymer having a fluoroaliphatic group)
ADD-7: polyoxyethylene nonyl phenyl ether (nonionic surfactant) (from Wako Pure Chemical Industries, Ltd.)

### <Solvent>

### PGMEA: Propylene Glycol Monomethyl Ether Acetate

### (Copper Complex a and Method of Preparation of the Same)

Five grams of copper benzoate (from Kanto Chemical Co. Inc.), and 7 g of methacryloyl oxyethyl phosphate (from Johoku Chemical Co. Ltd.) were dissolved into 25 ml of acetone, the mixture was stirred at room temperature for 4 hours so as to proceed a reaction. The obtained reaction product was dropped into a cyclohexane solvent, and the precipitate was collected by filtration and then dried, to thereby obtain copper complex A.

### (Copper Complex B and Method of Preparing the Same)

In place of methacryloyl oxyethyl phosphate in the method of preparing copper complex A, 5.7 g of quinoline-2-carboxylic acid was used, to thereby obtain copper complex B as a target product.

### (Copper Complex C and Method of Preparing the Same)

In place of methacryloyl oxyethyl phosphate in the method of preparing copper complex A, 3.67 g of hydroxymethyl sulfonic acid was used, to thereby obtain copper complex C as a target product.

### (Copper Complex D and Method of Preparing the Same)

In place of methacryloyl oxyethyl phosphate in the method of preparing copper complex A, 8.24 g of diphenyl phosphate, to thereby obtain copper complex D as a target product.

### Example 1

Compounds listed below were mixed, to thereby prepare a near-infrared absorbing composition of Example 1.

| Copper complex A | 25 | parts by mass |
|---|---|---|
| Polymerizable compound A | 22.48 | parts by mass |
| (curable compound) | | |
| P-1 (binder) | 2.50 | parts by mass |
| ADD-1 (surfactant) | 0.02 | parts by mass |
| Propylene glycol monomethyl | 50 | parts by mass |

ether acetate (solvent)

The near-infrared absorbing compositions of the individual Examples and the individual Comparative Examples were prepared similarly to Example 1, except that the amounts of addition of the copper complex, polymerizable compound, surfactant, and binder were adjusted as listed in Table below. Table also show results of evaluation.

### <Evaluation of Near-Infrared Absorbing Composition>

### (Manufacture of Near-Infrared Cut Filter)

Each of the near-infrared absorbing compositions of Examples and Comparative Examples was coated by spin coating (using Mikasa Spincoater 1H-D7 from MIKASA Co. Ltd.; 300 rpm) over the glass substrate, and then prebaked at 100° C. for 120 seconds. Thereafter, all samples were heated on a hot plate at 200° C. for 180 seconds. These processes were repeated five times, to thereby manufacture near-infrared cut filters of 200 μm thick.

### (Evaluation of Light Resistance)

The substrates of Examples and Comparative Examples were subjected to light resistance test using a super xenon weather meter SX75 (from Suga Test Instruments Co. Ltd.) under an illuminance of 75 W/m² for 100 hours. Maximum absorbance (Absλmax) of the near-infrared cut filters over the wavelength range from 700 nm to 1,400 nm, respectively before and after the light resistance test, was measured using a spectrophotometer U-4100 (from Hitachi High-Technologies Corporation), and retention rate of absorbance when compared between before and after the light resistance test was determined. The retention rate of absorbance is necessarily 90% or above. The retention rate of absorbance is preferably 95% or above, wherein a value of 97% or above is of large benefit from a technical point of view.

### (Evaluation of Defects)

Each of liquid near-infrared absorbing compositions of Examples and Comparative Examples was coated over an 8-inch wafer using Clean Track ACT-8 (from Tokyo Electron Ltd.), prebaked at 100° C. for 120 seconds, and postbaked at 200° C. for 180 seconds, to thereby manufacture the near-infrared cut filter of 20 μm thick. The thus-obtained silicon wafer with the near-infrared cut filter was inspected using an defect inspection apparatus ComPLUS3 from Applied Materials Technologies Inc. to detect defects, and the number of defects per 2462 cm² was determined.

TABLE 33

| | | | Polymerizable | | | | | | | |
|---|---|---|---|---|---|---|---|---|---|---|
| | Copper complex | | compound | | Surfactant | | Binder | | | |
| | | Amount of | | Amount of | | Amount of | | Amount of | Light | |
| | Compound | addition | Compound | addition | Compound | addition | Compound | addition | resistance | Defects |
| Example 1 | Copper complex A | 50% | A | 44.96% | ADD-1 | 0.04000% | P-1 | 5% | 97% | 23 |
| Example 2 | Copper complex A | 50% | A | 44.96% | ADD-2 | 0.04000% | P-1 | 5% | 96% | 25 |
| Example 3 | Copper complex A | 50% | A | 44.96% | ADD-3 | 0.04000% | P-1 | 5% | 95% | 21 |
| Example 4 | Copper complex A | 50% | A | 44.96% | ADD-4 | 0.04000% | P-1 | 5% | 98% | 26 |
| Example 5 | Copper complex A | 50% | A | 44.96% | ADD-5 | 0.04000% | P-1 | 5% | 99% | 22 |
| Example 6 | Copper complex A | 50% | A | 44.96% | ADD-6 | 0.04000% | P-1 | 5% | 100% | 20 |
| Example 7 | Copper complex A | 50% | A | 44.96% | ADD-7 | 0.04000% | P-1 | 5% | 93% | 23 |
| Example 8 | Copper complex A | 50% | A | 45.00% | ADD-1 | 0.00010% | P-1 | 5% | 92% | 27 |
| Example 9 | Copper complex A | 50% | A | 44.80% | ADD-1 | 0.20000% | P-1 | 5% | 97% | 21 |
| Example 1O | Copper complex A | 50% | A | 43.00% | ADD-1 | 2.00000% | P-1 | 5% | 97% | 32 |
| Example 11 | Copper complex B | 50% | A | 44.96% | ADD-1 | 0.04000% | P-1 | 5% | 95% | 25 |
| Example 12 | Copper complex C | 50% | A | 44.96% | ADD-1 | 0.04000% | P-1 | 5% | 94% | 27 |
| Example 13 | Copper complex A | 50% | B | 44.96% | ADD-1 | 0.04000% | P-1 | 5% | 96% | 23 |
| Example 14 | Copper complex A | 50% | C | 44.96% | ADD-1 | 0.04000% | P-1 | 5% | 96% | 18 |
| Example 15 | Copper complex A | 32% | C | 62.96% | ADD-1 | 0.04000% | P-1 | 5% | 94% | 22 |
| Example 16 | Copper complex A | 75% | C | 19.96% | ADD-1 | 0.04000% | P-1 | 5% | 98% | 23 |
| Example 17 | Copper complex A | 50% | A | 45.00% | ADD-3 | 0.00010% | P-1 | 5% | 91% | 24 |
| Example 18 | Copper complex A | 50% | A | 44.80% | ADD-3 | 0.20000% | P-1 | 5% | 97% | 28 |
| Comparative | Pd complex A | 50% | A | 44.96% | ADD-1 | 0.04000% | P-1 | 5% | 83% | 21 |
| Example 1 | | | | | | | | | | |

In Table above, amounts of addition of the individual components are given in % by mass, representing ratios of mixing relative to the whole solid content. Pd complex A is described in Example 10 of Published Japanese Translation of PCT International Publication for Patent Application No. 2010-516823.

As clearly known from Table above, the near-infrared cut layers excellent in the light resistance and only with small numbers of defects were obtained by using the composition of the present invention.

### Example 19

The compounds below were mixed to prepare a near-infrared absorbing composition of Example 19.

| | | |
|---|---|---|
| Copper complex A | 25 | parts by mass |
| Polymerizable compound A | 22.48 | parts by mass |
| (curable compound) | | |
| P-1 (binder) | 2.50 | parts by mass |
| Megafac F176 (from DIC Corporation) | 0.02 | parts by mass |
| (fluorine-containing surfactant) | | |
| Propylene glycol monomethyl | 50 | parts by mass |

ether acetate (solvent)

The near-infrared absorbing compositions of the individual Examples and the individual Comparative Examples were prepared similarly to Example 19, except that the amounts of addition of the copper complex, polymerizable compound and surfactant were adjusted as listed in Table below. Table also shows results of evaluation.

### <Evaluation of Near-Infrared Absorbing Composition>

### (Manufacture of Near-Infrared Cut Filter)

Each of the near-infrared absorbing compositions of Examples and Comparative Examples was coated by spin coating (using Mikasa Spincoater 1H-D7 from MIKASA Co. Ltd.; 300 rpm) over the glass substrate, and then prebaked at 100° C. for 120 seconds. Thereafter, all samples were heated on a hotplate at 200° C. for 180 seconds. These processes were repeated five times, to thereby manufacture near-infrared cut filters of 200 μm thick.

Further thereon, a stack (composed of 44 layers) having silica (SiO₂: 20 to 250 nm thick) layers and titania (TiO₂: 70 to 130 nm thick) layers alternately stacked therein was formed at a vacuum evaporation temperature of 200° C., as the dielectric multi-layered film capable of reflecting near-infrared radiation.

### (Evaluation of Light Resistance and Defect)

The light resistance and the number of defects were evaluated similarly as described in Example 1.

### (High Temperature and High Humidity Test)

Each of glass substrates of Examples and Comparative Examples was allowed to stand in a thermo-hygrostat chamber IW-222 (from Yamato Scientific Co. Ltd.) at 85° C., 95% RH for 24 hours, and then absorption spectrum of each near-infrared cut filter over the wavelength range from 400 nm to 1,400 nm was measured respectively before and after the high temperature and high humidity test, using a spectrophotometer U-4100 (from Hitachi High-Technologies Corporation), and rate of change in absorption peak area was determined. The rate of change in absorption peak area is necessarily 10% or below. The rate of change in absorption peak area is preferably 5% or below, and particularly 3% or below.

TABLE 34

| | Copper complex | | Polymerizable compound | | Surfactant | | Binder | |
|---|---|---|---|---|---|---|---|---|
| | | Amount of | | Amount of | | Amount of | | Amount of |
| | Compound | addition | Compound | addition | Compound | addition | Compound | addition |
| Example 19 | Copper complex A | 50% | A | 44.96% | ADD-1 | 0.04000% | P-1 | 5% |
| Example 20 | Copper complex B | 50% | A | 44.96% | ADD-1 | 0.04000% | P-1 | 5% |
| Example 21 | Copper complex C | 50% | A | 44.96% | ADD-1 | 0.04000% | P-1 | 5% |
| Example 22 | Copper complex D | 50% | A | 44.96% | ADD-1 | 0.04000% | P-1 | 5% |
| Example 23 | Copper complex A | 29% | A | 65.96% | ADD-1 | 0.04000% | P-1 | 5% |
| Example 24 | Copper complex A | 30% | A | 64.96% | ADD-1 | 0.04000% | P-1 | 5% |
| Example 25 | Copper complex A | 75% | A | 19.96% | ADD-1 | 0.04000% | P-1 | 5% |
| Example 26 | Copper complex A | 90% | A | 4.96% | ADD-1 | 0.04000% | P-1 | 5% |
| Example 27 | Copper complex A | 91% | A | 3.96% | ADD-1 | 0.04000% | P-1 | 5% |
| Example 28 | Copper complex A | 50% | F | 44.96% | ADD-1 | 0.04000% | P-1 | 5% |
| Example 29 | Copper complex A | 50% | G | 44.96% | ADD-1 | 0.04000% | P-1 | 5% |
| Example 30 | Copper complex A | 50% | C | 44.96% | ADD-1 | 0.04000% | P-1 | 5% |
| Example 31 | Copper complex A | 50% | D | 44.96% | ADD-1 | 0.04000% | P-1 | 5% |
| Example 32 | Copper complex A | 50% | E | 44.96% | ADD-1 | 0.04000% | P-1 | 5% |
| Example 33 | Copper complex A | 50% | A | 44.96% | ADD-1 | 0.04000% | P-1 | 5% |
| Example 34 | Copper complex A | 50% | A | 44.96% | ADD-1 | 0.04000% | P-1 | 5% |
| Example 35 | Copper complex A | 50% | A | 44.96% | ADD-1 | 0.04000% | P-1 | 5% |
| Comparative | Pigment A | 50% | A | 44.96% | ADD-1 | 0.04000% | P-1 | 5% |
| Example 2 | | | | | | | | |
| Comparative | Pd complexA | 50% | A | 44.96% | ADD-1 | 0.04000% | P-1 | 5% |
| Example 3 | | | | | | | | |

| | Dielectric multi-layered film | | | | |
|---|---|---|---|---|---|
| | High refractive | Low refractive | Light | | High temperature and |
| | index material | index material | resistance | Defects | high humidity test |
| Example 19 | Titanium oxide | Silica | 97% | 23 | 3% |
| Example 20 | Titanium oxide | Silica | 96% | 25 | 7% |
| Example 21 | Titanium oxide | Silica | 95% | 27 | 8% |
| Example 22 | Titanium oxide | Silica | 98% | 26 | 2% |
| Example 23 | Titanium oxide | Silica | 90% | 24 | 2% |
| Example 24 | Titanium oxide | Silica | 91% | 23 | 3% |
| Example 25 | Titanium oxide | Silica | 97% | 25 | 3% |
| Example 26 | Titanium oxide | Silica | 98% | 28 | 5% |
| Example 27 | Titanium oxide | Silica | 98% | 29 | 6% |
| Example 28 | Titanium oxide | Silica | 97% | 25 | 4% |
| Example 29 | Titanium oxide | Silica | 97% | 24 | 6% |
| Example 30 | Titanium oxide | Silica | 97% | 23 | 3% |
| Example 31 | Titanium oxide | Silica | 97% | 23 | 3% |
| Example 32 | Titanium oxide | Silica | 97% | 27 | 7% |
| Example 33 | Zirconium oxide | Silica | 96% | 23 | 5% |
| Example 34 | Zinc oxide | Silica | 96% | 24 | 6% |
| Example 35 | Titanium oxide | Alumina | 96% | 23 | 6% |
| Comparative | Titanium oxide | Silica | 84% | 31 | 3% |
| Example 2 | | | | | |
| Comparative | Titanium oxide | Silica | 88% | 35 | 3% |
| Example 3 | | | | | |

In Table above, amounts of addition of the individual components are given in % by mass, representing ratios of mixing relative to the whole solid content. Dye A is ABS670T (from Exciton). Pd complex A is described in Example 10 of Published Japanese Translation of PCT International Publication for Patent Application No. 2010-516823.

As is clear from Table above, the near-infrared cut filters, having the dielectric multi-layered films on the films manufactured by using the compositions of the present invention, were found to show excellent durability under high temperature and high humidity.

The present disclosure relates to the subject matter contained in Japanese Patent Application No. 167693/2012, filed on Jul. 27, 2012, and Japanese Patent Application No. 236342/2012 filed on Oct. 26, 2012, which are expressly incorporated herein by reference in their entirety. All the publications referred to in the present specification are also expressly incorporated herein by reference in their entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

What is claimed is:

1. A near-infrared absorbing composition comprising a copper complex having a maximum absorption wavelength in a near-infrared absorption region, and a surfactant, wherein the surfactant is at least either one of a fluorine-containing surfactant and a silicone-based surfactant, and the copper complex is contained in an amount of 30 to 90% by mass of the whole solid content of the infrared absorbing composition.

2. A near-infrared absorbing composition comprising a copper complex having a maximum absorption wavelength in a near-infrared absorption region, a polmyerizable compound, a solvent and a surfactant, wherein the surfactant is at least either one of fluorine-containing surfactant and silicone-based surfactant, an amount of addition of the copper complex is 30 to 90% by mass of the whole solid content of the infrared absorbing composition, an amount of addition of the solvent is 20 to 65 by mass of the composition, and an amount of the polymerizable compound is 20 to 60% by mass of the whole solid content of the infrared absorbing composition.

3. A near-infrared absorbing composition comprising a copper complex having a maximum absorption wavelength in a near-infrared absorption region and a surfactant, wherein the surfactant is a polymer having a fluoroaliphatic group.

4. The near-infrared absorbing composition of claim 1,
wherein the surfactant is a polymer having a fluoroaliphatic group.

5. The near-infrared absorbing composition of claim 3, wherein the copper complex is contained in an amount of 30 to 90% by mass of the whole solid content of the infrared absorbing composition.

6. The near-infrared absorbing composition of claim 1,
wherein the copper complex is a phosphate-copper complex compound.

7. The near-infrared absorbing composition of claim 1, wherein the copper complex compound is formed by using a compound represented by the formula (1) below:
(HO)ₙ—P(═O)—(OR²)₃₋₂ Formula (1)
wherein R² represents a C₁₋₁₈ alkyl group, C₆₋₁₈ aryl group, C₁₋₁₈ aralkyl group, or C₁₋₁₈ alkenyl group, or —OR² represents a C₄₋₁₀₀ polyoxyalkyl group, C₄₋₁₀₀ (meth)acryloyloxyalkyl group, or, C₄₋₁₀₀ (meth)acryloyl polyoxyalkyl group, and n represents 1 or 2.

8. The near-infrared absorbing composition of claim 1, further comprising a curable compound.

9. The near-infrared absorbing composition of claim 3, further comprising a curable compound.

10. The near-infrared absorbing composition of claim 1,
wherein the surfactant is contained in an amount of 0.0001 to 2% by mass of the whole solid content.

11. The near-infrared absorbing composition of claim 2,
wherein the surfactant is contained in an amount of 0.0001 to 2% by mass of the whole solid content.

12. The near-infrared absorbing composition of claim 3,
wherein the surfactant is contained in an amount of 0.0001 to 2% by mass of the whole solid content.

13. A stack comprising a near-infrared cut layer formed by curing the near-infrared absorbing composition described in claim 1, and a dielectric multi-layered film.

14. The stack of claim 13,
wherein the near-infrared cut layer is provided on a transparent support.

15. The stack of claim 13,
wherein the dielectric multi-layered film is configured to have high refractive index material layers and low refractive index material layers alternately stacked therein.

16. The stack of claim 15,
wherein the high refractive index material layer is a layer composed of titania, and the low refractive index material layer is a layer composed of silica.

17. A near-infrared cut filter having a near-infrared cut layer formed by curing the near-infrared absorbing composition described in claim 1.

18. A camera module comprising a substrate for solid state image sensing device, and a near-infrared cut filter described in claim 17 disposed on a light receiving side of the substrate for a solid state image sensing device.

19. A near-infrared cut filter comprising a translucent support, a near-infrared cut layer formed by curing a near-infrared absorbing composition containing a copper complex having a maximum absorption wavelength in the near-infrared absorption region, and a dielectric multi-layered film, stacked in this order.

20. A method for manufacturing a solid state image sensing device having an image sensor, comprising coating a near-infrared absorbing composition of claim 1 on the image sensor.
